(19) United States
(12) Patent Application Publication
(10) Pub. No.: US 2021/0280810 A1
(43) Pub. Date: Sep. 9, 2021

(54) PHOTOELECTRIC CONVERSION ELEMENT, PHOTOELECTRIC CONVERSION MODULE, AND ELECTRONIC DEVICE

(71) Applicant: RICOH COMPANY, LTD., Tokyo (JP)

(72) Inventors: Nozomu TAMOTO, Shizuoka (JP); Yuuji TANAKA, Shizuoka (JP); Naomichi KANEI, Shizuoka (JP); Tamotsu HORIUCHI, Kyoto (JP); Suzuka NOZOE, Kanagawa (JP)

(21) Appl. No.: 17/185,451

(22) Filed: Feb. 25, 2021

(30) Foreign Application Priority Data
Feb. 27, 2020 (JP) 2020-032018

(51) Int. Cl. H01L 51/44; G01N 23/2258; H01L 51/00; H01L 51/42; H01G 9/20

(52) U.S. Cl. CPC H01L 51/441; G01N 23/2258; H01G 9/2036; H01L 51/4273; H01L 51/0031

(57) ABSTRACT

A photoelectric conversion element including: a first electrode; a photoelectric conversion layer; and a second electrode, wherein the photoelectric conversion layer includes an electron-transporting layer and a hole-transporting layer, the electron-transporting layer includes a lithium ion, the hole-transporting layer includes an organic hole-transporting material and a lithium salt, and lithium included in the electron-transporting layer is more than lithium included in the hole-transporting layer.

### CROSS-REFERENCE TO RELATED APPLICATIONS

The present application claims priority under 35 U.S.C. § 119 to Japanese Patent Application No. 2020-032018 filed Feb. 27, 2020. The contents of which are incorporated herein by reference in their entirety.

### BACKGROUND OF THE INVENTION

### Field of the Invention

The present disclosure relates to a photoelectric conversion element, a photoelectric conversion module, and an electronic device.

### Description of the Related Art

In recent years, driving power required in an electronic circuit has become very small, and it has become possible to drive various electronic components such as sensors even with a weak power (μW order). Moreover, when a sensor is used, it has been expected to be applied to environmental power generation elements as a self-supporting power supply that can generate electricity and can consume the electricity on the spot. Among them, solar cells, which are a kind of photoelectric conversion element, have attracted much interest as an element that can generate electricity anywhere even with a weak light so long as there is light.

Photoelectric conversion elements such as solar cells are required to have output with a low illuminance and durability depending on applications.

In order to provide a photoelectric conversion element, which is excellent in initial characteristics of the photoelectric conversion efficiency or has a high durability to irradiation of light, and a solar cell using the photoelectric conversion element, the following photoelectric conversion element has been proposed. Specifically, the photoelectric conversion element includes a substrate, a first electrode, a photoelectric conversion layer, a hole-transporting layer, and a second electrode, wherein the photoelectric conversion layer includes a semiconductor bearing a sensitizing dye and a polyvalent acid lithium salt (see Japanese Unexamined Patent Application Publication No. 2014-63790).

In order to provide a solar cell, which has a high photoelectric conversion efficiency, does not deteriorate the photoelectric conversion efficiency even used for a long period of time, and is excellent in durability, the following solar cell has been proposed. Specifically, the solar cell includes: a support; a first electrode; a semiconductor layer formed of a dye-born semiconductor; a charge-transporting layer including a charge-transporting material formed of a conductive polymeric compound formed by allowing a polymerizable compound to polymerize; and a second electrode, at least the first electrode, the semiconductor layer, the charge-transporting layer, and the second electrode being disposed on the substrate, wherein the charge-transporting layer includes a lithium salt and an anionic surfactant (see Japanese Unexamined Patent Application Publication No. 2013-89328).

In order to provide a photoelectric conversion element and an all-solid-dye-sensitized solar cell, which are excellent in photoelectric conversion characteristics particularly under low illuminance conditions, the following photoelectric conversion element has been proposed. Specifically, the photoelectric conversion element includes a substrate, a first electrode, a photoelectric conversion layer including an n-type semiconductor and a sensitizing dye, a charge-transporting layer, and a second electrode, wherein the charge-transporting layer is a solid-charge-transporting layer, at least one of the photoelectric conversion layer and the charge-transporting layer includes an alkali metal salt of an anion represented by General Formula (1): [(CₙF₂ₙ₊₁SO₂)₂N]⁻ (where n is an integer of from 1 through 6), and the anion is included in an amount of 1.30 μmol/mm³ or more relative to a total volume of the photoelectric conversion layer and the charge-transporting layer (see Japanese Unexamined Patent Application Publication No. 2014-232608).

### SUMMARY OF THE INVENTION

According to one aspect of the present disclosure, a photoelectric conversion element includes: a first electrode; a photoelectric conversion layer; and a second electrode. The photoelectric conversion layer includes an electron-transporting layer and a hole-transporting layer. The electron-transporting layer includes a lithium ion. The hole-transporting layer includes an organic hole-transporting material and a lithium salt. Lithium included in the electron-transporting layer is more than lithium included in the hole-transporting layer.

### BRIEF DESCRIPTION OF THE DRAWINGS

FIG. 1 is a cross-sectional view of one example of an edge part of a photoelectric conversion element;

FIG. 2 is a cross-sectional view of another example of an edge part of a photoelectric conversion element;

FIG. 3A is a view for explaining a method for analyzing a photoelectric conversion element by a GCIB method and a TOF-SIMS method (part 1);

FIG. 3B is a view for explaining a method for analyzing a photoelectric conversion element by a GCIB method and a TOF-SIMS method (part 2);

FIG. 3C is a view for explaining a method for analyzing a photoelectric conversion element by a GCIB method and a TOF-SIMS method (part 3);

FIG. 3D is a view for explaining a method for analyzing a photoelectric conversion element by a GCIB method and a TOF-SIMS method (part 4);

FIG. 3E is a view for explaining a method for analyzing a photoelectric conversion element by a GCIB method and a TOF-SIMS method (part 5);

FIG. 3F is a view for explaining a method for analyzing a photoelectric conversion element by a GCIB method and a TOF-SIMS method (part 6);

FIG. 3G is a view for explaining a method for analyzing a photoelectric conversion element by a GCIB method and a TOF-SIMS method (part 7);

FIG. 3H is a view for explaining a method for analyzing a photoelectric conversion element by a GCIB method and a TOF-SIMS method (part 8);

FIG. 3I is a view for explaining a method for analyzing a photoelectric conversion element by a GCIB method and a TOF-SIMS method (part 9);

FIG. 3J is a view for explaining a method for analyzing a photoelectric conversion element by a GCIB method and a TOF-SIMS method (part 10);

FIG. 3K is a view for explaining a method for analyzing a photoelectric conversion element by a GCIB method and a TOF-SIMS method (part 11);

FIG. 3L is a view for explaining a method for analyzing a photoelectric conversion element by a GCIB method and a TOF-SIMS method (part 12);

FIG. 4A is a view for explaining a method for analyzing a photoelectric conversion element by a SAICAS method and a TOF-SIMS method (part 1);

FIG. 4B is a view for explaining a method for analyzing a photoelectric conversion element by a SAICAS method and a TOF-SIMS method (part 2);

FIG. 4C is a view for explaining a method for analyzing a photoelectric conversion element by a SAICAS method and a TOF-SIMS method (part 3);

FIG. 4D is a view for explaining a method for analyzing a photoelectric conversion element by a SAICAS method and a TOF-SIMS method (part 4);

FIG. 4E is a view for explaining a method for analyzing a photoelectric conversion element by a SAICAS method and a TOF-SIMS method (part 5);

FIG. 5 is a schematic view presenting one example of a photoelectric conversion element of the present disclosure;

FIG. 6 is a schematic view presenting another example of a photoelectric conversion element of the present disclosure;

FIG. 7 is a schematic view presenting another example of a photoelectric conversion element of the present disclosure;

FIG. 8 is a schematic view presenting one example of a photoelectric conversion module of the present disclosure;

FIG. 9 is a schematic view presenting another example of a photoelectric conversion module of the present disclosure;

FIG. 10 is a schematic view presenting another example of a photoelectric conversion module of the present disclosure;

FIG. 11 is a schematic view presenting one example where a mouse is used as an electronic device;

FIG. 12 is a schematic view presenting one example where a photoelectric conversion element is mounted in a mouse;

FIG. 13 is a schematic view presenting one example where a keyboard used in a personal computer is used as an electronic device;

FIG. 14 is a schematic view presenting one example where a photoelectric conversion element is mounted in a keyboard;

FIG. 15 is a schematic view presenting one example where a small photoelectric conversion element is mounted in some keys of a keyboard;

FIG. 16 is a schematic view presenting one example where a sensor is used as an electronic device;

FIG. 17 is a schematic view presenting one example where a turntable is used as an electronic device;

FIG. 18 is a schematic view presenting one example of an electronic device obtained by combining the photoelectric conversion element and/or the photoelectric conversion module of the present disclosure with a device configured to be driven by electric power generated through photoelectric conversion of the photoelectric conversion element and/or the photoelectric conversion module;

FIG. 19 is a schematic view presenting one example where a power supply IC for a photoelectric conversion element is incorporated between the photoelectric conversion element and the circuit of the device in FIG. 18;

FIG. 20 is a schematic view presenting one example where an electricity storage device is incorporated between the power supply IC and the circuit of the device in FIG. 19;

FIG. 21 is a schematic view presenting one example of a power supply module including the photoelectric conversion element and/or the photoelectric conversion module of the present disclosure and a power supply IC;

FIG. 22 is a schematic view presenting one example of a power supply module obtained by adding the electricity storage device to the power supply IC in FIG. 21;

FIG. 23 is one example of a TOF-SIMS depth profile obtained from a hole-transporting layer to an electron-transporting layer in the present disclosure; and

FIG. 24 is one example of a TOF-SIMS depth profile obtained from an electron-transporting layer to a first substrate in the present disclosure.

### DETAILED DESCRIPTION OF THE INVENTION

### (Photoelectric Conversion Element)

A photoelectric conversion element of the present disclosure includes at least a first electrode, a photoelectric conversion layer, and a second electrode, and further includes other members such as a substrate and a hole blocking layer if necessary.

The photoelectric conversion layer includes an electron-transporting layer and a hole-transporting layer.

An object of the present disclosure is to provide a photoelectric conversion element, which includes a solid-type hole-transporting layer including an organic hole-transporting material, can obtain a high output even with light of a low illuminance, and is excellent in persistence of its effect.

According to the present disclosure, it is possible to provide a photoelectric conversion element, which includes a solid-type hole-transporting layer including an organic hole-transporting material, can obtain a high output even with light of a low illuminance, and is excellent in persistence of its effect.

The present inventors found that, in a photoelectric conversion element which includes a solid-type hole-transporting layer including an organic hole-transporting material, when lithium included in the electron-transporting layer is more than lithium included in the hole-transporting layer, it is possible to obtain a photoelectric conversion element, which can obtain a high output even with light of a low illuminance and is excellent in persistence of its effect. As a result, the present inventors completed the present disclosure. The reason for this is not obvious, but it is believed that the aforementioned effect is achieved because a lithium ion in the electron-transporting layer enhances an electron-transporting property of the electron-transporting layer, and the reverse electron transfer, in which electrons transferred in the electron-transporting layer and holes existing in the hole-transporting layer are reunited, can be prevented.

It is not necessary to add a lithium salt to the electron-transporting layer in advance. So long as a lithium salt is added to the hole-transporting layer, the lithium ion migrates to the electron-transporting layer, and therefore the electron-transporting layer includes lithium. As a result, the effects of the present disclosure can be obtained.

Here, the lithium included in the electron-transporting layer being more than the lithium included in the hole-transporting layer means that an average value of ionic intensities of the lithium included in the electron-transporting layer is larger than an average value of ionic intensities of the lithium included in the hole-transporting layer, in a depth profile obtained by measuring the lithium included in the electron-transporting layer and the lithium included in the hole-transporting layer by the following measurement method (1) or (2).

(1) after the second electrode is removed from the photoelectric conversion element, a gas cluster ion beam is applied toward the hole-transporting layer and the electron-transporting layer from a side of the hole-transporting layer, to cut the hole-transporting layer and the electron-transporting layer to prepare an exposed surface; and the lithium of the exposed surface is measured through time-of-flight secondary ion mass spectrometry (TOF-SIMS) in a thickness direction of the hole-transporting layer and the electron-transporting layer, to measure a distribution of the lithium in the thickness direction of the hole-transporting layer and the electron-transporting layer; and

(2) after the second electrode is removed from the photoelectric conversion element, the hole-transporting layer and the electron-transporting layer are cut by a cutting blade in a diagonal direction relative to a thickness direction from a side of an exposed surface of the hole-transporting layer, to form an exposed surface in the diagonal direction; and the lithium of the exposed surface is measured through time-of-flight secondary ion mass spectrometry (TOF-SIMS) to measure a distribution of the lithium in the thickness direction of the hole-transporting layer and the electron-transporting layer.

A configuration example of a photoelectric conversion element will be described with reference to drawings.

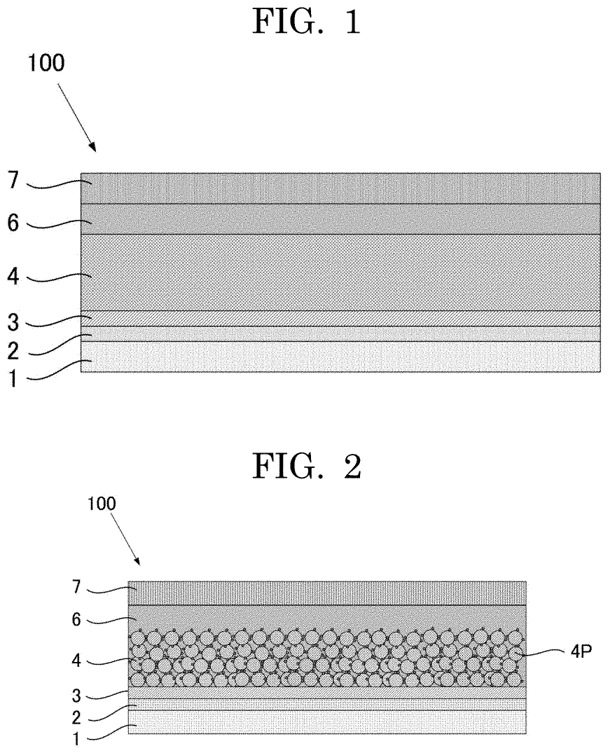

FIG. 1 is a cross-sectional view of one example of a photoelectric conversion element.

A photoelectric conversion element 100 includes a first substrate 1, a first electrode 2, a hole blocking layer 3, a photoelectric conversion layer, and a second electrode 7 in this order.

The photoelectric conversion layer includes an electron-transporting layer 4 and a hole-transporting layer 6.

FIG. 2 is a cross-sectional view of another example of a photoelectric conversion element.

A photoelectric conversion element 100 of FIG. 2 is an example where the electron-transporting layer 4 is produced by an electron-transporting semiconductor particle 4P including a photosensitization compound adsorbed on a surface thereof in the photoelectric conversion element 100 of FIG. 1. In this case, the hole-transporting material constituting the hole-transporting layer 6 exists between the electron-transporting semiconductor particles 4P in the electron-transporting layer 4. In this case, the electron-transporting layer 4 represents a region including the electron-transporting semiconductor particle 4P, and also includes, for example, the hole-transporting material included between the electron-transporting semiconductor particles 4P. Meanwhile, the hole-transporting layer 6 represents an upper region of the photoelectric conversion layer where the electron-transporting semiconductor particle 4P does not exist.

Specific examples of the measurement methods (1) and (2) will be described hereinafter.

### <Measurement Method (1): GCIB/TOF-SIMS>

To put it simply, the measurement method (1) is a method where etching is performed by a gas cluster ion beam from a surface side to measure lithium through TOF-SIMS.

The TOF-SIMS (time-of-flight secondary ion mass spectrometry) is a method where a solid sample is irradiated with a primary ion and a secondary ion generated from the surface is subjected to mass spectrometry. The TOF-SIMS can analyze a top surface.

When the TOF-SIMS is used to perform analysis in a depth direction (thickness direction), a profile in the depth direction is obtained while etching and the TOF-SIMS are alternately repeated. At this time, a gas cluster ion beam (GCIB) is used for etching. The gas cluster ion beam is ion beam formed of about several thousands of gas atoms (molecules) such as argon, and enables ion beam etching in which energy per one atom is considerably low. Therefore, almost no chemical change derived from the irradiated ion is found on the surface obtained after the etching.

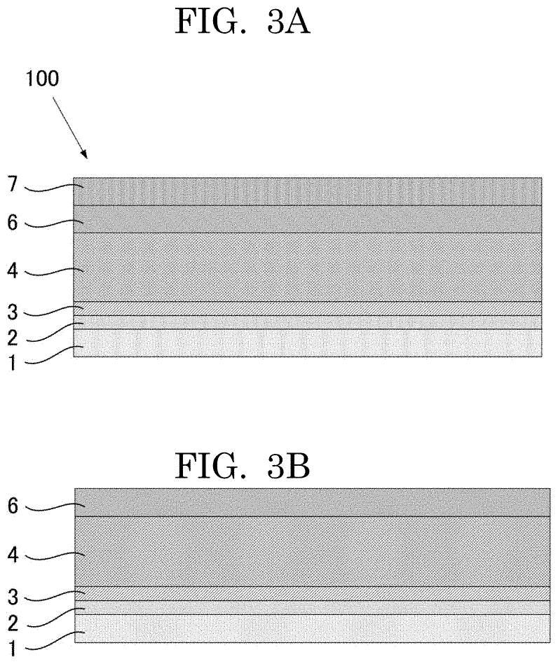

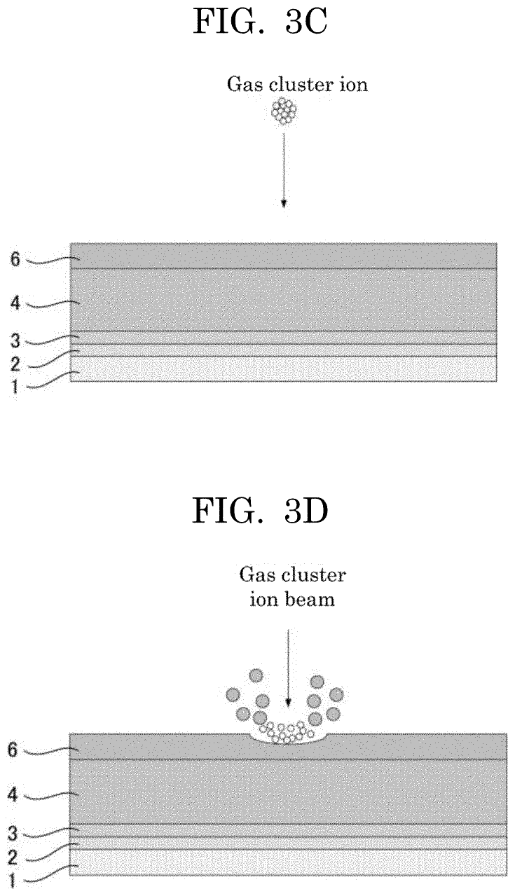

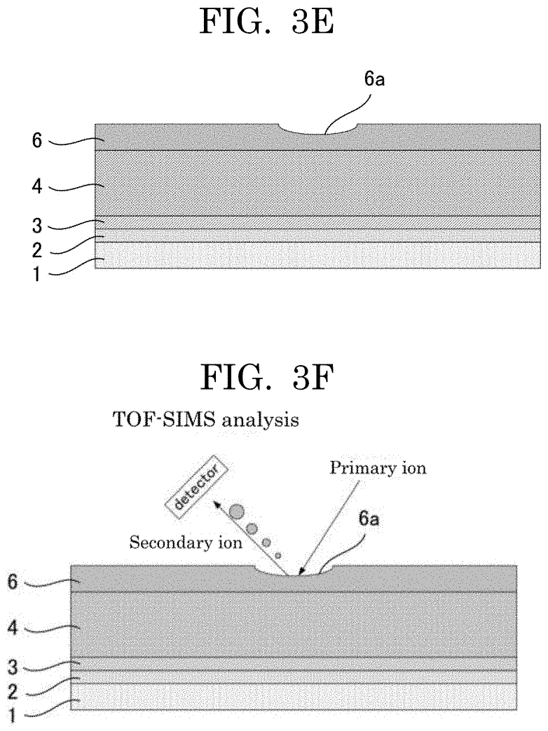

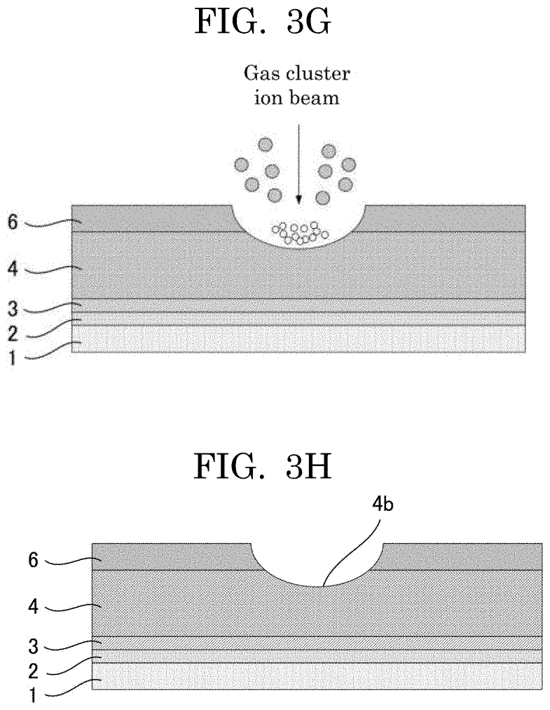

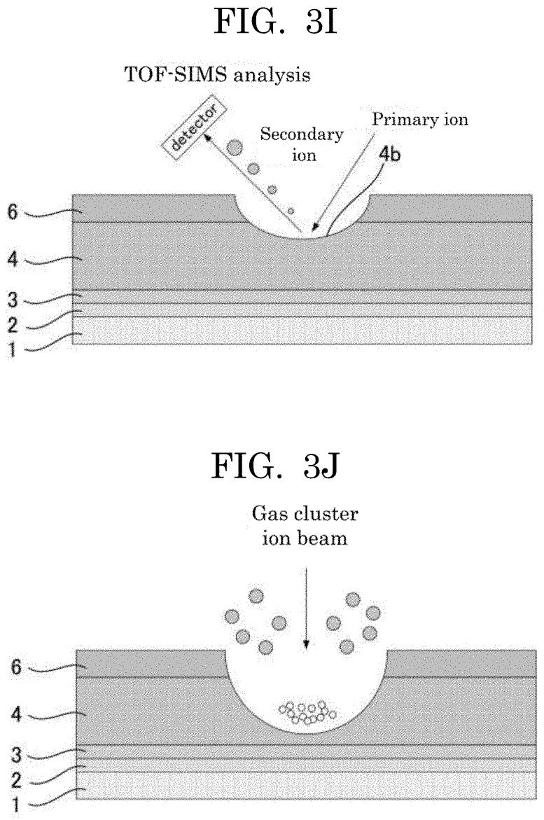

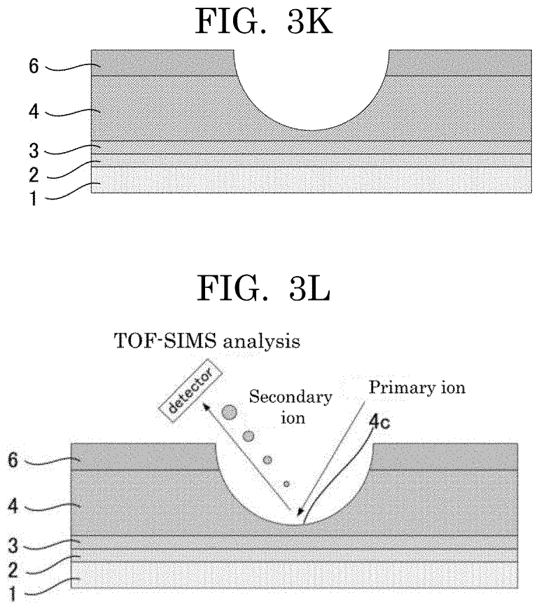

The measurement method (1) will be described with reference to FIG. 3A to FIG. 3L.

First, a photoelectric conversion element 100 is provided (FIG. 3A).

Next, a second electrode 7 is removed (FIG. 3B). The removal method is not particularly limited and may be appropriately selected depending on the intended purpose. In addition to, for example, a chemical etching and a physical etching, the second electrode 7 may be removed by exfoliating it by a piece of adhesive tape in some cases.

Then, a hole-transporting layer 6 is irradiated with a gas cluster ion beam of Ar (FIG. 3C).

As a result, the hole-transporting layer 6 is cut, to form a new exposed surface 6a (FIG. 3D and FIG. 3E).

The formed exposed surface 6a is subjected to the TOF-SIMS analysis. That is, the exposed surface 6a is irradiated with a primary ion, and a secondary ion generated from the exposed surface 6a is detected by a detector, to perform identification (FIG. 3F).

The gas cluster ion beam of Ar is further applied thereto (FIG. 3G), to form a new exposed surface 4b (FIG. 3H).

The formed exposed surface 4b is subjected to the TOF-SIMS (FIG. 3I).

Irradiation of the gas cluster ion beam and the TOF-SIMS are performed in the same manner as described above (FIG. 3J to FIG. 3L). This procedure is repeated to obtain a profile in the depth direction.

In the TOF-SIMS, when one of the detection targets includes a Li ion, a distribution of the Li ion of the hole-transporting layer and the electron-transporting layer in the thickness direction can be obtained.

In the case where one of the hole-transporting layer and the electron-transporting layer includes a large amount of an inorganic material and the other includes no inorganic material or a small amount of the inorganic material, the ion beam having the same intensity is applied to both the hole-transporting layer and the electron-transporting layer at the time of irradiation of the gas cluster ion beam, both the hole-transporting layer and the electron-transporting layer cannot be cut well. Therefore, when one of the hole-transporting layer and the electron-transporting layer includes an inorganic material, and the other includes no inorganic material, it is preferable that the intensity of the ion beam or the sputter time be changed depending on each layer at the time of irradiation of the gas cluster ion beam. For example, when the hole-transporting layer includes a small amount of the inorganic material and the electron-transporting layer includes a large amount of the inorganic material, the intensity of the ion beam for cutting the electron-transporting layer is preferably higher than the intensity of the ion beam for cutting the hole-transporting material, or the sputter time for cutting the electron-transporting layer is preferably longer than the sputter time for cutting the hole-transporting material.

### <Measurement Method (2): SAICAS/TOF-SIMS>

To put it simply, the measurement method (2) is a method where a sample is diagonally cut by a surface and interfacial cutting analysis system (SAICAS) method, and lithium on the diagonal surface is measured through TOF-SIMS.

When the depth direction (thickness direction) is analyzed using the TOF-SIMS, there is a method other than the method (1) where a sample is cut in a diagonal direction in place of etching, to expose a surface to be measured, and a profile of the surface to be measured is obtained. At this time, the cutting in the diagonal direction is performed using a SAICAS method.

The SAICAS method is a method for determining the exfoliation strength and the shear strength of a film. The cutting method at this time can be used for cutting a sample in a diagonal direction.

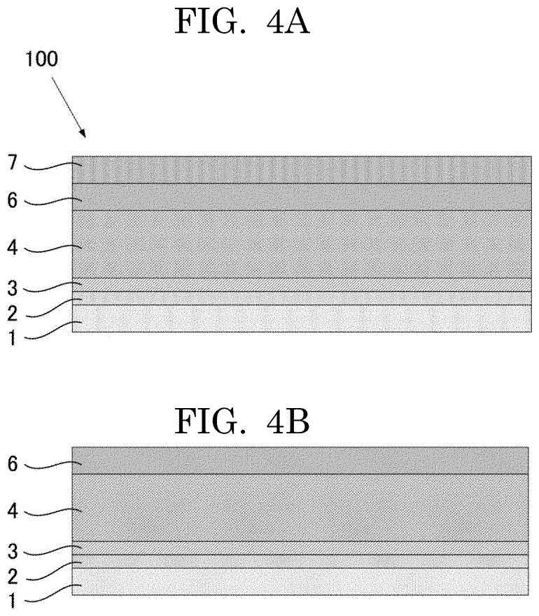

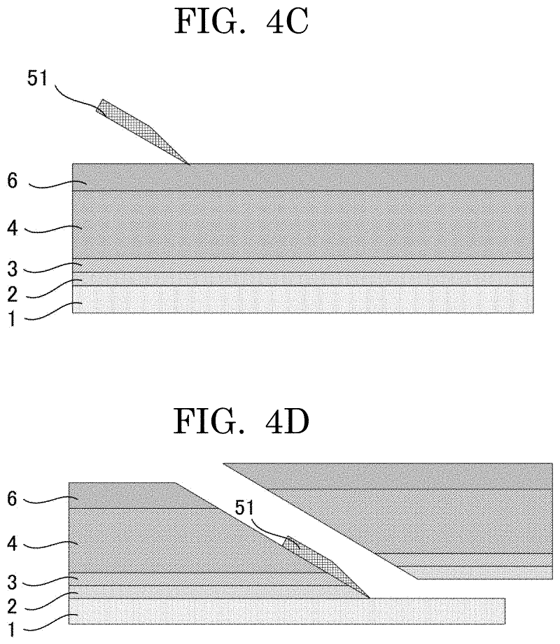

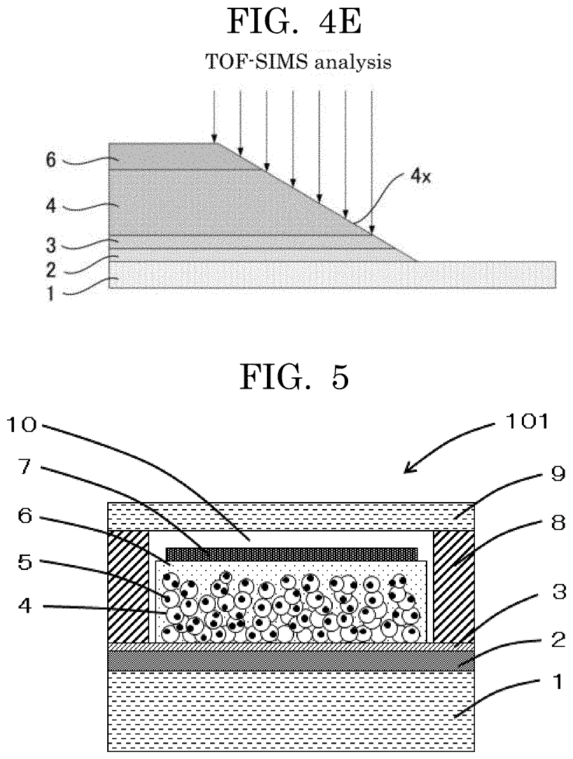

The measurement method (2) will be described with reference to FIG. 4A to FIG. 4E.

First, a photoelectric conversion element 100 is provided (FIG. 4A).

Next, a second electrode 7 is removed (FIG. 4B). The removal method is not particularly limited and may be appropriately selected depending on the intended purpose. In addition to, for example, a chemical etching and a physical etching, the second electrode 7 may be removed by exfoliating it by a piece of adhesive tape in some cases.

Then, a cutting blade 51 used in the SAICAS method is applied to a surface of the hole-transporting layer 6 so that the cutting direction is a diagonal direction relative to the thickness direction (FIG. 4C).

The cutting blade 51 is inserted in the diagonal direction, to cut the hole-transporting layer 6 and the electron-transporting layer 4 in the diagonal direction (FIG. 4D).

An exposed surface 4x that is an exposed diagonal surface is subjected to the TOF-SIMS, to measure a distribution of lithium (FIG. 4E).

As a result, a profile in the depth direction is obtained. At this time, the cutting length through SAICAS preferably falls within a measurement range of the TOF-SIMS. When the measurement is performed at a constant-speed mode, a vertical speed and a horizontal speed are adjusted, so that the cutting length falls within a measurement range and information on the material distributions of the hole-transporting layer and the electron-transporting layer can be sufficiently obtained.

A ratio (I_{E}/I_{H}) of an average value (I_{E}) of ionic intensities of the lithium included in the electron-transporting layer to an average value (I_{H}) of ionic intensities of the lithium included in the hole-transporting layer is not particularly limited and may be appropriately selected depending on the intended purpose, so long as the ratio (I_{E}/I_{H}) is more than 1. The ratio (I_{E}/I_{H}) is preferably 10 or more, more preferably 100 or more, still more preferably 300 or more. When the ratio (I_{E}/I_{H}) falls within the particularly preferable range, a high output can be obtained even with light of a low illuminance, and its persistence is enhanced, which is advantageous. Meanwhile, the upper limit is not particularly restricted, but is preferably 500 or less.

A larger amount of the lithium ion included in the electron-transporting layer is effective in the present disclosure. It is believed that as the ratio (I_{E}/I_{H}) is larger, an amount of migration of the lithium ion from the hole-transporting layer to the electron-transporting layer is larger, and therefore an amount of the lithium ion included in the electron-transporting layer is larger, further enhancing the effects of the present disclosure.

A ratio (I_{E}/I_{E2}) of an average value (I_{E}) of ionic intensities of the lithium included in the electron-transporting layer to an average value (I_{E2}) of ionic intensities of the electron-transporting material included in the electron-transporting layer is not particularly limited and may be appropriately selected depending on the intended purpose. The ratio (I_{E}/I_{E2}) is preferably 1 or more, more preferably 1.5 or more, still more preferably 2 or more, particularly preferably 5 or more. For example, when the electron-transporting material includes titanium oxide, the (I_{E2}) means an average value of ionic intensities of TiO. It is believed that as the ratio (I_{E}/I_{E2}) is larger, an amount of the lithium ion included in the electron-transporting layer is larger, further enhancing the effects of the present disclosure. Meanwhile, the upper limit is not particularly restricted, but is, for example, 10 or less.

Hereinafter, details of the respective configurations will be described.

### <Substrate>

A shape, structure, and size of the substrate are not particularly limited and may be appropriately selected depending on the intended purpose.

A material of the substrate is preferably a material having transparency and an insulation property. Examples of the material include glass, plastic films, and ceramics. Among them, a material having heat resistance against a firing temperature is preferable when the firing step is performed to form the electron-transporting layer. Moreover, the substrate is preferably a substrate having flexibility.

The substrate may be disposed on an outermost part at a side of the first electrode of the photoelectric conversion element, may be disposed on an outermost part at a side of the second electrode of the photoelectric conversion element, or may be disposed on both the outermost part at the side of the first electrode of the photoelectric conversion element and the outermost part at the side of the second electrode of the photoelectric conversion element.

Hereinafter, the substrate disposed on the outermost part at the side of the first electrode is referred to as a first substrate, and the substrate disposed on the outermost part at the side of the second electrode is referred to as a second substrate.

An average thickness of the substrate is not particularly limited and may be appropriately selected depending on the intended purpose. The average thickness of the substrate is, for example, 50 μm or more but 5 mm or less.

### <First Electrode>

A shape and size of the first electrode are not particularly limited and may be appropriately selected depending on the intended purpose.

A structure of the first electrode is not particularly limited and may be appropriately selected depending on the intended purpose. The structure of the first electrode may be a single layer structure or may be a structure where a plurality of materials are stacked.

A material of the first electrode is not particularly limited and may be appropriately selected depending on the intended purpose, so long as it has conductivity. Examples of the material include transparent conductive metal oxides, carbon, and metals.

Examples of the transparent conductive metal oxide include indium-tin oxide (referred to as “ITO” hereinafter), fluorine-doped tin oxide (referred to as “FTO” hereinafter), antimony-doped tin oxide (referred to as “ATO” hereinafter), niobium-doped tin oxide (referred to as “NTO” hereinafter), aluminum-doped zinc oxide (referred to as AZO” hereinafter), indium-zinc oxide, and niobium-titanium oxide.

Examples of the carbon include carbon black, carbon nanotube, graphene, and fullerene.

Examples of the metal include gold, silver, aluminum, nickel, indium, tantalum, and titanium.

These may be used alone or in combination. Among them, a transparent conductive metal oxide having high transparency is preferable, and ITO, FTO, ATO, NTO, and AZO are more preferable.

An average thickness of the first electrode is not particularly limited and may be appropriately selected depending on the intended purpose. The average thickness of the first electrode is preferably 5 nm or more but 100 μm or less, more preferably 50 nm or more but 10 μm or less. When a material of the first electrode is carbon or a metal, the average thickness of the first electrode is preferably an enough average thickness to obtain translucency.

The first electrode can be formed by known methods such as the sputtering method, the vapor deposition method, and the spray method.

The first electrode is preferably formed on the substrate. An integrated commercially available product where the first electrode is formed on the substrate in advance can be used.

Examples of the integrated commercially available product include FTO-coated glass, ITO-coated glass, zinc oxide, aluminum-coated glass, FTO-coated transparent plastic films, and ITO-coated transparent plastic films. Examples of other integrated commercially available products include: a glass substrate provided with a transparent electrode where tin oxide or indium oxide is doped with a cation or an anion having a different atomic value; and a glass substrate provided with a metal electrode having such a structure that allows light in the form of a mesh or stripes to pass.

These may be used alone, or two or more products may be used in combination as a mixed product or a laminate. Moreover, a metal lead wire may be used in combination in order to decrease an electric resistance value.

In order to produce a photoelectric conversion module that will be described hereinafter, an electrode of an integrated commercially available product may be appropriately processed to produce a substrate on which a plurality of first electrodes are formed.

A material of the metal lead wire is, for example, aluminum, copper, silver, gold, platinum, and nickel.

The metal lead wire can be used in combination by forming it on the substrate through, for example, vapor deposition, sputtering, or pressure bonding, and disposing a layer of ITO or FTO thereon or disposing it on ITO or FTO.

### <Hole Blocking Layer>

In order to prevent a decrease in electric power, which is caused when a hole-transporting layer contacts an electrode to recombine holes in the hole-transporting layer and electrons on the surface of the electrode (i.e., reverse electron transfer), the hole blocking layer is provided. An effect of the hole blocking layer is particularly significant in a solid-dye-sensitization-type solar cell. The reason for this is attributed to the fact that the solid-dye-sensitization-type solar cell containing, for example, an organic hole-transporting material has a rapider rate of recombination (reverse electron transfer) of holes in the hole-transporting material and electrons on the surface of the electrode compared to a wet-dye-sensitization-type solar cell containing, for example, an electrolytic solution.

The hole blocking layer is disposed on, for example, the first electrode.

A material of the hole blocking layer is not particularly limited and may be appropriately selected depending on the intended purpose, so long as it is transparent to a visible light and is an electron-transporting material. Examples of the material include titanium oxide, niobium oxide, magnesium oxide, aluminum oxide, zinc oxide, tungsten oxide, and tin oxide. Among them, titanium oxide is more preferable. These may be used alone or in combination.

A film formation method of the hole blocking layer is not particularly limited and may be appropriately selected depending on the intended purpose. In order to prevent electric current loss with indoor light, a high internal resistance is required, and the film formation method is also important. Generally, examples thereof include a sol-gel method that is a wet film formation method. However, such a method cannot achieve a sufficiently high film density, and cannot sufficiently prevent electric current loss. Therefore, the film formation method is more preferably a dry film formation method such as a sputtering method, and such a method can achieve a sufficiently high film density, to prevent electric current loss.

An average thickness of the hole blocking layer is not particularly limited and may be appropriately selected depending on the intended purpose. In terms of a transmittance and prevention of reverse electron transfer, the average thickness of the hole blocking layer is preferably 5 nm or more but 1,000 nm or less, more preferably 500 nm or more but 700 nm or less in the case of the wet film formation method, and more preferably 10 nm or more but 30 nm or less in the case of the dry film formation method.

### <Photoelectric Conversion Layer>

The photoelectric conversion layer includes an electron-transporting layer and a hole-transporting layer, and further includes other members if necessary.

### <<Electron-Transporting Layer>>

The electron-transporting layer includes an electron-transporting semiconductor.

The electron-transporting layer preferably includes an electron-transporting semiconductor including a photosensitization compound adsorbed on a surface thereof.

The electron-transporting layer is disposed on, for example, the hole blocking layer.

The electron-transporting layer may be a single layer or a multilayer.

As the electron-transporting semiconductor, an electron-transporting semiconductor particle is preferably used.

In the case of a multilayer, a dispersion liquid of semiconductor particles different in particle diameters may be coated to form a multilayer, or different kinds of semiconductors or coating layers having formulation different in a resin and an additive may be coated to form a multilayer.

Note that, when a film thickness obtained after one coating is insufficient, the multilayer coating is an effective means.

Generally, as an average thickness of the electron-transporting layer increases, an amount of the born photosensitization material per a unit projected area also increases. Therefore, a light trapping rate increases, but a diffusion length of injected electrons also increases, which results in a large loss due to recombination of electric charges. Therefore, the average thickness of the electron-transporting layer is preferably 100 nm or more but 100 μm or less.

The electron-transporting semiconductor is not particularly limited and may be appropriately selected depending on the intended purpose. Examples of the electron-transporting semiconductor include: simple substance semiconductors such as silicon and germanium; compound semiconductors such as chalcogenides of metal; and compounds having a perovskite structure. These may be used alone or in combination.

Examples of the chalcogenides of metal include: oxides of, for example, titanium, tin, zinc, iron, tungsten, zirconium, hafnium, strontium, indium, cerium, yttrium, lanthanum, vanadium, niobium, and tantalum; sulfides of, for example, cadmium, zinc, lead, silver, antimony, and bismuth; selenides of, for example, cadmium and lead; and tellurium compounds of, for example, cadmium.

Examples of the other compound semiconductors include: phosphides of zinc, gallium, indium, and cadmium; gallium arsenide; copper-indium-selenide, and copper-indium-sulfide.

Examples of the compound having a perovskite structure include strontium titanate, calcium titanate, sodium titanate, barium titanate, and potassium niobate.

Among the electron-transporting semiconductors, oxide semiconductors are preferable, titanium oxide, zinc oxide, tin oxide, and niobium oxide are more preferable, and titanium oxide is particularly preferable.

A crystal type of the electron-transporting semiconductor is not particularly limited and may be appropriately selected depending on the intended purpose. The crystal type may be a single crystal, polycrystalline, or amorphous.

A size of the semiconductor particle is not particularly limited and may be appropriately selected depending on the intended purpose. An average particle diameter of primary particles is preferably 1 nm or more but 100 nm or less, more preferably 5 nm or more but 50 nm or less.

Moreover, an effect of diffusing incident light achieved by mixing or stacking a semiconductor particle having a larger average particle diameter may improve efficiency. In this case, an average particle diameter of the semiconductor particle is preferably 50 nm or more but 500 nm or less.

A production method of the electron-transporting layer is not particularly limited and may be appropriately selected depending on the intended purpose. Examples of the production method include a method such as sputtering where a thin film is formed in vacuum, and a wet film formation method. Among them, in terms of production cost, it is preferable to use a wet film formation method, and it is particularly preferable to use a method where paste obtained by dispersing particles or sol of a semiconductor is prepared, and then the paste is coated onto the hole blocking layer.

When the wet film formation method is used, a coating method is not particularly limited and may be appropriately selected depending on the intended purpose. Examples of the coating method include the dip method, the spray method, the wire bar method, the spin-coating method, the roller coating method, the blade coating method, and the gravure coating method. Examples of a wet printing method include relief printing, offset printing, gravure printing, intaglio printing, rubber plate printing, and screen printing.

When the dispersion liquid of the semiconductor particle is prepared by using mechanical pulverization or a mill, at least a semiconductor particle alone or a mixture of a semiconductor particle and a resin is dispersed in water or an organic solvent to prepare the dispersion liquid.

The resin is not particularly limited and may be appropriately selected depending on the intended purpose. Examples of the resin include polymers or copolymers of vinyl compounds (e.g., styrene, vinyl acetate, acrylic acid ester, and methacrylic acid ester), silicone resins, phenoxy resins, polysulfone resins, polyvinyl butyral resins, polyvinyl formal resins, polyester resins, cellulose ester resins, cellulose ether resins, urethane resins, phenol resins, epoxy resins, polycarbonate resins, polyarylate resins, polyamide resins, and polyimide resins. These may be used alone or in combination.

Examples of the solvent include water, alcohol solvents, ketone solvents, ester solvents, ether solvents, amide solvents, halogenated hydrocarbon solvents, and hydrocarbon solvents.

Examples of the alcohol solvent include methanol, ethanol, isopropyl alcohol, and α-terpineol.

Examples of the ketone solvent include acetone, methyl ethyl ketone, and methyl isobutyl ketone.

Examples of the ester solvent include ethyl formate, ethyl acetate, and n-butyl acetate.

Examples of the ether solvent include diethyl ether, dimethoxy ethane, tetrahydrofuran, dioxolane, and dioxane.

Examples of the amide solvent include N,N-dimethylformamide, N,N-dimethylacetamide, and N-methyl-2-pyrrolidone.

Examples of the halogenated hydrocarbon solvent include dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene.

Examples of the hydrocarbon solvent include n-pentane, n-hexane, n-octane, 1,5-hexadiene, cyclohexane, methylcyclohexane, cyclohexadiene, benzene, toluene, o-xylene, m-xylene, p-xylene, ethylbenzene, and cumene.

These may be used alone or in combination.

To the dispersion liquid of the semiconductor particle or the paste of the semiconductor particle obtained by, for example, the sol-gel method, acid, a surfactant, or a chelating agent may be added in order to prevent re-aggregation of the particles.

Examples of the acid include hydrochloric acid, nitric acid, and acetic acid.

Examples of the surfactant include polyoxyethylene octylphenyl ether.

Examples of the chelating agent include acetyl acetone, 2-aminoethanol, and ethylene diamine.

Moreover, addition of a thickener is also an effective means for the purpose of improving a film formation property.

Examples of the thickener include polyethylene glycol, polyvinyl alcohol, and ethyl cellulose.

In order to electronically contact particles with each other after the coating to improve strength of a film and adhesiveness to a substrate, the semiconductor particle is preferably subjected to firing, irradiation of microwave, irradiation of electron rays, and irradiation of laser light. These treatments may be performed alone or in combination.

When the firing is performed, the firing temperature is not particularly limited and may be appropriately selected depending on the intended purpose. When the firing temperature is increased too much, a resistance of the substrate may be increased or melting may occur. Therefore, the firing temperature is preferably 30° C. or more but 700° C. or less, more preferably 100° C. or more but 600° C. or less. The firing time is not particularly limited and may be appropriately selected depending on the intended purpose, but is preferably 10 minutes or more but 10 hours or less.

The microwave may be emitted from a side at which the electron-transporting layer is formed, or may be emitted from the back side. The irradiation time of the microwave is not particularly limited and may be appropriately selected depending on the intended purpose. The irradiation time of the microwave is preferably one hour or shorter.

After firing, for example, chemical plating using an aqueous solution of titanium tetrachloride or a mixed solution with an organic solvent, or electrochemical plating using an aqueous solution of titanium trichloride may be performed in order to increase a surface area of the semiconductor particle or enhance an electron injection efficiency to the semiconductor particle from the photosensitization compound.

A stacked film, which is obtained by, for example, firing the semiconductor particle having a diameter of several tens of nanometers, can form a porous state. Such a nanoporous structure has an extremely high surface area, and the surface area can be represented by using a roughness factor.

The roughness factor is a numerical value representing an actual area of the inner sides of pores relative to an area of the semiconductor particles coated onto the substrate. Therefore, the roughness factor is preferably larger. However, in terms of a relationship with a thickness of the electron-transporting layer, the roughness factor is preferably 20 or more.

### <<Photosensitization Compound>>

In the present disclosure, the photosensitization compound is preferably adsorbed on the surface of the electron-transporting semiconductor of the electron-transporting layer in order to further improve the conversion efficiency.

The photosensitization compound is not particularly limited and may be appropriately selected depending on the intended purpose so long as the photosensitization compound is a compound photoexcited by excitation light to be used. Examples of the photosensitization compound include: metal complex compounds described in, for example, Japanese Translation of PCT International Application Publication No. 7-500630, Japanese Unexamined Patent Application Publication No. 10-233238, Japanese Unexamined Patent Application Publication No. 2000-26487, Japanese Unexamined Patent Application Publication No. 2000-323191, and Japanese Unexamined Patent Application Publication No. 2001-59062; coumarine compounds described in, for example, Japanese Unexamined Patent Application Publication No. 10-93118, Japanese Unexamined Patent Application Publication No. 2002-164089, Japanese Unexamined Patent Application Publication No. 2004-95450, and J. Phys. Chem. C, 7224, Vol. 111 (2007); polyene compounds described in, for example, Japanese Unexamined Patent Application Publication No. 2004-95450 and Chem. Commun., 4887 (2007); indoline compounds described in, for example, Japanese Unexamined Patent Application Publication No. 2003-264010, Japanese Unexamined Patent Application Publication No. 2004-63274, Japanese Unexamined Patent Application Publication No. 2004-115636, Japanese Unexamined Patent Application Publication No. 2004-200068, Japanese Unexamined Patent Application Publication No. 2004-235052, J. Am. Chem. Soc., 12218, Vol. 126 (2004), Chem. Commun., 3036 (2003), and Angew. Chem. Int. Ed., 1923, Vol. 47 (2008); thiophene compounds described in, for example, J. Am. Chem. Soc., 16701, Vol. 128 (2006) and J. Am. Chem. Soc., 14256, Vol. 128 (2006); cyanine dyes described in, for example, Japanese Unexamined Patent Application Publication No. 11-86916, Japanese Unexamined Patent Application Publication No. 11-214730, Japanese Unexamined Patent Application Publication No. 2000-106224, Japanese Unexamined Patent Application Publication No. 2001-76773, and Japanese Unexamined Patent Application Publication No. 2003-7359; merocyanine dyes described in, for example, Japanese Unexamined Patent Application Publication No. 11-214731, Japanese Unexamined Patent Application Publication No. 11-238905, Japanese Unexamined Patent Application Publication No. 2001-52766, Japanese Unexamined Patent Application Publication No. 2001-76775, and Japanese Unexamined Patent Application Publication No. 2003-7360; 9-arylxanthene compounds described in, for example, Japanese Unexamined Patent Application Publication No. 10-92477, Japanese Unexamined Patent Application Publication No. 11-273754, Japanese Unexamined Patent Application Publication No. 11-273755, and Japanese Unexamined Patent Application Publication No. 2003-31273; triarylmethane compounds described in, for example, Japanese Unexamined Patent Application Publication No. 10-93118 and Japanese Unexamined Patent Application Publication No. 2003-31273; and phthalocyanine compounds and porphyrin compounds described in, for example, Japanese Unexamined Patent Application Publication No. 9-199744, Japanese Unexamined Patent Application Publication No. 10-233238, Japanese Unexamined Patent Application Publication No. 11-204821, Japanese Unexamined Patent Application Publication No. 11-265738, J. Phys. Chem., 2342, Vol. 91 (1987), J. Phys. Chem. B, 6272, Vol. 97 (1993), Electroanal. Chem., 31, Vol. 537 (2002), Japanese Unexamined Patent Application Publication No. 2006-032260, J. Porphyrins Phthalocyanines, 230, Vol. 3 (1999), Angew. Chem. Int. Ed., 373, Vol. 46 (2007), and Langmuir, 5436, Vol. 24 (2008). Among them, metal complex compounds, coumarine compounds, polyene compounds, indoline compounds, and thiophene compounds are preferable, compounds expressed by the following Structural Formula (1), the following Structural Formula (2), and the following Structural Formula (3) (available from Mitsubishi Paper Mills Limited) are more preferable. These photosensitization compounds may be used alone or in combination.

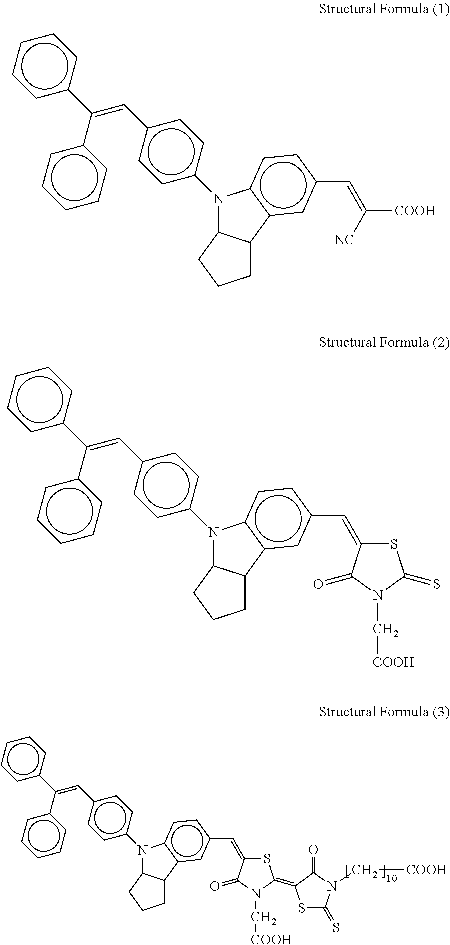

A compound including the following General Formula (1) is more preferable.

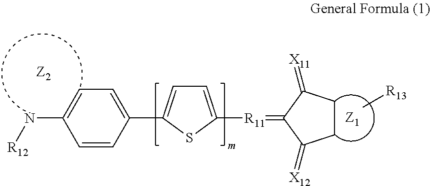

In General Formula (1), X₁₁ and X₁₂ each independently represent an oxygen atom, a sulfur atom, or a selenium atom.

R₁₁ represents a methine group that may have a substituent. Specific examples of the substituent include an aryl group (e.g., a phenyl group and a naphthyl group) and a heterocycle (e.g., a thienyl group and a furyl group).

R₁₂ represents an alkyl group that may have a substituent, an aryl group that may have a substituent, or a heterocyclic group that may have a substituent. Examples of the alkyl group include a methyl group, an ethyl group, a 2-propyl group, and a 2-ethylhexyl group. Examples of the aryl group and the heterocyclic group include the groups exemplified above.

R₁₃ represents an acid group such as carboxylic acid, sulfonic acid, phosphonic acid, boronic acid, or phenols. The number of R₁₃ may be one or more.

Z1 and Z2 each independently represent a substituent that forms a cyclic structure. Examples of Z1 include condensed hydrocarbon-based compounds (e.g., a benzene ring and a naphthalene ring) and heterocycles (e.g., a thiophene ring and a furan ring) each of which may have a substituent. Specific examples of the substituent include the alkyl groups and the alkoxy groups (e.g., a methoxy group, an ethoxy group, and a 2-isopropoxy group) described above. Examples of Z2 include the following (A-1) to (A-22).

m represents an integer of from 0 through 2.

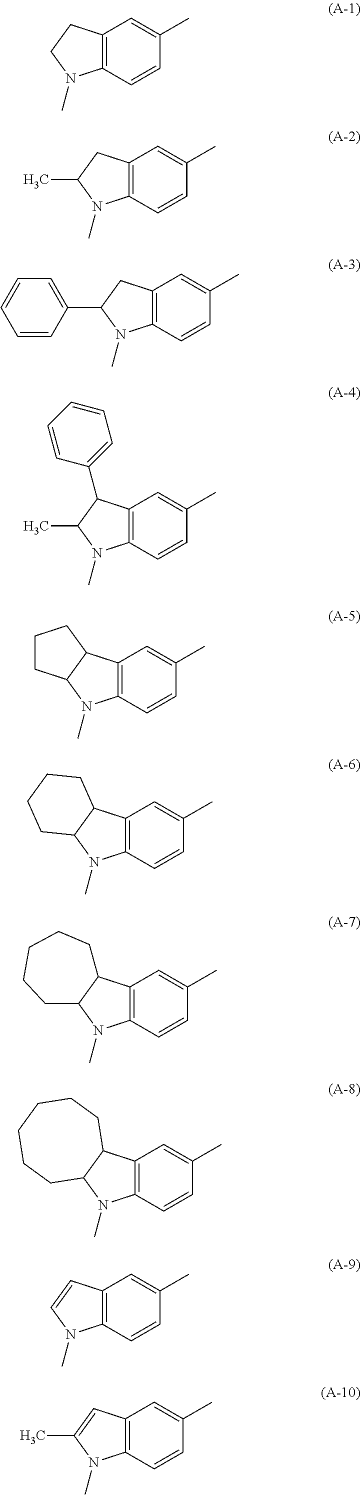

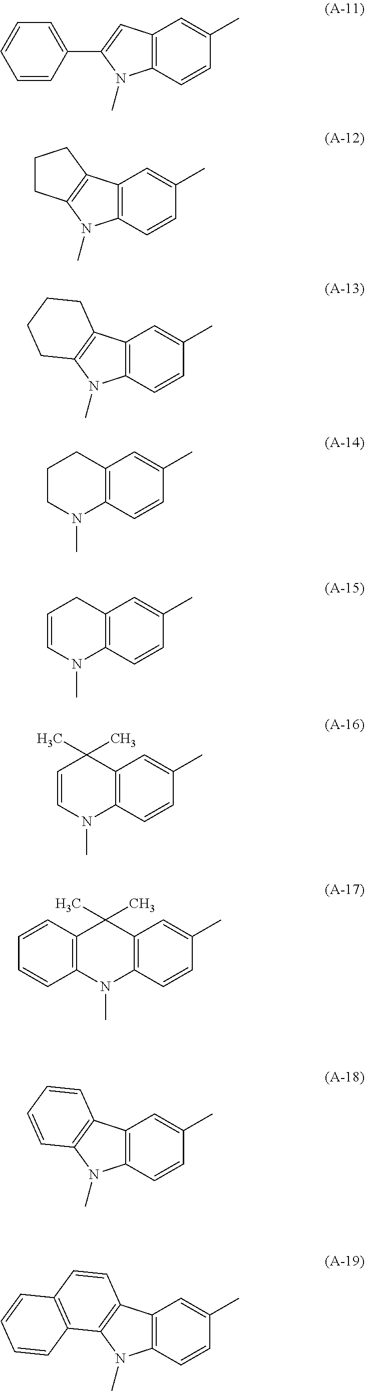

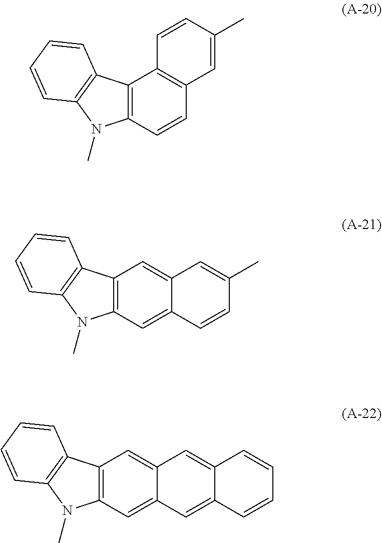 [SMILES: Cc1ccc2c(ccc3c2c2ccccc2n3C)c1 ; Cc1ccc2cc3c(cc2c1)c1ccccc1n3C ; Cn1c2ccccc2c2cc3cc4ccccc4cc3cc21]

Specific examples of the photosensitization compound including the General Formula (1) include, but are not limited to, the following (B-1) to (B-36).

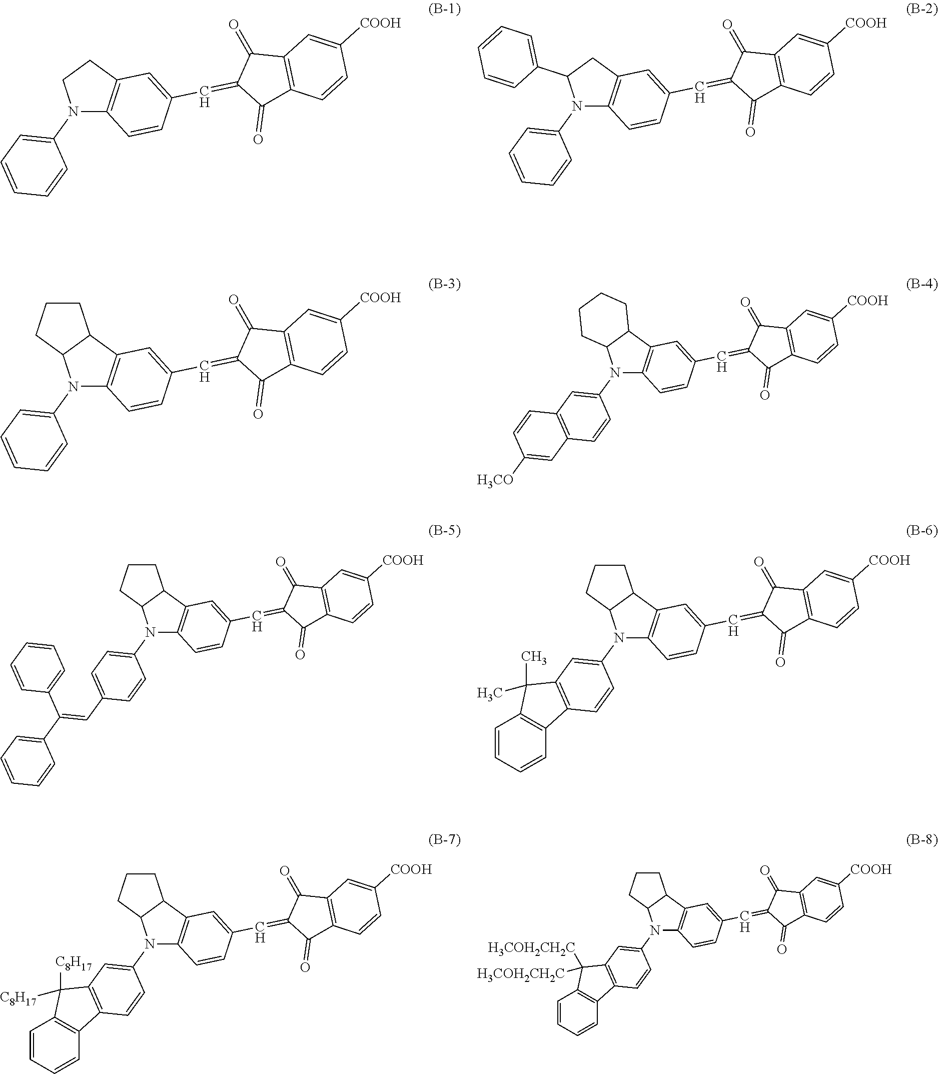

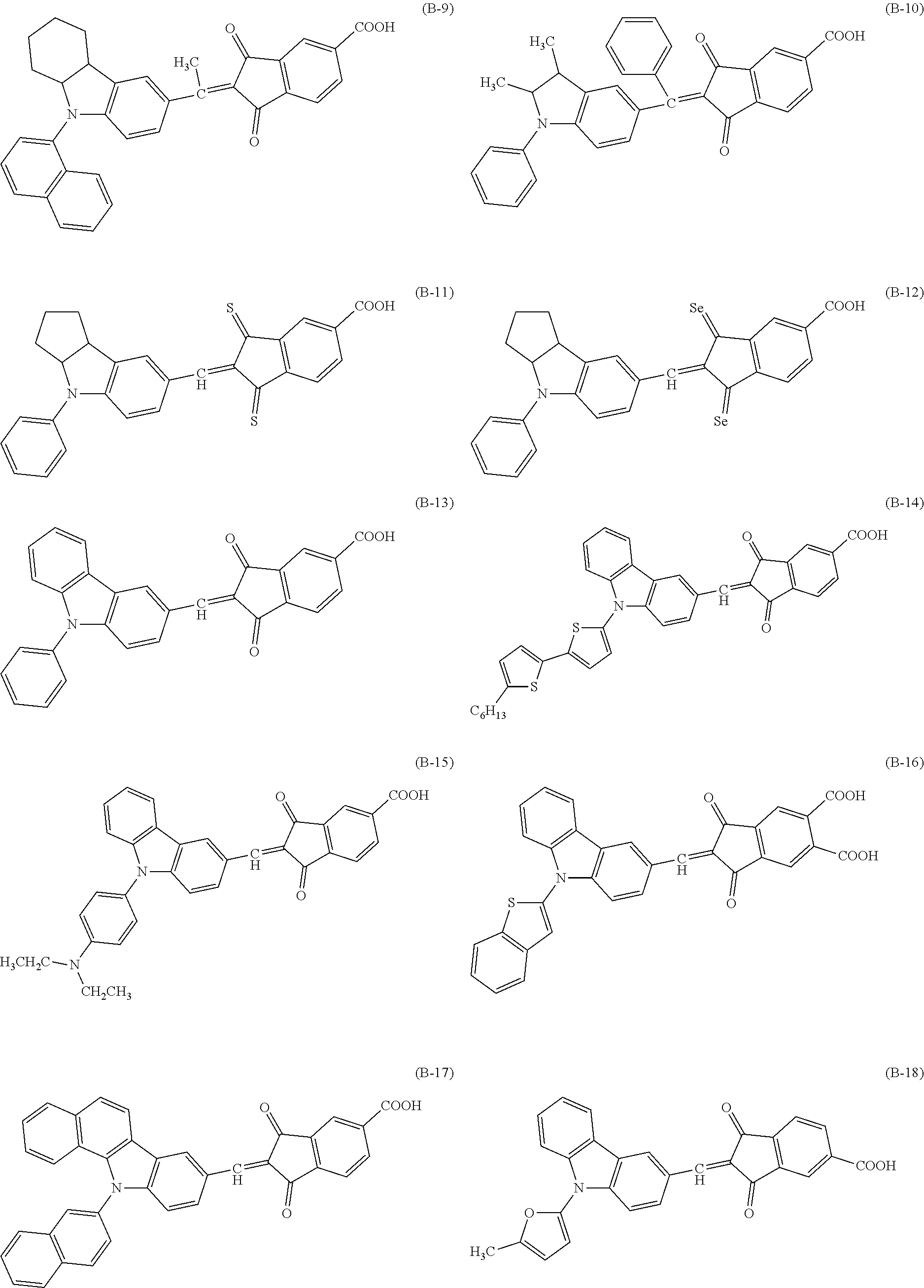

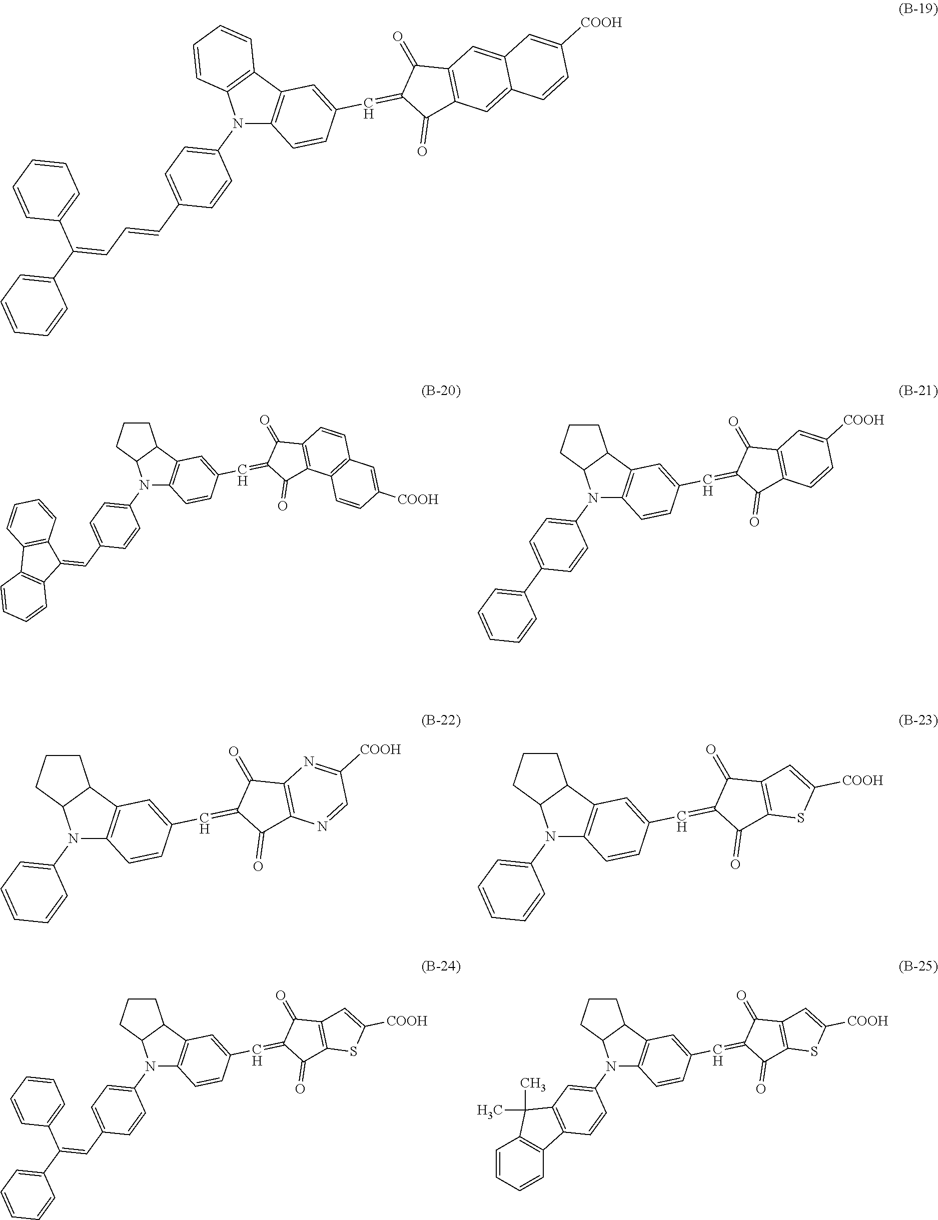

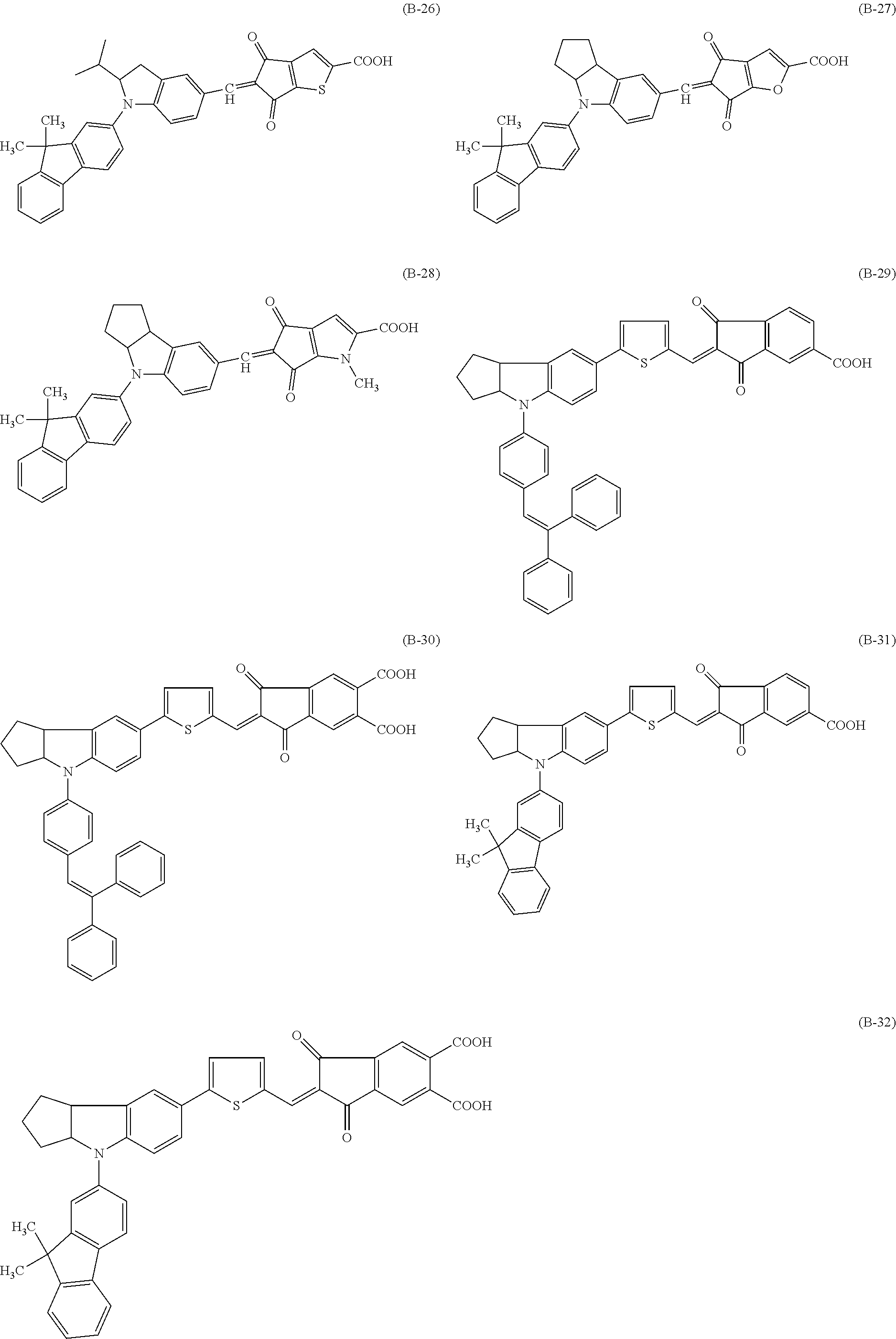

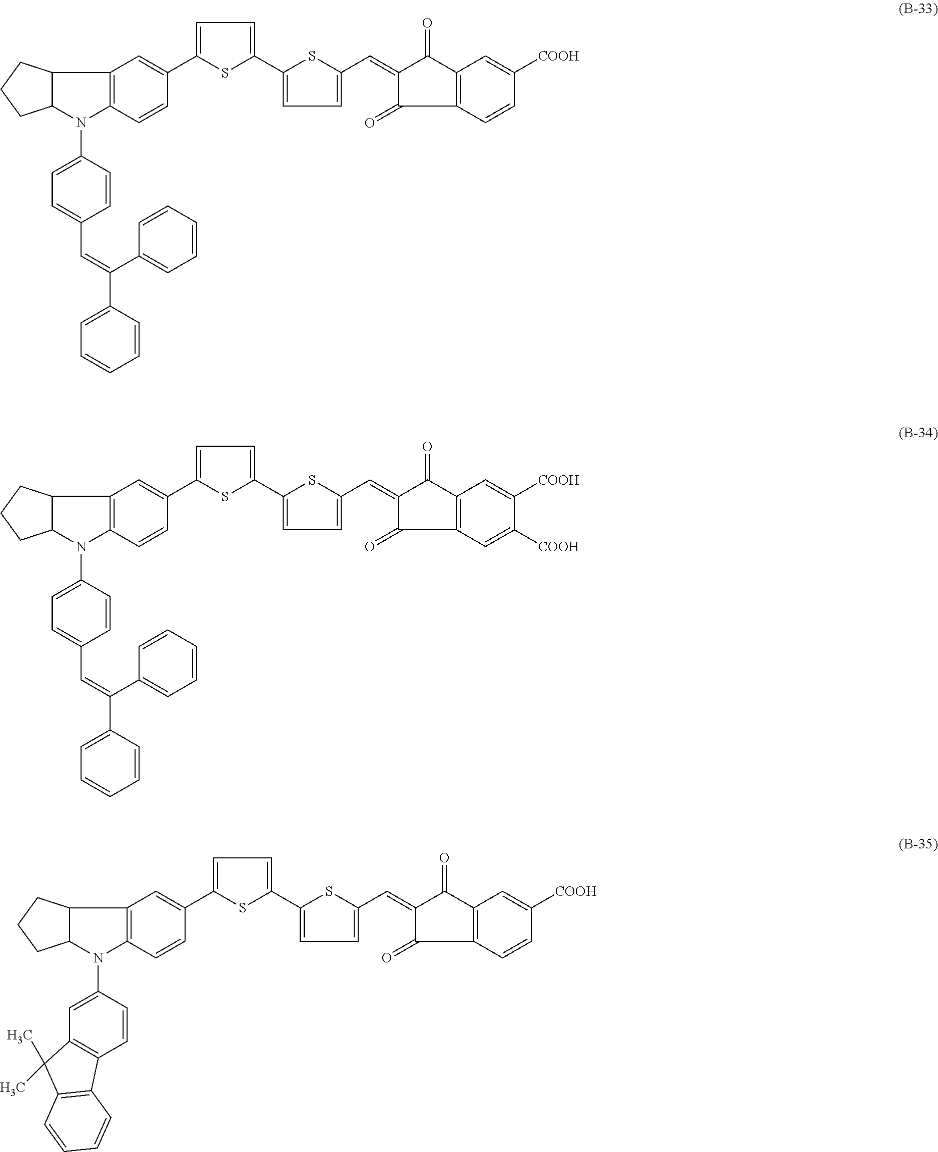

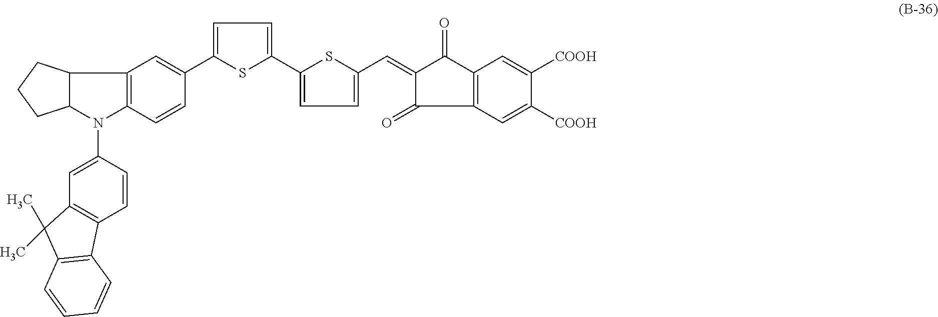

As a method for adsorbing the photosensitization compound on the electron-transporting semiconductor, for example, it is possible to use a method where an electron collecting electrode including an electron-transporting semiconductor particle is immersed in a solution or a dispersion liquid of the photosensitization compound, and a method where a solution or a dispersion liquid of the photosensitization compound is coated and adsorbed on the electron-transporting semiconductor.

Examples of the method where the electron collecting electrode including the electron-transporting semiconductor particle is immersed in the solution or the dispersion liquid of the photosensitization compound include the immersion method, the dip method, the roller method, and the air knife method.

Examples of the method where the solution or the dispersion liquid of the photosensitization compound is coated and adsorbed on the electron-transporting semiconductor include the wire bar method, the slide hopper coating method, the extrusion coating method, the curtain coating method, the spin-coating method, and the spray coating method.

Moreover, the photosensitization compound may be adsorbed in a supercritical fluid using, for example, carbon dioxide.

When the photosensitization compound is adsorbed, a condensing agent may be used in combination.

The condensing agent may be an agent exhibiting such a catalytic function that a photosensitization compound is physically or chemically bound to a surface of the electron-transporting semiconductor, or may be an agent that stoichiometrically acts and advantageously moves a chemical equilibrium.

Moreover, thiol or a hydroxyl compound may be added thereto as a condensation auxiliary.

Examples of the solvent that dissolves or disperses the photosensitization compound include water, alcohol solvents, ketone solvents, ester solvents, ether solvents, amide solvents, halogenated hydrocarbon solvents, and hydrocarbon solvents.

Examples of the alcohol solvent include methanol, ethanol, and isopropyl alcohol.

Examples of the ketone solvent include acetone, methyl ethyl ketone, and methyl isobutyl ketone.

Examples of the ester solvent include ethyl formate, ethyl acetate, and n-butyl acetate.

Examples of the ether solvent include diethyl ether, dimethoxy ethane, tetrahydrofuran, dioxolane, and dioxane.

Examples of the amide solvent include N,N-dimethylformamide, N,N-dimethylacetamide, and N-methyl-2-pyrrolidone.

Examples of the halogenated hydrocarbon solvent include dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene.

Examples of the hydrocarbon solvent include n-pentane, n-hexane, n-octane, 1,5-hexadiene, cyclohexane, methylcyclohexane, cyclohexadiene, benzene, toluene, o-xylene, m-xylene, p-xylene, ethylbenzene, and cumene.

These may be used alone or in combination.

Depending on kinds of photosensitization compounds, there is a photosensitization compound that functions more effectively when aggregation between compounds is prevented. Therefore, an aggregation dissociating agent may be used in combination.

The aggregation dissociating agent is not particularly limited and may be appropriately selected depending on a dye to be used. Examples of the aggregation dissociating agent include steroid compounds (e.g., cholic acid and chenodeoxycholic acid), long-chain alkyl carboxylic acid, and long-chain alkyl phosphonic acid.

An amount of the aggregation dissociating agent added is preferably 0.01 parts by mass or more but 500 parts by mass or less, more preferably 0.1 parts by mass or more but 100 parts by mass or less, relative to 1 part by mass of the photosensitization compound.

By using them, a temperature, at which the photosensitization compound, or the photosensitization compound and the aggregation dissociating agent are adsorbed, is preferably −50° C. or more but 200° C. or less.

The aforementioned adsorption may be performed under standing still or under stirring.

A stirring method is not particularly limited and may be appropriately selected depending on the intended purpose. Examples of the stirring method include a stirrer, a ball mill, a paint conditioner, a sand mill, Attritor, a disperser, and ultrasonic dispersion.

The time required for the adsorption is preferably 5 seconds or more but 1,000 hours or less, more preferably 10 seconds or more but 500 hours or less, still more preferably 1 minute or more but 150 hours or less.

The adsorption is preferably performed in the dark place.

### <<Hole-Transporting Layer>>

The hole-transporting layer includes at least an organic hole-transporting material and a lithium salt, and further includes other components if necessary.

The hole-transporting layer is preferably a solid.

The hole-transporting layer may be a single layer structure formed of a single material or may be a stacked structure formed of a plurality of compounds.

As an organic hole-transporting material used when the hole-transporting layer is a single layer structure, known organic hole-transporting compounds are used.

Specific examples thereof include oxadiazole compounds described in, for example, Japanese Examined Patent Publication No. 34-5466, triphenylmethane compounds described in, for example, Japanese Examined Patent Publication No. 45-555, pyrazoline compounds described in, for example, Japanese Examined Patent Publication No. 52-4188, hydrazone compounds described in, for example, Japanese Examined Patent Publication No. 55-42380, oxadiazole compounds described in, for example, Japanese Unexamined Patent Application Publication No. 56-123544, tetraarylbenzidine compounds described in, for example, Japanese Unexamined Patent Application Publication No. 54-58445, and stilbene compounds described in, for example, Japanese Unexamined Patent Application Publication No. 58-65440 or Japanese Unexamined Patent Application Publication No. 60-98437.

Among them, spiro compounds are particularly preferable. Examples of the Spiro compound include compounds including the following General Formula (4).

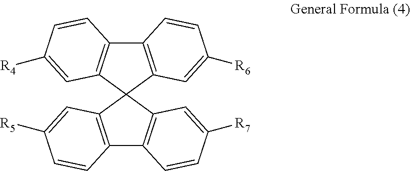

In the General Formula (4), R₄ to R₇ each independently represent a substituted amino group such as a dimethylamino group, a diphenylamino group, or a naphthyl-4-tolylamino group.

The spiro compound is not particularly limited and may be appropriately selected depending on the intended purpose. Examples of the Spiro compound include, but are not limited to, the following exemplified compounds D-1 to D-20. These may be used alone or in combination.

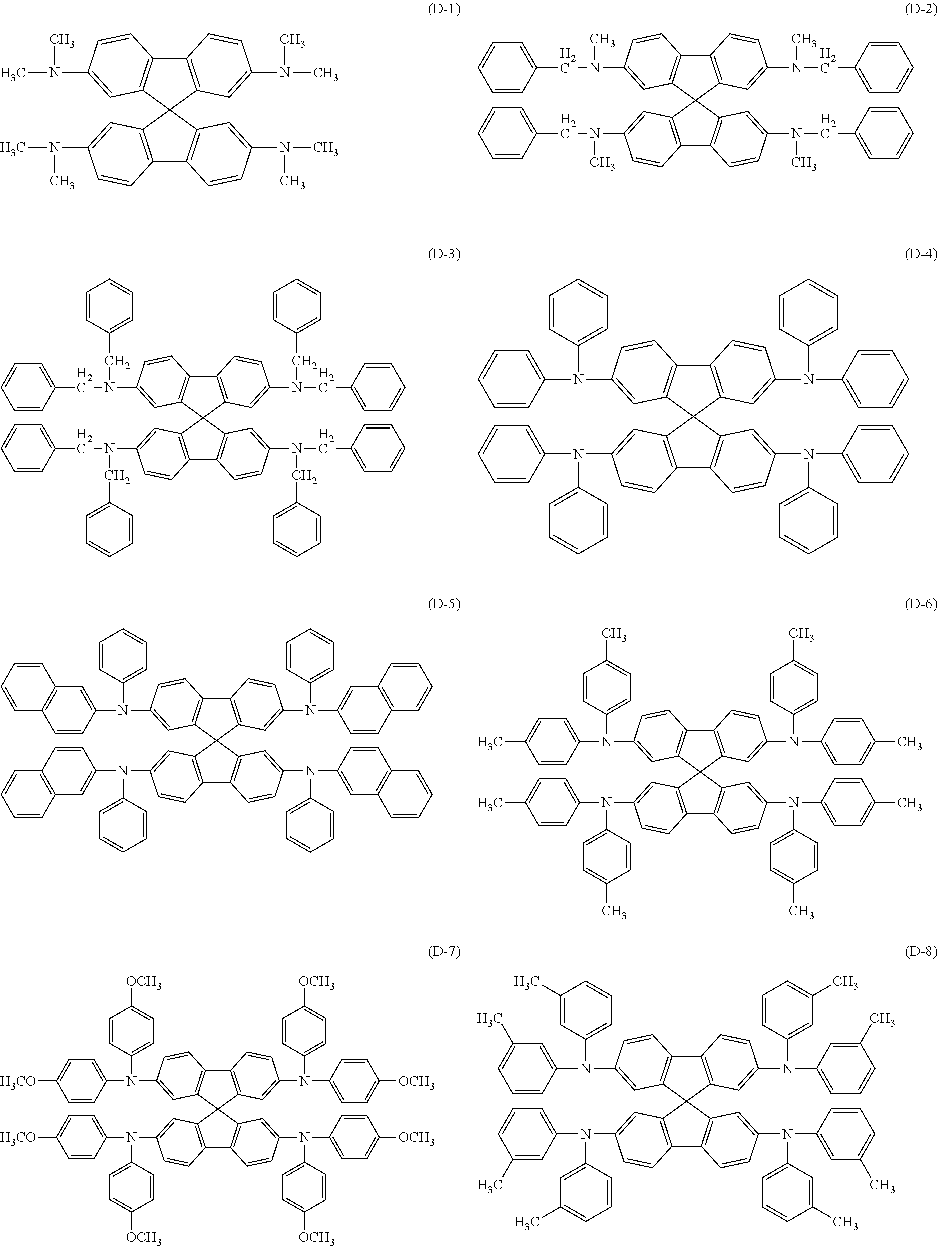

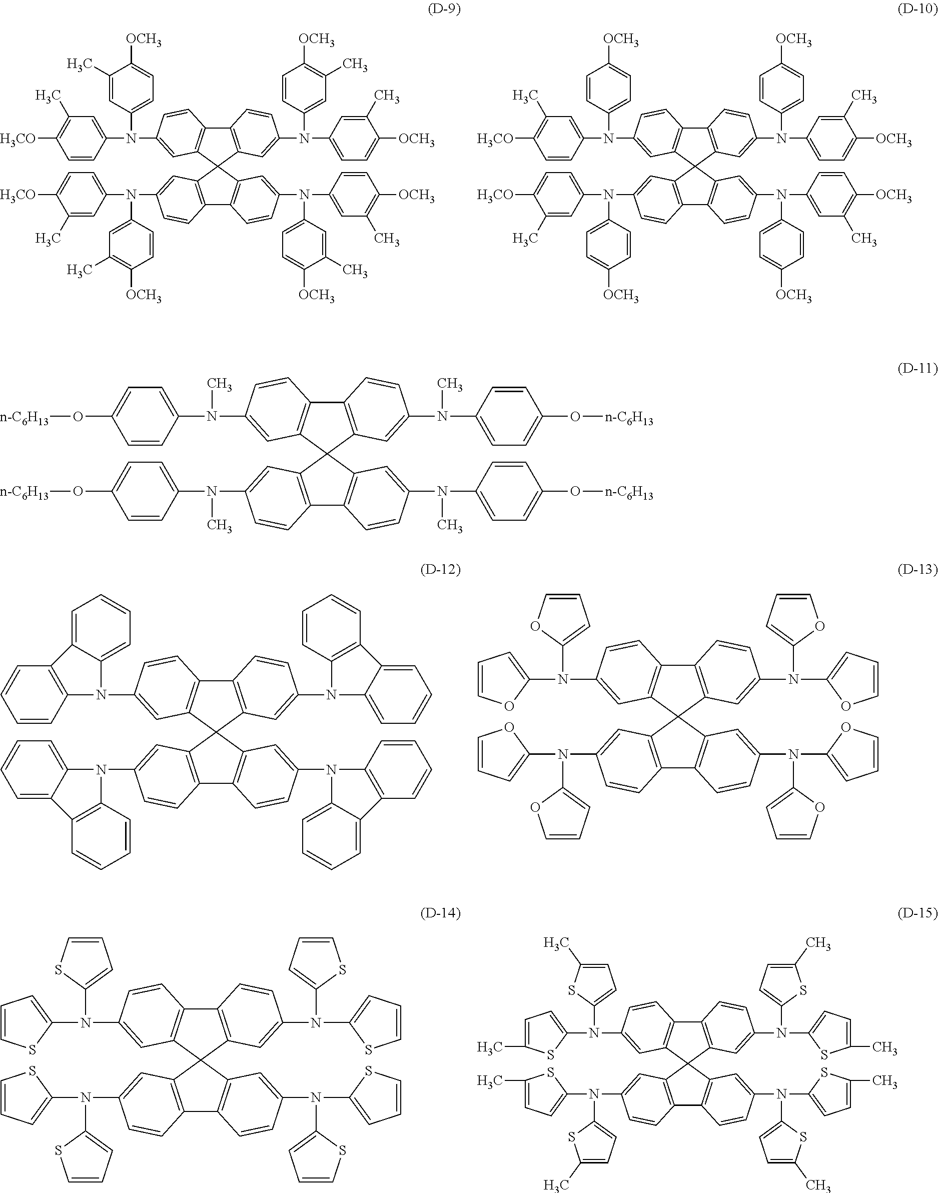

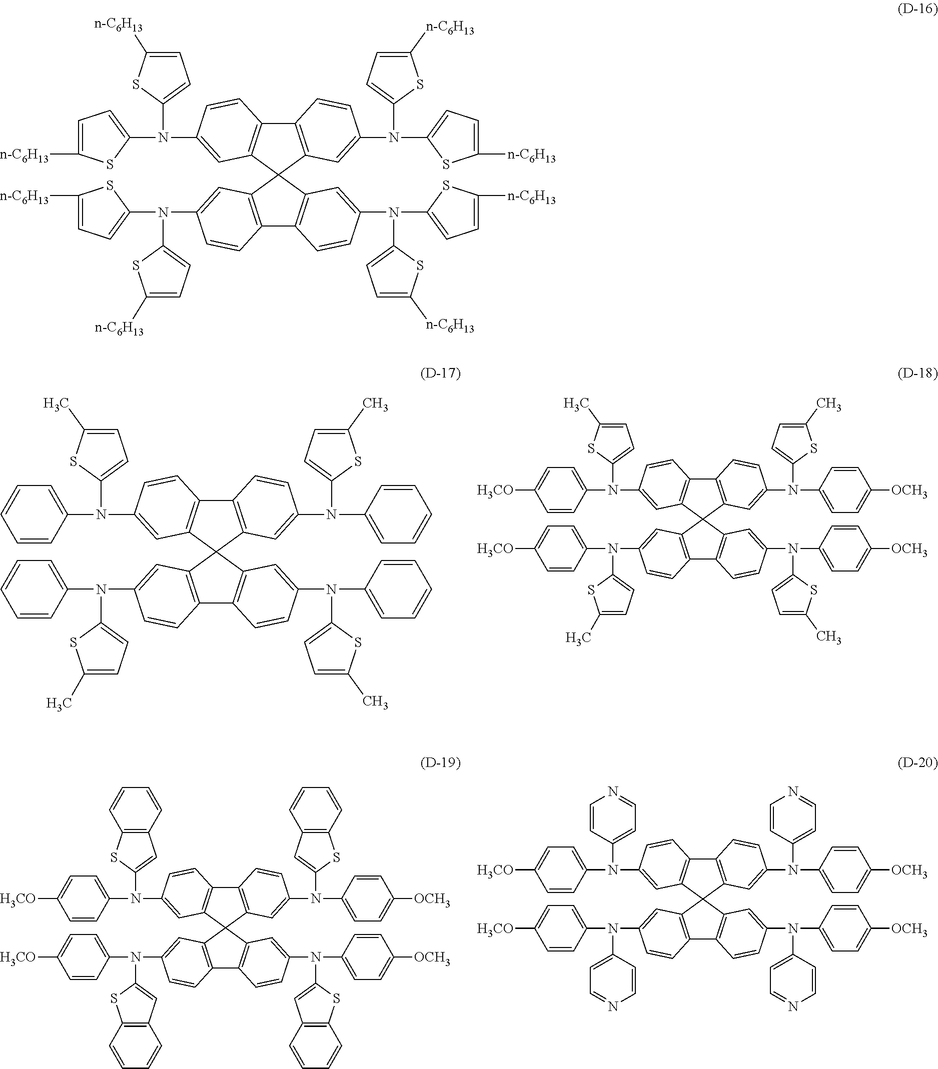

Because these spiro compounds have high hole mobility and two benzidine skeleton molecules are spirally bound, a nearly spherical electron cloud is formed and hopping conductivity between molecules is excellent. Therefore, the Spiro compounds exhibit excellent photoelectric conversion properties. Moreover, the Spiro compounds are dissolved in various organic solvents because of high solubility. Because the spiro compounds are amorphous (amorphous substances that do not have a crystal structure), the spiro compounds tend to be densely filled in a porous electron-transporting layer. Because the spiro compounds do not absorb light of 450 nm or longer, light absorption of the photosensitization compound can be effectively performed, which is particularly preferable for a solid dye-sensitized solar cell.

An amount of the organic hole-transporting material in the hole-transporting layer is not particularly limited and may be appropriately selected depending on the intended purpose.

The lithium salt is not particularly limited and may be appropriately selected depending on the intended purpose so long as it is a salt including lithium. Examples of the lithium salt include lithium hexafluorophosphate (LiPF₆), lithium perchlorate (LiClO₄), lithium chloride (LiCl), lithium tetrafluoroborate (LiBF₄), lithium hexafluoride arsenic (LiAsF₆), lithium trifluoromethanesulfonate (LiCF₃SO₃), lithium bis(trifluoromethanesulfonyl)imide [LiN(CF₃SO₂)₂], lithium (fluorosulfonyl)(trifluoromethanesulfonyl)imide [LiNSO₂)(CF₃SO₂)₂], lithium bis(pentafluoroethanesulfonyl)imide [LiN(C₂F₅SO₂)₂], lithium bis(fluorosulfonyl)imide [LiN(FSO₂)₂], lithium diisopropylimide, lithium (fluorosulfonyl)(methylsulfonyl)imide, lithium (fluorosulfonyl)(pentafluoroethylsulfonyl)imide, and lithium (fluorosulfonyl)(ethylsulfonyl)imide. These may be used alone or in combination.

Among them, lithium bis(trifluoromethanesulfonyl)imide, lithium bis(fluorosulfonyl)imide, and lithium (fluorosulfonyl)(trifluoromethanesulfonyl)imide are more preferable.

An amount of the lithium salt in the hole-transporting layer is not particularly limited and may be appropriately selected depending on the intended purpose. The amount of the lithium salt in the hole-transporting layer is preferably 5% by mole or more but 50% by mole or less, more preferably 20% by mole or more but 35% by mole or less, relative to the hole-transporting material.

The hole-transporting layer further includes an oxidizing agent, which is effective.

The oxidizing agent has a function of oxidizing a hole-transporting material to generate cation radicals. The hole-transporting material is deprived of electrons (holes are supplied) by the oxidizing agent and then becomes an oxidant, to improve a hole-transporting property. This is preferable in terms of improvement of the output and the persistence of its effect.

The oxidizing agent is not particularly limited and may be appropriately selected depending on the intended purpose so long as it has a function of oxidizing the hole-transporting material. Examples thereof include tris(4-bromophenyl)aminium hexachloroantimonate, silver hexafluoroantimonate, nitrosonium tetrafluoroborate, silver nitrate, metal complexes, and hypervalent iodine compounds. These may be used alone or in combination. Among them, metal complexes are more preferable. Use of the metal complex as the oxidizing agent is advantageous because it has high solubility and remaining products do not easily remain.

Examples of the metal complex include a complex including, for example, a metal cation, a ligand, and an anion.

Examples of the metal cation include cations of, for example, chromium, manganese, iron, cobalt, nickel, copper, molybdenum, ruthenium, rhodium, palladium, silver, tungsten, rhenium, osmium, iridium, gold, and platinum. Among them, cations of iron, cobalt, nickel, and copper are preferable, and a cation of cobalt is more preferable. That is, the metal complex is more preferably a cobalt complex. The cobalt complex is preferably a trivalent cobalt complex.

The ligand preferably includes a 5-membered heterocycle and/or a 6-membered heterocycle including at least one nitrogen, and may include a substituent. Specific examples thereof include, but are not limited to, the following compounds.

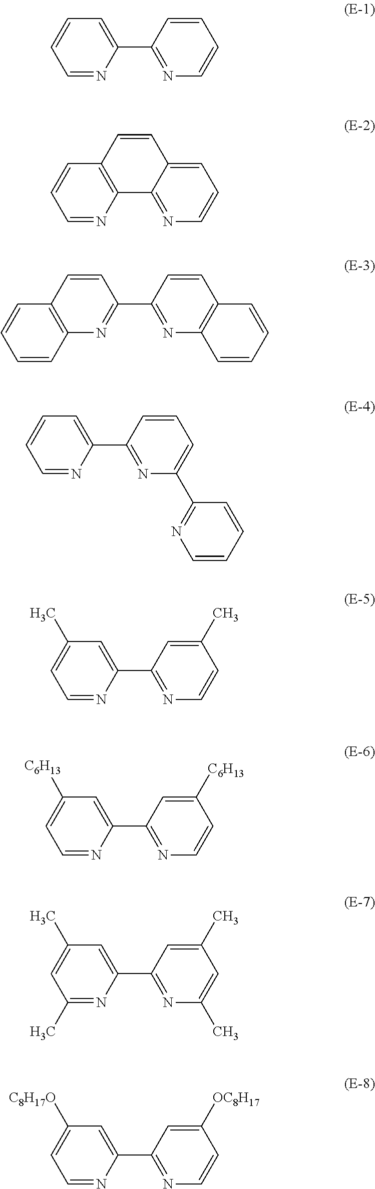

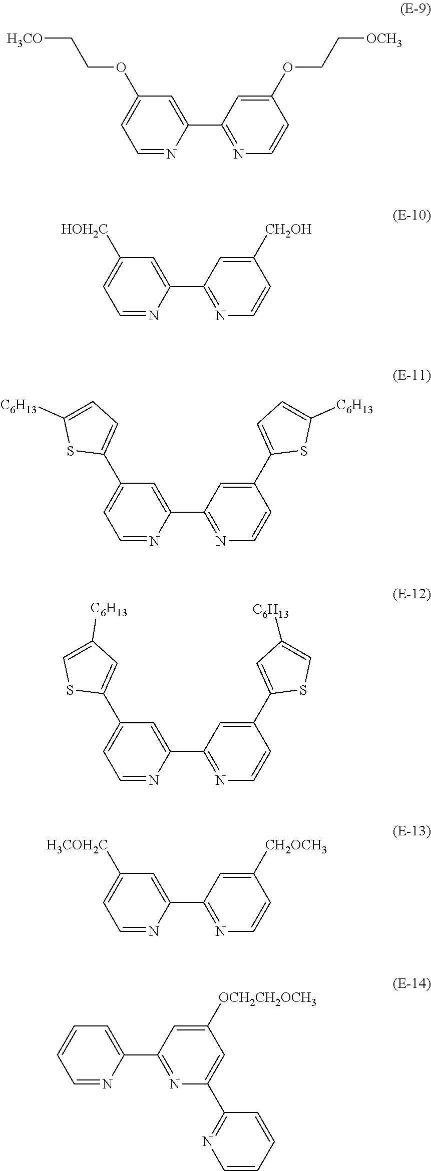

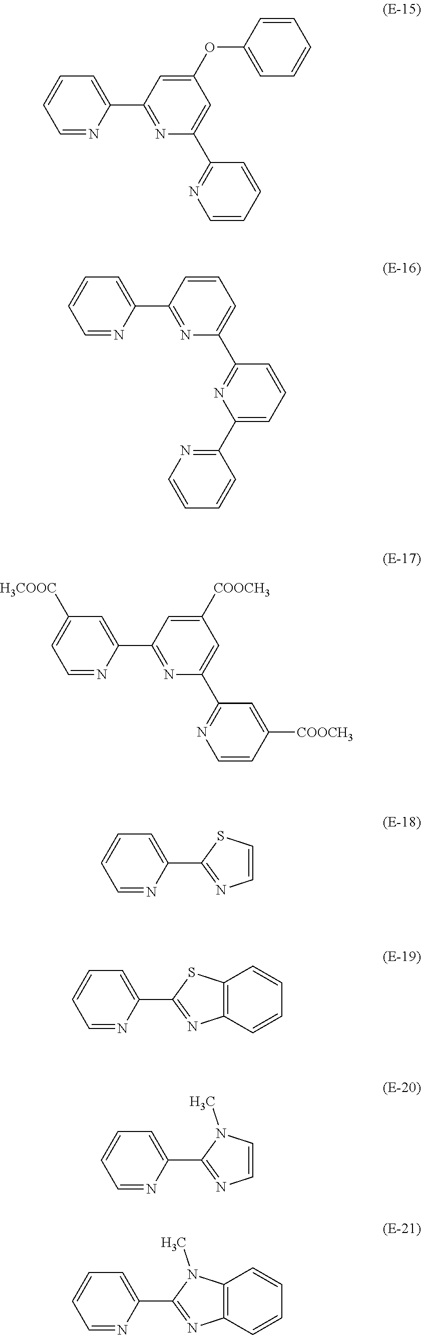

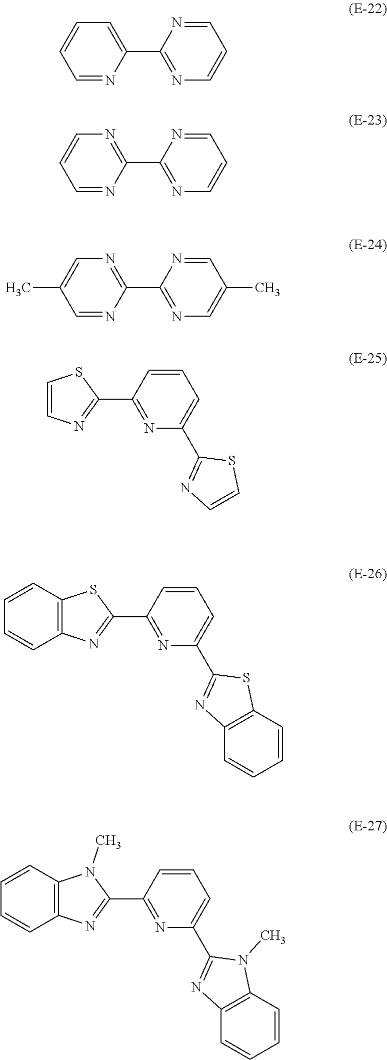

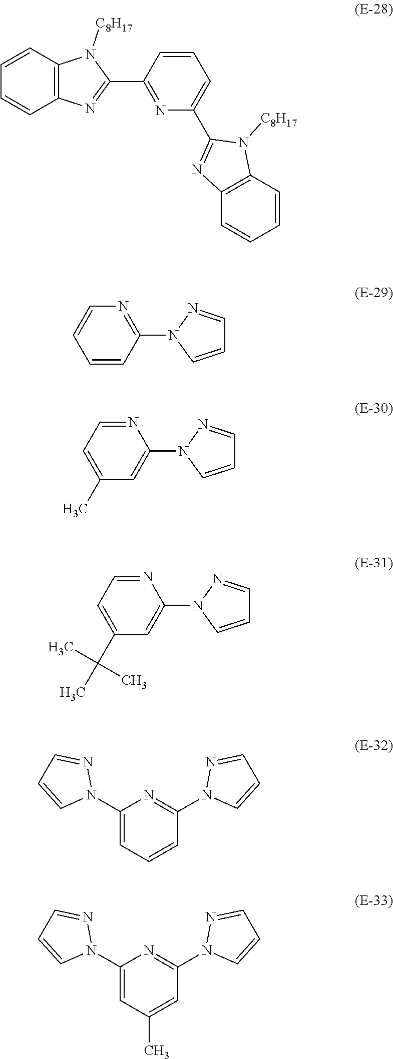

Examples of the anion include a hydride ion (H⁻), a fluoride ion (F⁻), a chloride ion (Cl⁻), a bromide ion (Br⁻), an iodide ion (I⁻), a hydroxide ion (OH⁻), a cyanide ion (CN⁻), a nitric acid ion (NO₃⁻), a nitrous acid ion (NO₂⁻), a hypochlorous acid ion (ClO⁻), a chlorous acid ion (ClO₂⁻), a chloric acid ion (ClO₃⁻), a perchloric acid ion (ClO₄⁻), a permanganic acid ion (MnO₄⁻), an acetic acid ion (CH₃COO⁻), a hydrogen carbonate ion (HCO₃⁻), a dihydrogen phosphate ion (H₂PO₄⁻), a hydrogen sulfate ion (HSO₄⁻), a hydrogen sulfide ion (HS⁻), a thiocyanic acid ion (SCN⁻), a tetrafluoroboric acid ion (BF₄⁻), a hexafluorophosphate ion (PF₆⁻), a tetracyanoborate ion (B(CN)₄⁻), a dicyanoamine ion (N(CN)₂⁻), a p-toluenesulfonic acid ion (TsO⁻), a trifluoromethyl sulfonate ion (CF₃SO₂⁻), a bis(trifluoromethylsulfonyl)amine ion (N(SO₂CF₃)₂⁻), a tetrahydroxoaluminate ion ([Al(OH)₄]⁻ or [Al(OH)₄(H₂O)₂]⁻), a dicyanoargentate(I) ion ([Ag(CN)₂]⁻), a tetrahydroxochromate(III) ion ([Cr(OH)₄]⁻), a tetrachloroaurate(III) ion ([AuCl₄]⁻), an oxide ion (O²⁻), a sulfide ion (S²⁻), a peroxide ion (O₂²⁻), a sulfuric acid ion (SO₄²⁻), a sulfurous acid ion (SO₃²⁻), a thiosulfuric acid (S₂O₃²⁻), a carbonic acid ion (CO₃²⁻), a chromic acid ion (CrO₄²⁻), a dichromic acid ion (Cr₂O₇²⁻), a monohydrogen phosphate ion (HPO₄²⁻), a tetrahydroxozincate(II) ion ([Zn(OH)₄]²⁻), a tetracyanozincate(II) ion ([Zn(CN)₄]²⁻), a tetrachlorocuprate(II) ion ([CuCl₄]²⁻), a phosphoric acid ion (PO₄³⁻), a hexacyanoferrate(III) ion ([Fe(CN)₆]³⁻), a bis(thiosulfate)argentate(I) ion ([Ag(S₂O₃)₂]³⁻), and a hexacyanoferrate(II) ion ([Fe(CN)₆]⁴⁻). These may be used alone or in combination. Among them, a tetrafluoroboric acid ion, a hexafluorophosphate ion, a tetracyanoborate ion, a bis(trifluoromethylsulfonyl)amine ion, and a perchloric acid ion are preferable.

Among these metal complexes, trivalent cobalt complexes represented by the following General Formulas (5) and (6) are particularly preferable. When the metal complex is a trivalent cobalt complex, the function as the oxidizing agent is excellent, which is advantageous.

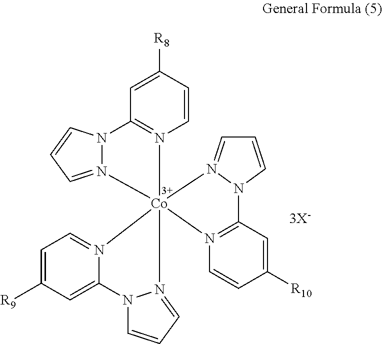

In the General Formula (5), R₈ to R₁₀ each independently represent a hydrogen atom, a methyl group, an ethyl group, a propyl group, a tert-butyl group, or a trifluoromethyl group. X⁻ represents one selected from the group consisting of the above monovalent anions.

Specific examples of the cobalt complex represented by the General Formula (5) are described below. However, the present disclosure is not limited thereto. These may be used alone or in combination.

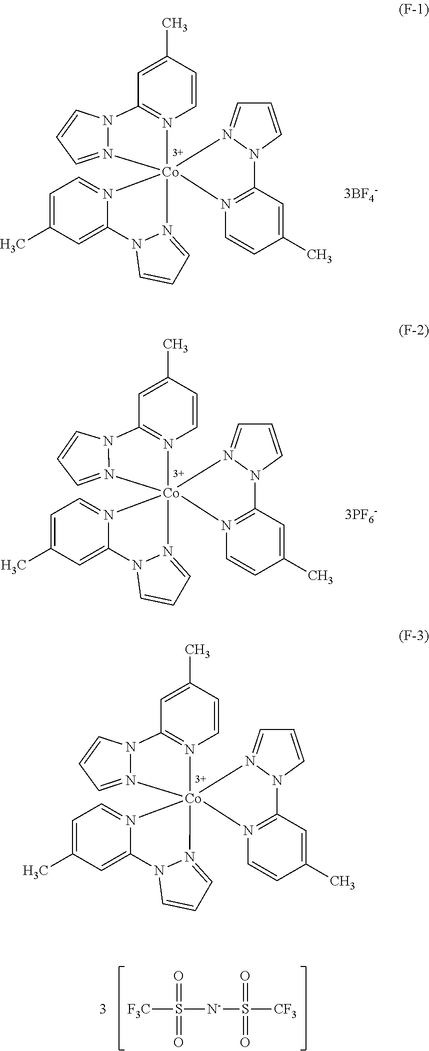

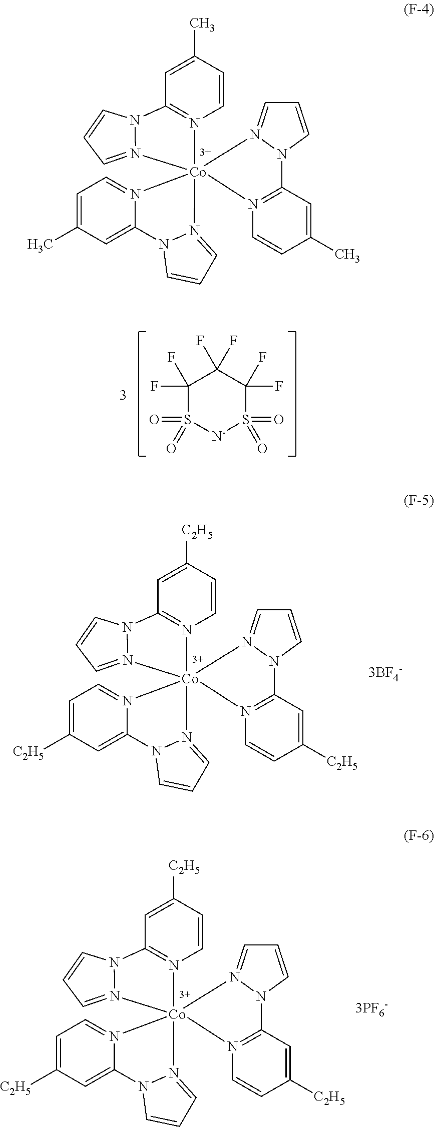

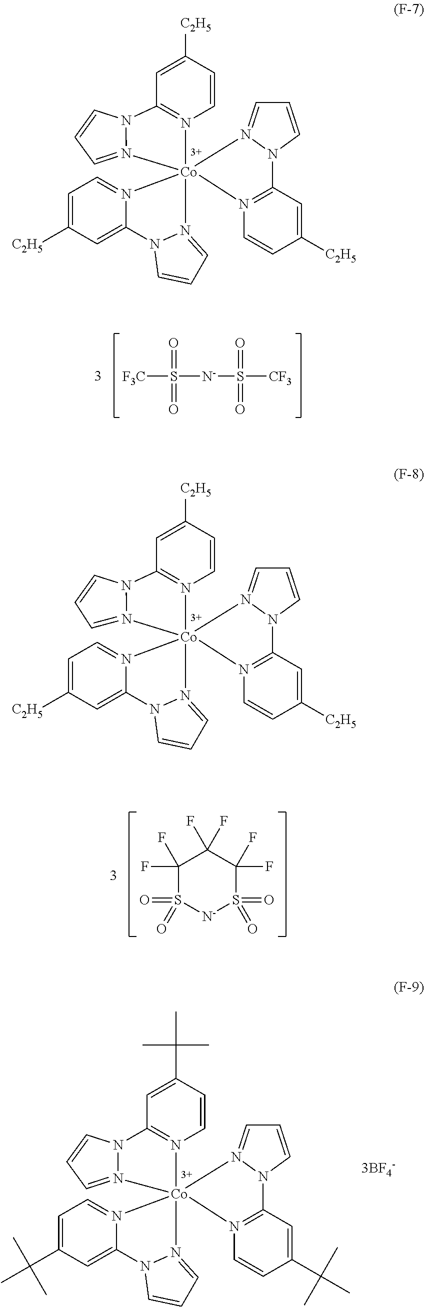

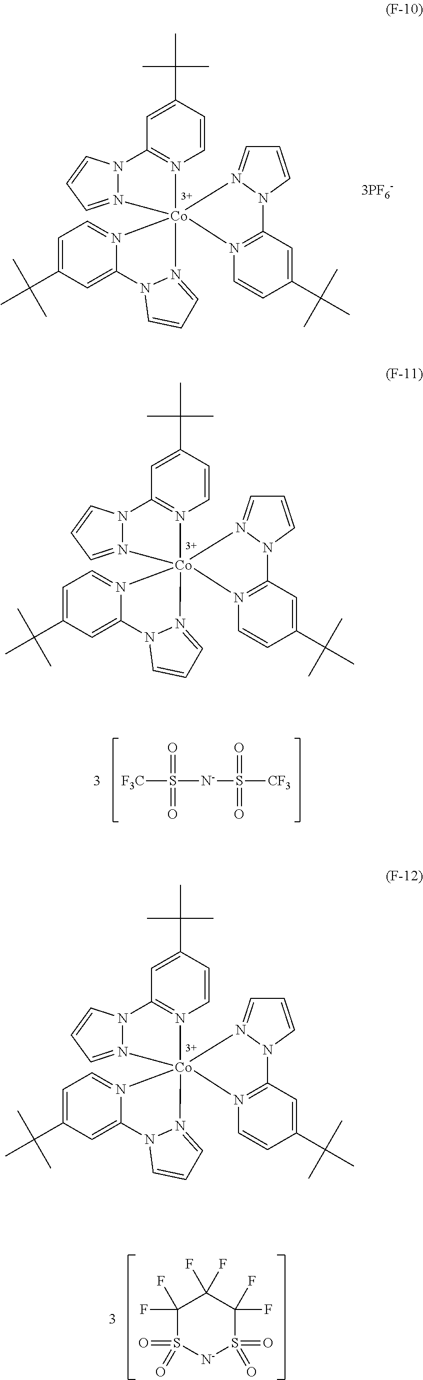

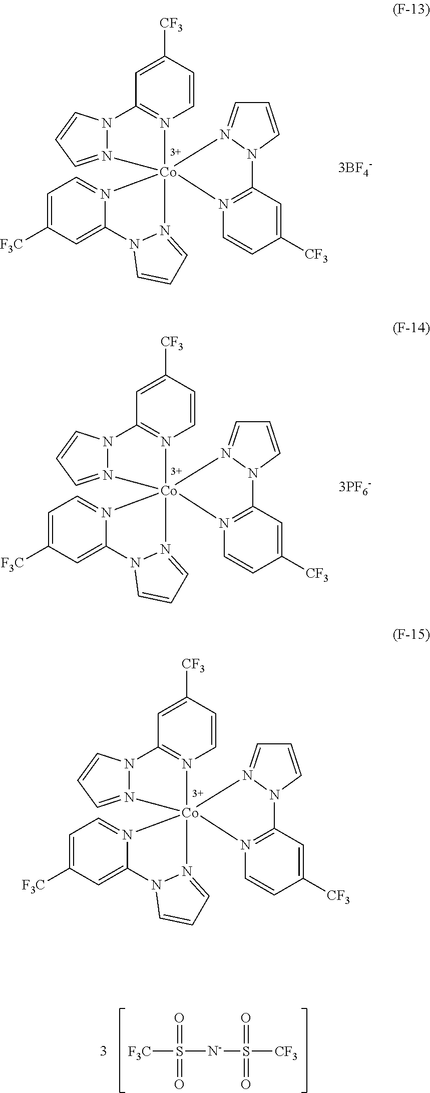

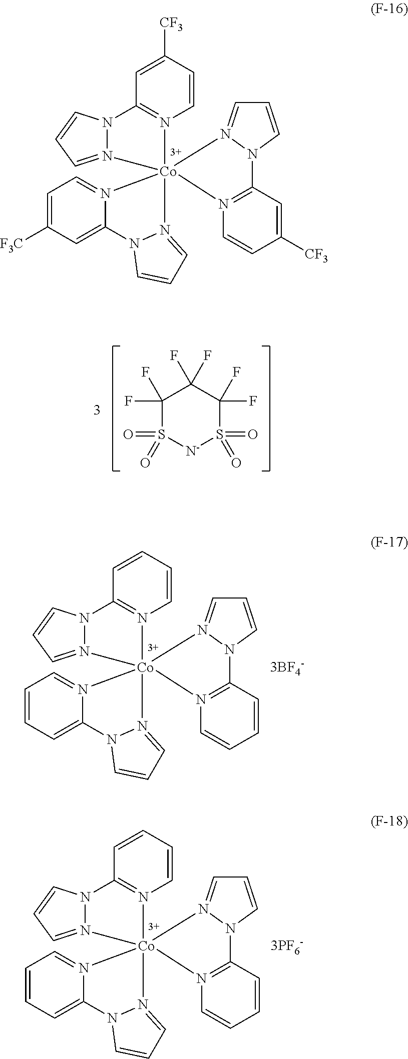

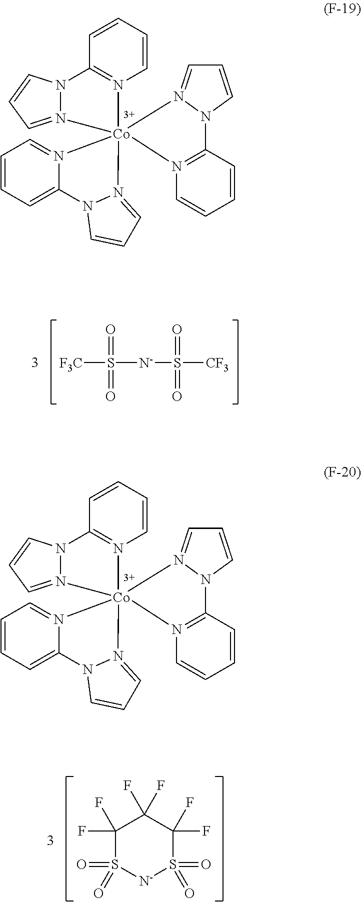

As the metal complex, a trivalent cobalt complex represented by the following General Formula (6) is also effectively used.

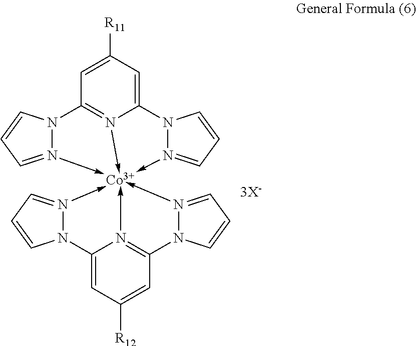

In the General Formula (6), R₁₁ and R₁₂ each independently represent a hydrogen atom, a methyl group, an ethyl group, a propyl group, a tert-butyl group, or a trifluoromethyl group. X⁻ represents one selected from the group consisting of the above monovalent anions.

Specific examples of the cobalt complex represented by the General Formula (6) are described below. However, the present disclosure is not limited thereto. These may be used alone or in combination.

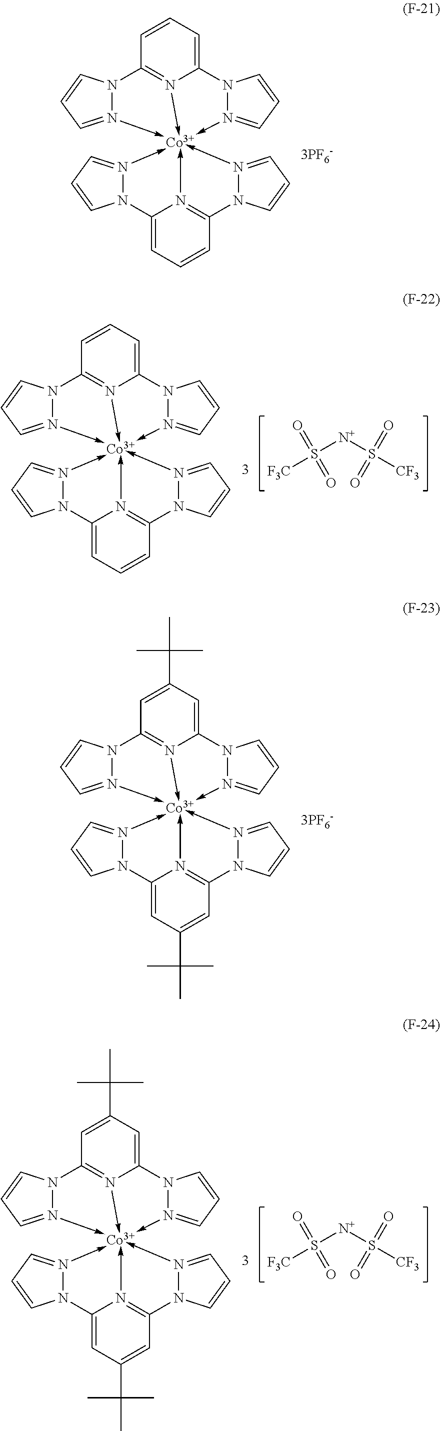

As the oxidizing agent, a hypervalent iodine compound is also preferably used. The hypervalent iodine compound is a compound that includes 8 or more electrons in the valence shell and includes a hypervalent iodine atom. Among them, particularly, when a periodinane compound represented by the following General Formula (7) and a diaryliodonium salt represented by the following General Formula (8) are used as the oxidizing agent in the hole-transporting layer, a high output can be obtained because of high solubility, low crystallinity, and low acidity. When acidity of the hole-transporting layer is high, the open circuit voltage becomes low. When the amount of a basic material added is large, it is possible to make the open circuit voltage high. However, because a concentration of the hole-transporting material is decreased, series resistance is increased to thereby decrease the output under light of a high illuminance.

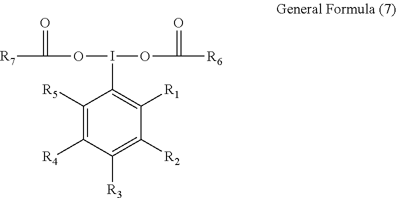

In the General Formula (7), R₁ to R₅ each independently represent a hydrogen atom or a methyl group. R₆ and R₇ each independently represent a methyl group or a trifluoromethyl group.

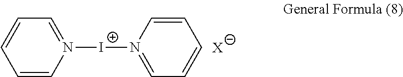

In the General Formula (8), X represents BF₄, PF₄, the following Structural Formula (4), or the following Structural Formula (5).

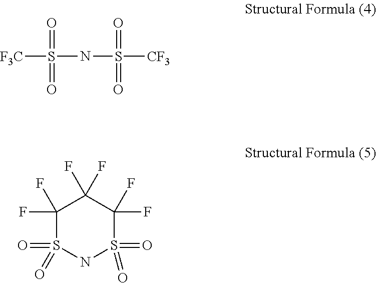

Specific examples of the periodinane compound represented by the General Formula (7) and the diaryliodonium salt represented by the General Formula (8) include, but are not limited to, the following (G-1) to (G-10).

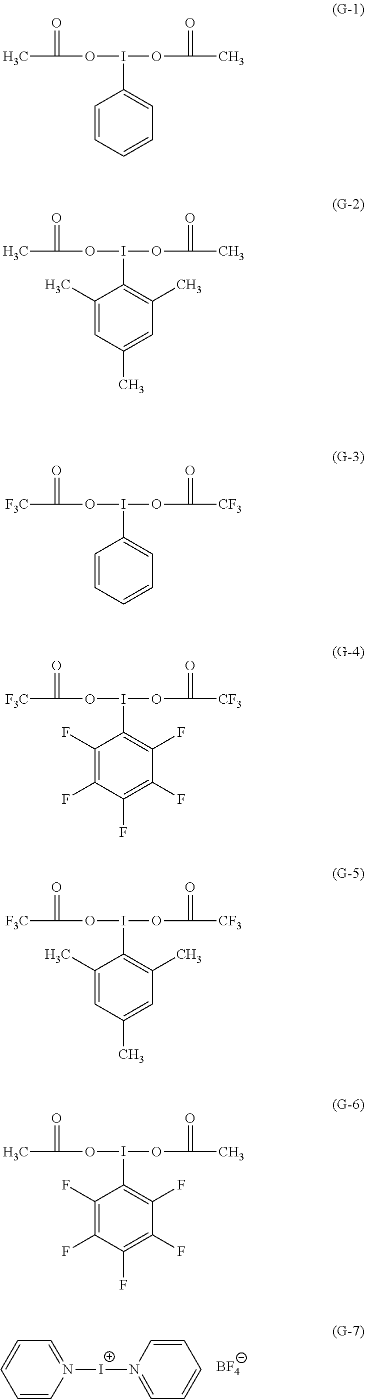

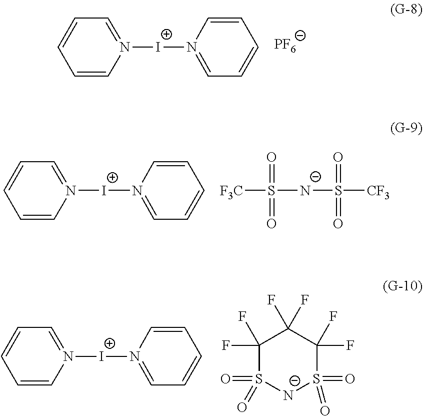

In addition, hypervalent iodine compounds expressed by the following Structural Formulas are also effective.

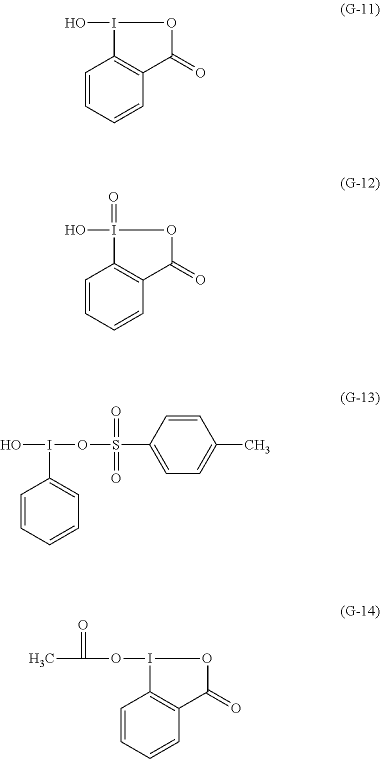

An amount of the oxidizing agent is preferably 5% by mole or more but 30% by mole or less, more preferably 10% by mole or more but 20% by mole or less, relative to the hole-transporting material. By addition of the oxidizing agent, it is not necessary to oxidize all hole-transporting material, and it is effective so long as the hole-transporting material is partially oxidized.

The oxidizing agent may be used alone or in combination. When two or more oxidizing agents are used in combination, the hole-transporting layer is not easily crystallized and may obtain a high thermal resistance in some cases.

Preferably, the hole-transporting layer further includes a compound having a pyridine ring structure.

The pyridine ring is expressed by the following Structural Formula (6), and the compound having a pyridine ring structure is a compound including at least one pyridine ring.

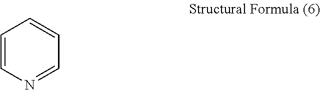

When the hole-transporting layer includes the compound having a pyridine ring structure, open circuit voltage is increased. As a result, an effect of increasing the output can be obtained.

Among these compounds having a pyridine ring structure, compounds represented by the following General Formula (9) and General Formula (10) are more preferable.

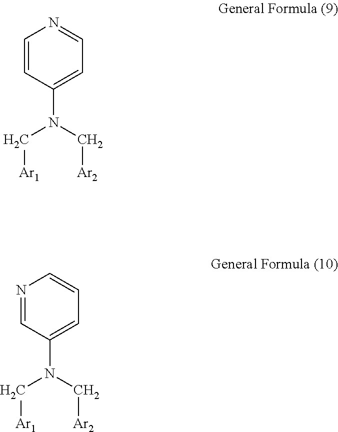

In the General Formula (9) and the General Formula (10), Ar₁ and Ar₂ represent an aryl group that may have a substituent, the Ar₁ and the Ar₂ may be identical or different, and may be joined with each other.

Specific examples of the compound having a pyridine ring include, but are not limited to, the following exemplified compounds C-1 to C-16. These may be used alone or in combination.

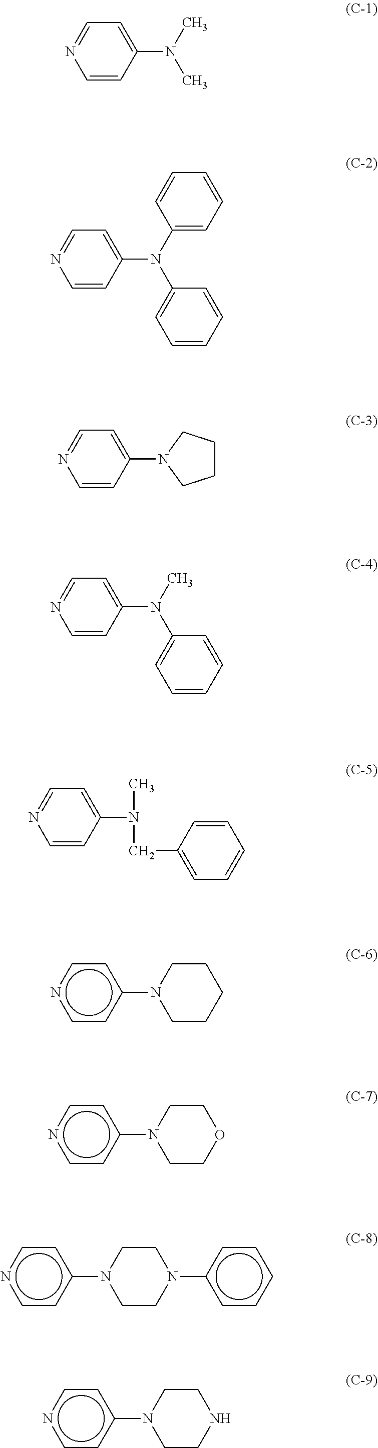

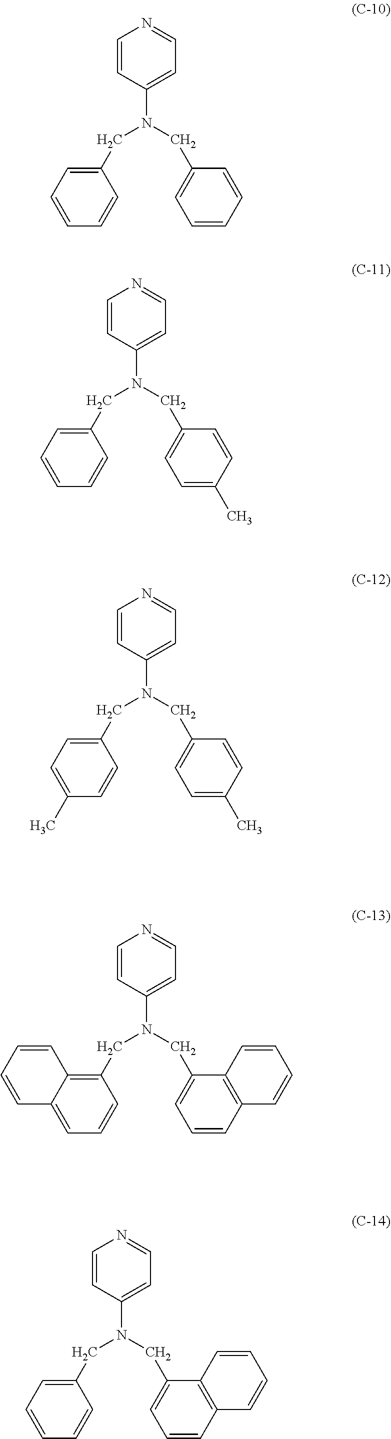 [SMILES: c1ccc(CN(Cc2ccccc2)c2ccncc2)cc1 ; Cc1ccc(CN(Cc2ccccc2)c2ccncc2)cc1 ; Cc1ccc(CN(Cc2ccc(C)cc2)c2ccncc2)cc1 ; c1ccc2c(CN(Cc3cccc4ccccc34)c3ccncc3)cccc2c1 ; c1ccc(CN(Cc2cccc3ccccc23)c2ccncc2)cc1]

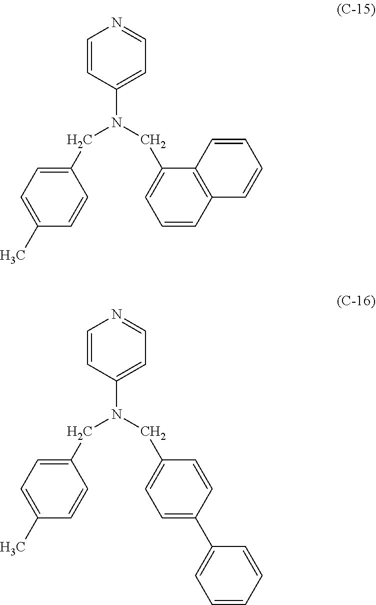 [SMILES: Cc1ccc(CN(Cc2cccc3ccccc23)c2ccncc2)cc1 ; Cc1ccc(CN(Cc2ccc(-c3ccccc3)cc2)c2ccncc2)cc1]

Inclusion of the compound having a pyridine ring structure in the hole-transporting layer can enhance not only the output of the photoelectric conversion element but also the durability or the stability, and is particularly effective in improving the stability or the durability against light of a low illuminance.

An amount of the compound having a pyridine ring is preferably 20% by mole or more but 65% by mole or less, more preferably 35% by mole or more but 50% by mole or less, relative to the hole-transporting material. When the amount of the compound having a pyridine ring falls within the preferable range, a high open circuit voltage can be maintained, and a high output can be obtained. In addition, even when the photoelectric conversion element is used under various environments for a long period of time, high stability and durability can be obtained.

Various additives may be added to the organic hole-transporting material.

Examples of the additive include iodine, metal iodides, quaternary ammonium salts, metal bromides, metal chlorides, metal acetates, metal sulfates, metal complexes, sulfur compounds, ionic liquids described in Inorg. Chem. 35 (1996) 1168, and basic compounds.

Examples of the metal iodide include sodium iodide, potassium iodide, cesium iodide, calcium iodide, copper iodide, iron iodide, and silver iodide.

Examples of the quaternary ammonium salt include tetraalkylammonium iodide and pyridinium iodide.

Examples of the metal bromide include sodium bromide, potassium bromide, cesium bromide, and calcium bromide.

Examples of the metal chloride include: bromide salts of quaternary ammonium compounds such as tetraalkylammonium bromide and pyridinium bromide; copper chloride; and silver chloride.

Examples of the metal acetate include copper acetate, silver acetate, and palladium acetate.

Examples of the metal sulfate include copper sulfate and zinc sulfate.

Examples of the metal complex include a ferrocyanate salt-ferricyanate salt and a ferrocene-ferricinium ion.

Examples of the sulfur compound include sodium polysulfide and alkylthiol-alkyl disulfide.

Examples of the ionic liquid described in Inorg. Chem. 35 (1996) 1168 include viologen dye, hydroquinone, 1,2-dimethyl-3-n-propylimidazolium iodide, 1-methyl-3-n-hexylimidazolium iodide, 1,2-dimethyl-3-ethylimidazolium trifluoromethanesulfonate, 1-methyl-3-butylimidazolium nonafluorobutyl sulfonate, and 1-methyl-3-ethylimidazolium bis(trifluoromethyl)sulfonyl imide.

When the hole-transporting layer is a staked structure, a polymeric material is preferably used on the hole-transporting layer near the second electrode. Use of the polymeric material excellent in a film forming property can make the surface of a porous electron-transporting layer smoother, to improve photoelectric conversion characteristics.

Because the polymeric material does not easily permeate through the inside of the porous electron-transporting layer, the polymeric material is excellent in coating the surface of the porous electron-transporting layer and can achieve an effect of preventing short circuit when an electrode is provided. As a result, higher performances can be obtained.

The polymeric material, which is used when the hole-transporting layer has a stacked structure and is disposed at a position near the second electrode, is not particularly limited. More preferable examples of the polymeric material include known hole-transporting polymeric materials.

Examples of the hole-transporting polymeric material include polythiophene compounds, polyphenylene vinylene compounds, polyfluorene compounds, polyphenylene compounds, polyarylamine compounds, and polythiadiazole compounds.

Examples of the polythiophene compound include poly(3-n-hexylthiophene), poly(3-n-octyloxythiophene), poly(9,9′-dioctyl-fluorene-co-bithiophene), poly(3,3′″-didodecyl-quarter thiophene), poly(3,6-dioctylthieno[3,2-b]thiophene), poly(2,5-bis(3-decylthiophen-2-yl)thieno[3,2-b]thiophene), poly(3,4-didecylthiophene-co-thieno[3,2-b]thiophene), poly(3,6-dioctylthieno[3,2-b]thiophene-co-thieno[3,2-b]thiophene), poly(3,6-dioctylthieno[3,2-b]thiophene-co-thiophene), and poly(3,6-dioctylthieno[3,2-b]thiophene-co-bithiophene).

Examples of the polyphenylene vinylene compound include poly[2-methoxy-5-(2-ethylhexyloxy)-1,4-phenylenevinylene], poly[2-methoxy-5-(3,7-dimethyloctyloxy)-1,4-phenylenevinylene], and poly[(2-methoxy-5-(2-ethylhexyloxy)-1,4-phenylenevinylene)-co-(4,4-biphenylene-vinylene)].

Examples of the polyfluorene compound include poly(9,9′-didodecylfluorenyl-2,7-diyl), poly[(9,9-dioctyl-2,7-divinylenefluorene)-alt-co-(9,10-anthracene)], poly[(9,9-dioctyl-2,7-divinylenefluorene)-alt-co-(4,4-biphenylene)], poly[(9,9-dioctyl-2,7-divinylenefluorene)-alt-co-(2-methoxy-5-(2-ethylhexyl oxy)-1,4-phenylene)], and poly[(9,9-dioctyl-2,7-diyl)-co-(1,4-(2,5-dihexyloxy)benzene)].

Examples of the polyphenylene compound include poly[2,5-dioctyloxy-1,4-phenylene] and poly[2,5-di(2-ethylhexyloxy-1,4-phenylene].

Examples of the polyarylamine compound include poly[(9,9-dioctylfluorenyl-2,7-diyl)-alt-co-(N,N′-diphenyl)-N,N′-di(p-hexylphenyl)-1,4-diaminobenzene], poly[(9,9-dioctylfluorenyl-2,7-diyl)-alt-co-(N,N′-bis(4-octyloxyphenyl)benzidine-N,N′-(1,4-diphenylene)], poly[(N,N′-bis(4-octyloxyphenyl)benzidine-N,N-(1,4-diphenylene)], poly[(N,N′-bis(4-(2-ethylhexyloxy)phenyl)benzidine-N,N′-(1,4-diphenylene)], poly[phenylimino-1,4-phenylenevinylene-2,5-dioctyloxy-1,4-phenylenevinylene-1,4-phenylene], poly[p-tolylimino-1,4-phenylenevinylene-2,5-di(2-ethylhexyloxy)-1,4-phenylenevinylene-1,4-phenylene], and poly[4-(2-ethylhexyloxy)phenylimino-1,4-biphenylene].

Examples of the polythiadiazole compound include poly[(9,9-dioctylfluorenyl-2,7-diyl)-alt-co-(1,4-benzo(2,1′,3)thiadiazole] and poly(3,4-didecylthiophene-co-(1,4-benzo(2,1′,3)thiadiazole).

Among them, polythiophene compounds and polyarylamine compounds are particularly preferable in terms of carrier mobility and ionization potential.

The hole-transporting layer can be directly formed on the electron-transporting layer including the photosensitization compound.

A method for producing the hole-transporting layer is not particularly limited and may be appropriately selected depending on the intended purpose. Examples of the method include a method for forming a thin film under vacuum such as vacuum deposition and a wet film formation method. Among them, particularly, the wet film formation method is preferable, a method for performing coating on the electron-transporting layer is preferable in terms of production cost.

When the wet film formation method is used, the coating method is not particularly limited and can be performed according to known methods. Examples of the coating method include the dip method, the spray method, the wire bar method, the spin-coating method, the roller coating method, the blade coating method, and the gravure coating method. Examples of the wet printing method include various methods such as relief printing, offset printing, gravure printing, intaglio printing, rubber plate printing, and screen printing.

The film may be formed in a supercritical fluid or a subcritical fluid having lower temperature and pressure than a critical point.

The supercritical fluid is not particularly limited and may be appropriately selected depending on the intended purpose, so long as it exists as a non-condensable high-density fluid in a temperature and pressure region exceeding the limit (critical point) at which gas and liquid can coexist, does not condense even when compressed, and is fluid in a state of being equal to or more than the critical temperature and the critical pressure. The supercritical fluid is preferably a supercritical fluid having a low critical temperature.

Examples of the supercritical fluid include carbon monoxide, carbon dioxide, ammonia, nitrogen, water, alcohol solvents, hydrocarbon solvents, halogen solvents, and ether solvents.

Examples of the alcohol solvent include methanol, ethanol, and n-butanol.

Examples of the hydrocarbon solvent include ethane, propane, 2,3-dimethylbutane, benzene, and toluene.

Examples of the halogen solvent include methylene chloride and chlorotrifluoromethane.

Examples of the ether solvent include dimethyl ether.

These may be used alone or in combination.

Among them, carbon dioxide having a critical pressure of 7.3 MPa and a critical temperature of 31° C. is particularly preferable because it can easily generate a supercritical state, has incombustibility, and is easily handled.

The subcritical fluid is not particularly limited and may be appropriately selected depending on the intended purpose so long as it exists as high-pressure liquid in a temperature and pressure region near the critical point.

The aforementioned compounds exemplified as the supercritical fluid can be suitably used as the subcritical fluid.

A critical temperature and a critical pressure of the supercritical fluid are not particularly limited and may be appropriately selected depending on the intended purpose. The critical temperature thereof is preferably −273° C. or more but 300° C. or less, particularly preferably 0° C. or more but 200° C. or less.

In addition to the supercritical fluid and the subcritical fluid, an organic solvent or an entrainer may be used in combination. The solubility in the supercritical fluid can be more easily adjusted by addition of the organic solvent or the entrainer.

The organic solvent is not particularly limited and may be appropriately selected depending on the intended purpose. Examples thereof include ketone solvents, ester solvents, ether solvents, amide solvents, halogenated hydrocarbon solvents, and hydrocarbon solvents.

Examples of the ketone solvent include acetone, methyl ethyl ketone, and methyl isobutyl ketone.

Examples of the ester solvent include ethyl formate, ethyl acetate, and n-butyl acetate.

Examples of the ether solvent include diisopropyl ether, dimethoxy ethane, tetrahydrofuran, dioxolane, and dioxane.

Examples of the amide solvent include N,N-dimethylformamide, N,N-dimethylacetamide, and N-methyl-2-pyrrolidone.

Examples of the halogenated hydrocarbon solvent include dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene.

Examples of the hydrocarbon solvent include n-pentane, n-hexane, n-octane, 1,5-hexadiene, cyclohexane, methylcyclohexane, cyclohexadiene, benzene, toluene, o-xylene, m-xylene, p-xylene, ethylbenzene, and cumene.

These may be used alone or in combination.

A press treatment may be performed after the organic hole-transporting material is provided on the electron-transporting layer containing the electron-transporting material to which the photosensitization compound has been adsorbed. It is believed that the press treatment allows the organic hole-transporting material to further adhere to the electron-transporting layer that is a porous electrode, resulting in improvement of efficiency.

The press treatment is not particularly limited and may be appropriately selected depending on the intended purpose. Examples of the press treatment include: a press molding method using a plate such as an IR tablet molding device; and a roll press method using a roller.

The pressure for the press treatment is preferably 10 kgf/cm² or more, more preferably 30 kgf/cm² or more.

The time of the press treatment is not particularly limited and may be appropriately selected depending on the intended purpose. The time thereof is preferably 1 hour or shorter. Moreover, heat may be applied at the time of the press treatment.

At the time of the press treatment, a release agent may be disposed between a pressing machine and electrodes.

Examples the release agent include fluororesins such as polyethylene tetrafluoride, polychloroethylene trifluoride, ethylene tetrafluoride-propylene hexafluoride copolymers, perfluoroalkoxy fluoride resins, polyvinylidene fluoride, ethylene-ethylene tetrafluoride copolymers, ethylene-chloroethylene trifluoride copolymers, and polyvinyl fluoride. These may be used alone or in combination.

An average thickness of the hole-transporting layer is 0.1 nm or more but 50 nm or less, more preferably 1 nm or more but 10 nm or less.

A metal oxide may be disposed between the organic hole-transporting material and the second electrode after the press treatment but before disposition of the second electrode.

Examples of the metal oxide include molybdenum oxide, tungsten oxide, vanadium oxide, and nickel oxide. These may be used alone or in combination. Among them, molybdenum oxide is preferable.

A method for disposing the metal oxide on the hole-transporting layer is not particularly limited and may be appropriately selected depending on the intended purpose. Examples of the method include a method where a thin film is formed in vacuum (e.g., sputtering and vacuum vapor deposition), and the wet film formation method.

The wet film formation method is preferably a method where a paste obtained by dispersing powder or sol of the metal oxide is prepared and is coated on the hole-transporting layer.

In the case where the wet film formation method is used, a coating method is not particularly limited and may be appropriately selected depending on the intended purpose. Examples of the coating method include the clip method, the spray method, the wire bar method, the spin-coating method, the roller coating method, the blade coating method, and the gravure coating method. Examples of the wet printing method include relief printing, offset printing, gravure printing, intaglio printing, rubber plate printing, and screen printing.

An average thickness of the metal oxide coated is preferably 0.1 nm or more but 50 nm or less, more preferably 1 nm or more but 10 nm or less.

### <Second Electrode>

The second electrode can be formed on the hole-transporting layer, or on a metal oxide on the hole-transporting layer.

The same as the first electrode can be generally used for the second electrode. In such a configuration that strength or airtightness is sufficiently maintained, a support is not always necessary.

A material of the second electrode is not particularly limited and may be appropriately selected depending on the intended purpose.

Examples of the material of the second electrode include metals, carbon compounds, conductive metal oxides, and conductive polymers.

Examples of the metal include platinum, gold, silver, copper, and aluminum.

Examples of the carbon compound include graphite, fullerene, carbon nanotube, and graphene.

Examples of the conductive metal oxide include ITO, FTO, and ATO.

Examples of the conductive polymer include polythiophene and polyaniline.

These may be used alone or in combination.

The second electrode can be appropriately formed on the hole-transporting layer by methods such as the coating method, the lamination method, the deposition method, the CVD method, and the pasting method, depending on kinds of materials to be used and kinds of the hole-transporting layer.

When a side of the second electrode is transparent and incident light is allowed to pass from the side of the second electrode, a material that reflects light is preferably used at the side of the second electrode, and glass, plastic, or a metal thin film on which a metal or conductive oxide is deposited is preferably used. In addition, providing an anti-reflection layer at a side where the incident light is to be received is an effective means.

### <Sealing Member>

The photoelectric conversion element of the present disclosure can be provided with a sealing member, which is effective.

The sealing member is not particularly limited and may be appropriately selected depending on the intended purpose, so long as at least the hole-transporting layer can be shielded from an external environment of the photoelectric conversion element.

The purpose of shielding at least the hole-transporting layer from an external environment of the photoelectric conversion element by the sealing member is to prevent entry of excessive oxygen or moisture from the outside and to prevent mechanical breakage caused by pressing force from the outside.

A method of the sealing can be roughly classified into “frame sealing” and “surface sealing”. Specifically, the frame sealing means that sealing members are provided around the photoelectric conversion layer formed of, for example, the electron-transporting layer and the hole-transporting layer of the photoelectric conversion element, and are attached to the second substrate. The surface sealing means that the sealing member is provided on the whole surface of the power generation region, and is attached to the second substrate. The frame sealing of the former can form a hollow section inside the sealed part. Therefore, an amount of moisture or an amount of oxygen inside the sealed part can appropriately be adjusted. In addition, since the second electrode is not in contact with the sealing member, an influence caused by exfoliated electrodes can be decreased. Meanwhile, the “surface sealing” of the latter is excellent in preventing entry of excessive oxygen or moisture from the outside. In addition, an area where the power generation region is in contact with the sealing member is large. Therefore, the sealing strength is high, and the surface sealing is particularly suitable when a flexible substrate is used as the first substrate.

Kinds of sealing member are not particularly limited and may be appropriately selected depending on the intended purpose. Examples thereof include curable resins and glass resins having a low melting temperature. The curable resin is not particularly limited and may be appropriately selected depending on the intended purpose so long as it is cured by light or heat. Among them, acrylic resins or epoxy resins are preferably used.

As a cured product of the acrylic resin, any of materials known in the art can be used, so long as the cured product is a product obtained by curing a monomer or an oligomer including an acrylic group in a molecule thereof.

As a cured product of the epoxy resin, any of materials known in the art can be used, so long as the cured product is a product obtained by curing a monomer or an oligomer including an epoxy group in a molecule thereof.

Among them, an epoxy resin having a high adhesive force with a substrate and an excellent barrier property against moisture or oxygen is more preferably used. As a result, it is possible to further enhance the durability of the photoelectric conversion element of the present disclosure that has a high output and an excellent stability.

Examples of the epoxy resin include water-dispersing epoxy resins, non-solvent epoxy resins, solid epoxy resins, thermosetting epoxy resins, curing agent-mixed epoxy resins, and ultraviolet ray-curable epoxy resins. Among them, thermosetting epoxy resins and ultraviolet ray-curable epoxy resins are preferable, ultraviolet ray-curable epoxy resins are more preferable. Note that, ultraviolet ray-curable epoxy resins may be heated.

The epoxy resin is not particularly limited and may be appropriately selected depending on the intended purpose. Examples of the epoxy resin include bisphenol A-based epoxy resins, bisphenol F-based epoxy resins, novolac-based epoxy resins, alicyclic epoxy resins, long-chain aliphatic epoxy resins, glycidyl amine-based epoxy resins, glycidyl ether-based epoxy resins, and glycidyl ester-based epoxy resins. These may be used alone or in combination.

The sealing member may include a curing agent and various additives if necessary.

Examples of the curing agent include amine-based curing agents, acid anhydride-based curing agents, polyamide-based curing agents, and other curing agents.

Examples of the amine-based curing agent include: aliphatic polyamines such as diethylenetriamine and triethylenetetramine; and aromatic polyamines such as methphenylenediamine, diaminodiphenylmethane, and diaminodiphenylsulfone.

Examples of the acid anhydride-based curing agent include phthalic anhydride, tetrahydrophthalic anhydride, hexahydrophthalic anhydride, methyltetrahydrophthalic anhydride, methylnadic anhydride, pyromellitic anhydride, HET anhydride, and dodecenylsuccinic anhydride.

Examples of other curing agents include imidazoles and polymercaptan. These may be used alone or in combination.

Examples of the additive include fillers, gap agents, polymerization initiators, drying agents (moisture absorbents), curing accelerators, coupling agents, flexibilizers, colorants, flame retardant auxiliaries, antioxidants, and organic solvents. These may be used alone or in combination. Among them, fillers, gap agents, curing accelerators, polymerization initiators, and drying agents (moisture absorbents) are preferable, and fillers and polymerization initiators are particularly preferable.

The filler is effective in preventing entry of moisture or oxygen under an external environment. In addition, the filler can obtain effects such as a decrease in volumetric shrinkage at the time of curing, a decrease in an amount of gas generated at the time of curing or heating, improvement of mechanical strength, and control of thermal conductivity or fluidity, and is considerably effective in maintaining a stable output under various environments in the present disclosure.

Regarding the output characteristics or the durability of the photoelectric conversion element, not only an influence caused by moisture or oxygen entering the photoelectric conversion element from an external environment but also an influence caused by gas generated at the time of heating and curing the sealing member cannot be ignored. Particularly, an influence caused by the gas generated at the time of heating greatly affects the output characteristics even when the photoelectric conversion element is used under a high temperature environment.

In this case, when the filler, the gap agent, and the drying agent are included in the sealing member, they can prevent entry of moisture or oxygen, and can decrease an amount of the sealing member used, which makes it possible to obtain an effect of decreasing generation of gas. This is effective not only at the time of curing but also when the photoelectric conversion element is used under a high temperature environment.

The filler is not particularly limited and known products may be used. Preferable examples thereof include inorganic fillers such as crystalline or amorphous silica, talc, alumina, aluminum nitride, silicon nitride, calcium silicate, and calcium carbonate. These may be used alone or in combination.

An average primary particle diameter of the filler is preferably 0.1 μm or more but 10 μm or less, more preferably 1 μm or more but 5 μm or less. When the average primary particle diameter of the filler is 0.1 μm or more but 10 μm or less, an effect of preventing entry of moisture or oxygen can be sufficiently achieved, an appropriate viscosity is obtained, and adhesiveness to a substrate or a defoaming property is improved. Alternatively, it is also effective in terms of control of a width of the sealing part or workability.

An amount of the filler is preferably 10 parts by mass or more but 90 parts by mass or less, more preferably 20 parts by mass or more but 70 parts by mass or less, relative to the total amount of the sealing member. When the amount of the filler is 10 parts by mass or more but 90 parts by mass or less, an effect of preventing entry of moisture or oxygen can be sufficiently obtained, an appropriate viscosity is obtained, and adhesiveness and workability are good.

The gap agent is called a gap controlling agent or a spacer agent, and can control gap of the sealing part. For example, when a sealing member is provided on a first substrate or a first electrode and a second substrate is provided thereon for sealing, gap of the sealing part matches with a size of the gap agent because the gap agent is mixed in an epoxy resin. As a result, it is possible to easily control the gap of the sealing part.

As the gap agent, known materials in the art can be used so long as it has a particulate shape and a uniform particle diameter, and has high solvent resistance and heat resistance. The particulate shape is not particularly limited, but is preferably spherical. Specific examples thereof include glass beads, silica particles, and organic resin particles. These may be used alone or in combination.

A particle diameter of the gap agent can be selected depending on gap of the sealing part to be set. The particle diameter thereof is preferably 1 μm or more but 100 μm or less, more preferably 5 μm or more but 50 μm or less.

The polymerization initiator is a material that is added for the purpose of initiating polymerization using heat or light.

The thermal polymerization initiator is a compound that generates active species such as radical cations through heating. Specific examples thereof include azo compounds such as 2,2″-azobisbutyronitrile (AIBN) and peroxides such as benzoyl peroxide (BPO)). Examples of the thermal cationic polymerization initiator include benzenesulfonic acid esters and alkyl sulfonium salts.

Meanwhile, as the photopolymerization initiator, a photocationic polymerization initiator is preferably used in the case of the epoxy resin. When the photocationic polymerization initiator is mixed with the epoxy resin, followed by irradiation of light, the photocationic polymerization initiator is decomposed to generate strong acid, and the acid induces polymerization of the epoxy resin. Then, curing reaction proceeds. The photocationic polymerization initiator has such effects that volumetric shrinkage during curing is low, oxygen inhibition does not occur, and storage stability is high.

Examples of the photocationic polymerization initiator include aromatic diazonium salts, aromatic iodonium salts, aromatic sulfonium salts, metallocene compounds, and silanol-aluminum complexes. Moreover, a photoacid generator having a function of generating an acid upon irradiation of light can also be used.

The photoacid generator functions as an acid for initiating cationic polymerization. Examples of the photoacid generator include onium salts such as ionic sulfonium salt-based onium salts and ionic iodonium salt-based onium salts including a cation part and an ionic part. These may be used alone or in combination.

An amount of the polymerization initiator is preferably 0.5 parts by mass or more but 10 parts by mass or less, more preferably 1 part by mass or more but 5 parts by mass or less relative to the total amount of the sealing member. The amount of the polymerization initiator satisfying 0.5 parts by mass or more but 10 parts by mass or less allows curing to proceed appropriately, can decrease the remaining uncured products, and can prevent the amount of gas from being excessive, which is effective.

The drying agent is also called a moisture absorbent and is a material having a function of physically or chemically adsorbing or absorbing moisture. Inclusion of the drying agent in the sealing member is effective because moisture resistance may be further improved and influence of the outgas can be decreased in some cases.

The drying agent is preferably particulate. Examples thereof include inorganic water-absorbing materials such as calcium oxide, barium oxide, magnesium oxide, magnesium sulfate, sodium sulfate, calcium chloride, silica gel, molecular sieve, and zeolite. Among them, zeolite is preferable because zeolite absorbs a large amount of moisture. These may be used alone or in combination.

The curing accelerator is also called a curing catalyst and is used for the purpose of accelerating a curing speed. The curing accelerator is mainly used for a thermosetting epoxy resin.

Examples of the curing accelerator include: tertiary amine or tertiary amine salts such as DBU (1,8-diazabicyclo(5,4,0)-undecene-7) and DBN (1,5-diazabicyclo(4,3,0)-nonene-5); imidazole-based compounds such as 1-cyanoethyl-2-ethyl-4-methylimidazole and 2-ethyl-4-methylimidazole; and phosphine or phosphonium salts such as triphenylphosphine and tetraphenylphosphonium.tetraphenyl borate. These may be used alone or in combination.

The coupling agent has an effect of enhancing a bonding force between molecules, and examples thereof include silane coupling agents. Specific examples thereof include: silane coupling agents such as 3-glycidoxypropyltrimethoxysilane, 3-glycidoxypropylmethyldimethoxysilane, 3-glycidoxypropylmethyldimethoxysilane, 2-(3,4-epoxycyclohexyl)ethyltrimethoxysilane, N-phenyl-γ-aminopropyltrimethoxysilane, N-(2-aminoethyl)3-aminopropylmethyldimethoxysilane, N-(2-aminoethyl)3-aminopropylmethyltrimethoxysilane, 3-aminopropyltriethoxysilane, 3-mercaptopropyltrimethoxysilane, vinyltrimethoxysilane, N-(2-(vinylbenzylamino)ethyl)3-aminopropyltrimethoxysilane hydrochloride, and 3-methacryloxypropyltrimethoxysilane. These may be used alone or in combination.

As the sealing member, resin compositions that are commercially available as sealing materials, seal materials, or adhesives have been known, and can be effectively used in the present disclosure. Among them, there are resin compositions that are developed and are commercially available to be used in solar cells or organic EL elements, and can be particularly effectively used in the present disclosure.

Examples of the commercially available products of the epoxy resin include product names: TB3118, TB3114, TB3124, and TB3125F (all of which are available from ThreeBond), World Rock 5910, World Rock 5920, and World Rock 8723 (all of which are available from Kyoritsu Chemical & Co., Ltd.), and WB90US(P) (available from MORESCO).

Examples of the commercially available products of the acrylic resin include product names: TB3035B and TB3035C (both of which are available from ThreeBond) and NICHIBAN UM (available from Nichiban Co., Ltd.).

These sealing members are effective in the present disclosure because they can be subjected to a heat treatment after curing by, for example, irradiation of ultraviolet rays. The heat treatment may decrease an amount of an uncured component in some cases, which is effective in decreasing an amount of outgas that affects output characteristics, in enhancing sealing performance, and in enhancing the output characteristics and its persistence.

A heat treatment temperature is not particularly limited and may be freely set depending on a sealing member to be used. The heat treatment temperature is preferably 50° C. or more but 200° C. or less, more preferably 60° C. or more but 150° C. or less, still more preferably 70° C. or more but 100° C. or less. A heat treatment time is not particularly limited and may be freely set depending on a sealing member to be used. The heat treatment time is preferably 10 minutes or more but 10 hours or less, more preferably 20 minutes or more but 5 hours or less, still more preferably 30 minutes or more but 3 hours or less.

Meanwhile, after a glass resin having a low melting temperature is coated and fired, the resin component is decomposed. Then, while the resin component is melted through, for example, infrared laser, the resultant is allowed to adhere to the grass substrate to thereby perform the sealing. At this time, the glass component having a low melting temperature is diffused inside the metal oxide layer and is physically joined, to thereby obtain high sealing performance. In addition, since the resin component vanishes, outgas as seen in ultraviolet-curing resins is not generated, which is effective in increasing the durability of the photoelectric conversion element. Generally, glass resins having a low melting temperature are commercially available as glass frit or glass paste. These can be effectively used. In the present disclosure, those having a lower melting temperature are preferable.

In the present disclosure, a sheet-shaped sealing material may be effectively used.

The sheet-shaped sealing material is a sheet on which a resin layer has been formed on a sheet in advance. As the sheet, glass or a film having high gas barrier properties may be used, and the sheet-shaped sealing material corresponds to a second substrate in the present disclosure. When the sheet-shaped sealing material is pasted on the second electrode of the photoelectric conversion element, followed by curing, the sealing member and the substrate can be formed at one time. When the resin layer is formed on the whole surface of the sheet, the “surface sealing” is achieved. However, the “frame sealing” that provides a hollow section inside the photoelectric conversion element can be achieved depending on formation patterns of the resin layer.

A position of the sealing member is not particularly limited and may be appropriately selected depending on the intended purpose, so long as the sealing member is disposed at such a position that shields at least the hole-transporting layer, preferably the electron-transporting layer, the hole-transporting layer, and the second electrode from an external environment of the photoelectric conversion element. However, in the present disclosure, the “frame sealing” that provides a hollow section is more preferable because an appropriate amount of oxygen inside the sealed part can be adjusted.

Inclusion of oxygen in the hollow section inside the sealed part makes it possible to stably maintain a function of transporting holes of the hole-transporting layer for a long period of time, which is considerably effective in improving the durability of the photoelectric conversion element. In the present disclosure, effects can be obtained so long as oxygen is included therein, but the oxygen concentration of the hollow section inside the sealed part disposed through the sealing is more preferably 5.0% by volume or more but 21.0% by volume or less, more preferably 10.0% by volume or more but 21.0% by volume or less.

The oxygen concentration of the hollow section can be controlled by performing the sealing in a glove box in which the oxygen concentration has been adjusted. The oxygen concentration can be adjusted by a method using a gas cylinder having a specific oxygen concentration or by a method using a nitrogen gas generator. The oxygen concentration in a glove box is measured using a commercially available oxygen concentration meter or oxygen monitor.

The oxygen concentration inside the hollow section formed through the sealing can be measured through, for example, an atmospheric pressure ionization mass spectrometer (API-MS). Specifically, the photoelectric conversion element is placed in a chamber filled with an inert gas, and the sealed part is opened in the chamber. Then, the gas in the chamber is subjected to quantitative analysis through API-MS, and all the components in the gas contained in the hollow section are quantified. A ratio of oxygen to a total of the all components can be calculated to determine an oxygen concentration.

Gas other than oxygen is preferably inert gas. Examples thereof include nitrogen and argon.

When the sealing is performed, the oxygen concentration and the dew point in a glove box are preferably controlled, and such a control is effective in improving the output and the durability.

The dew point is defined as a temperature at which condensation starts when water vapor-containing gas is cooled.

The dew point is not particularly limited but is preferably 0° C. or less, more preferably −20° C. or less. The lower limit thereof is preferably −50° C. or more.

A method for forming the sealing member is not particularly limited and may be appropriately selected depending on the intended purpose. Examples thereof include various methods such as the dispensing method, the wire bar method, the spin-coating method, the roller coating method, the blade coating method, the gravure coating method, the relief printing, the offset printing, the intaglio printing, the rubber plate printing, and the screen printing.

Moreover, a passivation layer may be disposed between the second electrode and the sealing member. The passivation layer is not particularly limited and may be appropriately selected depending on the intended purpose. For example, aluminum oxide, silicon nitride, and silicon oxide are preferable.

Hereinafter, a photoelectric conversion element of the present disclosure will be described with reference to drawings. However, the present disclosure is not limited thereto. The scope of the present disclosure can encompass those that are not described in the embodiments of the present disclosure regarding, for example, the number, the position, and the shape of the following constituent components.

FIG. 5 is a schematic view presenting one example of a photoelectric conversion element of the present disclosure. As presented in FIG. 5, in a photoelectric conversion element 101, a first electrode 2 is formed on a first substrate 1, and a hole blocking layer 3 is formed on the first electrode 2. An electron-transporting layer 4 is formed on the hole blocking layer 3, and a photosensitization compound 5 is adsorbed on the surface of an electron-transporting material constituting the electron-transporting layer 4. In an upper part and an inner part of the electron-transporting layer 4, a hole-transporting layer 6 is formed, and a second electrode 7 is formed on the hole-transporting layer 6. A second substrate 9 is disposed above the second electrode 7, and the layers between the second substrate 9 and the hole blocking layer 3 are sealed by a sealing member 8.

The photoelectric conversion element presented in FIG. 5 can include a hollow section 10 between the second electrode 7 and the second substrate 9. Since inclusion of the hollow section makes it possible to control an oxygen concentration inside the hollow section, the power generation performance and the durability can be further improved. In addition, the second electrode 7 and the second substrate 9 are not directly in contact with each other, it is possible to prevent the second electrode 7 from being exfoliated and broken.

Note that, the first electrode 2 and the second electrode 7 each have a path configured to allow electric current to pass to an electrode extraction terminal (not illustrated).

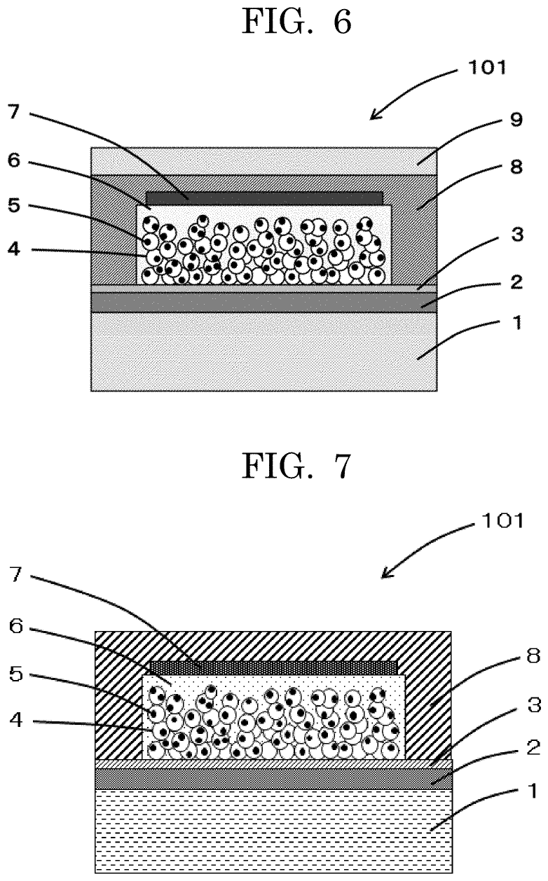

FIG. 6 is a schematic view presenting another example of a photoelectric conversion element of the present disclosure, and presents the case where the hollow section is not provided and the hollow section in FIG. 6 is filled with the sealing member 8.

A method for producing the photoelectric conversion element without the hollow section is not particularly limited and may be appropriately selected depending on the intended purpose. Examples of the method include: a method where the sealing member 8 is coated on the whole surface of the second electrode 7 and the second substrate 9 is provided thereon; and a method using the aforementioned sheet-shaped sealing material.

The hollow section inside the sealed part may be completely absent, or may partially remain. When the surface is almost entirely covered with the sealing member, it is possible to decrease exfoliation or breakage of the second substrate 9 in the case where stress is applied to the photoelectric conversion element due to a twist or falling. As a result, mechanical strength of the photoelectric conversion element can be enhanced. A buffer layer can be disposed between the second electrode 7 and the sealing member 8. As a modification example of FIG. 6, the configuration of FIG. 7 in which the second substrate is not provided may be used.

### <Photoelectric Conversion Module>

A photoelectric conversion module of the present disclosure includes the photoelectric conversion elements of the present disclosure that are electrically coupled in series or in parallel.

The photoelectric conversion module of the present disclosure includes a plurality of photoelectric conversion elements adjacent to each other and includes photoelectric conversion element-disposed regions coupled in series or in parallel. In each of the plurality of photoelectric conversion elements, a photoelectric conversion layer including an electron-transporting layer and a hole-transporting layer is formed between a first electrode and a second electrode.

The photoelectric conversion module of the present disclosure may include a plurality of photoelectric conversion elements. The plurality of photoelectric conversion elements may be coupled in series and/or in parallel. Alternatively, the photoelectric conversion module may include independent photoelectric conversion elements that are not coupled to each other.

The configuration of each layer of the photoelectric conversion module may have the same configuration as that of the photoelectric conversion element.

A structure of the photoelectric conversion module is not particularly limited and may be appropriately selected depending on the intended purpose. However, first electrodes, electron-transporting layers, and second electrodes are preferably separated in at least two photoelectric conversion elements adjacent to each other. This makes it possible to decrease a risk of short circuit. Meanwhile, in the at least two photoelectric conversion elements adjacent to each other, the hole-transporting layers may be separated, or the hole-transporting layers may have configuration of a continuous layer where the hole-transporting layers are extended to each other.

Moreover, the photoelectric conversion module may have a configuration where, in the at least two photoelectric conversion elements adjacent to each other, the first electrode in one photoelectric conversion element is electrically coupled to the second electrode in another photoelectric conversion element through a conduction section penetrating at least from the hole-transporting layer to the hole blocking layer.

The photoelectric conversion module may include a pair of substrates, and photoelectric conversion element-disposed regions coupled in series or in parallel between the pair of substrates. In addition, the photoelectric conversion module may include a configuration where the sealing member may be sandwiched between the pair of substrates.

Hereinafter, one example of a photoelectric conversion module of the present disclosure will be described with reference to drawings. However, the present disclosure is not limited thereto, the scope of the present disclosure can encompass those that are not described in the embodiments of the present disclosure regarding, for example, the number, the position, and the shape of the following constituent components.

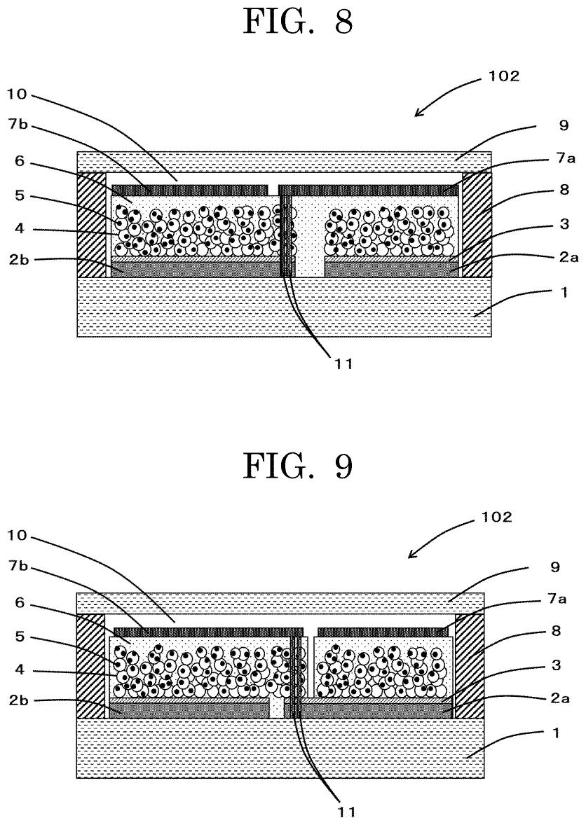

FIG. 8 is a schematic view presenting one example of a photoelectric conversion module of the present disclosure, and presents one example of a cross section of a part of the photoelectric conversion module that includes a plurality of photoelectric conversion elements coupled in series.

In FIG. 8, after a hole-transporting layer 6 is formed, a penetration section 11 is formed. Then, a second electrode 7 is formed thereon, to thereby introduce a material of the second electrode inside the penetration section 11, and this makes it possible to allow electric current to pass to a first electrode 2b of the adjacent cell. Note that, a first electrode 2a and a second electrode 7b each have an electrode of a further adjacent photoelectric conversion element or a path configured to allow electric current to pass to an electrode extraction terminal, which is not illustrated in FIG. 8.

The penetration section 11 may penetrate the first electrode 2 to reach the first substrate 1, or may not reach the first substrate 1 by stopping processing inside the first electrode 2.

In the case where a shape of the penetration section 11 is such a micropore that penetrates the first electrode 2 and reaches the first substrate 1, when a total opening area of the micropore relative to an area of the penetration section 11 is too large, a cross-sectional area of the film of the first electrode 2 is decreased to thereby increase the resistance value, which may cause a decrease of photoelectric conversion efficiency. Therefore, a ratio of the total opening area of the micropore to the area of the penetration section 11 is preferably 5/100 or more but 60/100 or less.

A method for forming the penetration section 11 is not particularly limited and may be appropriately selected depending on the intended purpose. Examples thereof include the sand blasting method, the water blasting method, abrasive paper, the chemical etching method, and the laser processing method. Among them, the laser processing method is preferable. This makes it possible to form a minute hole without using, for example, sand, etching, or a resist, and to perform processing with good cleanness and reproducibility. In addition, when the penetration section 11 is formed, at least one of the hole blocking layer 3, the electron-transporting layer 4, the hole-transporting layer 6, and the second electrode 7 can be removed through impact exfoliation using the laser processing method. As a result, it is not necessary to provide a mask at the time of stacking layers, and removal and formation of the minute penetration section 11 can be easily performed at one time.

FIG. 9 is a schematic view presenting one example of the photoelectric conversion module of the present disclosure. The hole-transporting layer 6 is separated from the adjacent photoelectric conversion element, and each component has an independent layer configuration, which is different from the photoelectric conversion module of FIG. 8. This configuration is advantageous because diffusion of electrons may be prevented and leakage of electric current may be decreased to thereby improve light durability.

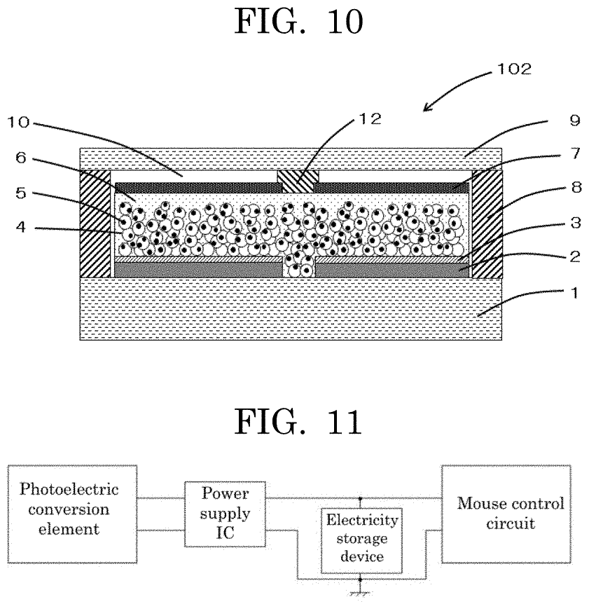

FIG. 10 is one example presenting a cross section of a part of a photoelectric conversion module of the present disclosure that includes a plurality of photoelectric conversion elements coupled in series, and includes a sealing member 12 like a beam in the hollow section between the photoelectric conversion elements. As presented in FIG. 8, disposition of a sealing member 12 such as a beam is effective because exfoliation or breakage of the second electrode 7 can be prevented, and mechanical strength of the sealing can be enhanced. Note that, the materials of the sealing member 8 and the sealing member 12 may be identical or different.

### <Electronic Device>

An electronic device of the present disclosure includes the photoelectric conversion element and/or the photoelectric conversion module of the present disclosure, and a device configured to be driven by electric power generated through photoelectric conversion of the photoelectric conversion element and/or the photoelectric conversion module, and further includes other devices if necessary.

A power supply module of the present disclosure includes the photoelectric conversion element and/or the photoelectric conversion module of the present disclosure and a power supply IC, and further includes other devices if necessary.

A specific embodiment of an electronic device including the photoelectric conversion element and/or the photoelectric conversion module of the present disclosure, and a device configured to be driven by electric power obtained through power generation of the photoelectric conversion element and/or the photoelectric conversion module will be described.

FIG. 11 presents one example where a mouse is used as the electronic device.

As presented in FIG. 11, a photoelectric conversion element and/or a photoelectric conversion module, a power supply IC, and an electricity storage device are combined, and the supplied electric power is allowed to pass to a power supply of a control circuit of a mouse. As a result, the electricity storage device is charged when the mouse is not used, and the mouse can be driven by the electric power, and therefore such a mouse that does not require wiring or replacement of a cell can be obtained. Because a cell is not required, a weight thereof can be decreased, which is effective.

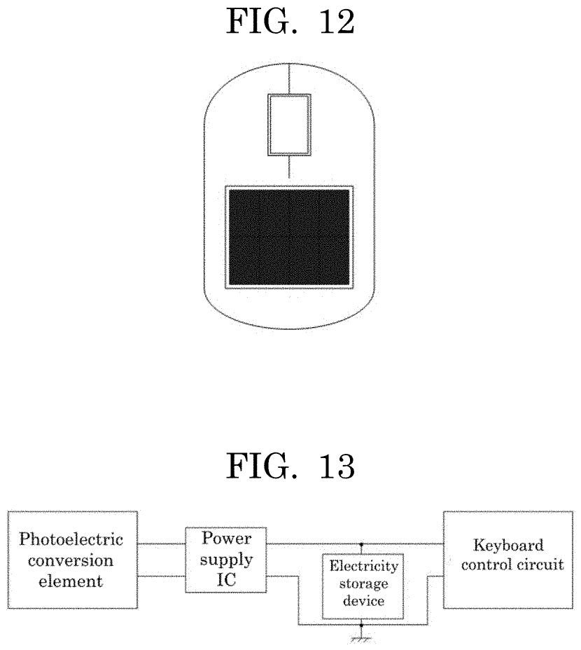

FIG. 12 presents a schematic view where a photoelectric conversion element is mounted in a mouse. A photoelectric conversion element, a power supply IC, and an electricity storage device are mounted inside a mouse, but an upper part of the photoelectric conversion element is covered with a transparent housing so that the photoelectric conversion element receives light. Moreover, the whole housing of the mouse can be formed of a transparent resin. The arrangement of the photoelectric conversion element is not limited to the above. For example, the photoelectric conversion element may be arranged in a position to which light is emitted even when the mouse is covered with a hand, and such arrangement may be preferable.

Another embodiment of an electronic device including the photoelectric conversion element and/or the photoelectric conversion module of the present disclosure, and a device configured to be driven by electric power obtained through power generation of the photoelectric conversion element and/or the photoelectric conversion module will be described.

FIG. 13 presents one example where a keyboard used in a personal computer is used as the electronic device.

As presented in FIG. 13, a photoelectric conversion element, a power supply IC, and an electricity storage device are combined, and the supplied electric power is allowed to pass to a power supply of a control circuit of a keyboard. As a result, the electricity storage device is charged when the keyboard is not used, and the keyboard can be driven by the electric power. Therefore, such a keyboard that does not require wiring or replacement of a cell can be obtained. Since a cell is not required, a weight thereof can be decreased, which is effective.

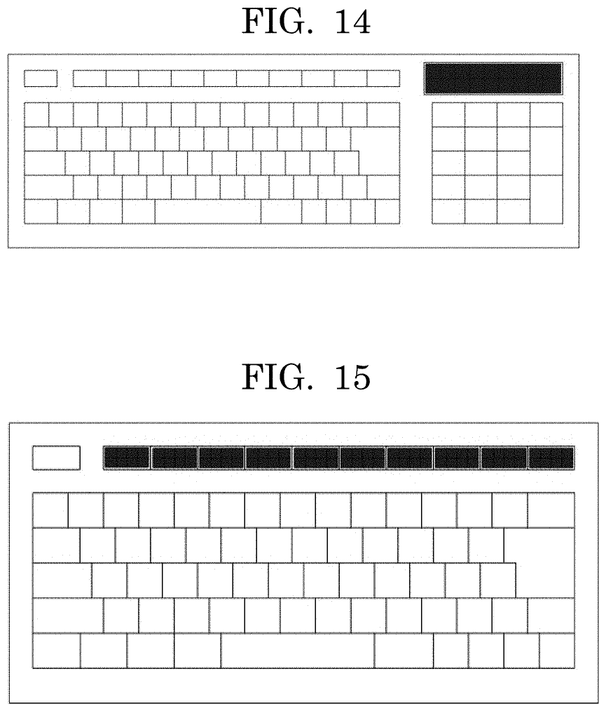

FIG. 14 presents a schematic view in which a photoelectric conversion element is mounted in a keyboard. A photoelectric conversion element, a power supply IC, and an electricity storage device are mounted inside the keyboard, but an upper part of the photoelectric conversion element is covered with a transparent housing so that the photoelectric conversion element receives light. The whole housing of the keyboard can be formed of a transparent resin. The arrangement of the photoelectric conversion element is not limited to the above.

In the case of a small keyboard in which a space for incorporating the photoelectric conversion element is small, a small photoelectric conversion element may be embedded in some keys as presented in FIG. 15, and such arrangement is effective.

Another embodiment of an electronic device including the photoelectric conversion element and/or the photoelectric conversion module of the present disclosure, and a device configured to be driven by electric power obtained through power generation of the photoelectric conversion element and/or the photoelectric conversion module will be described.

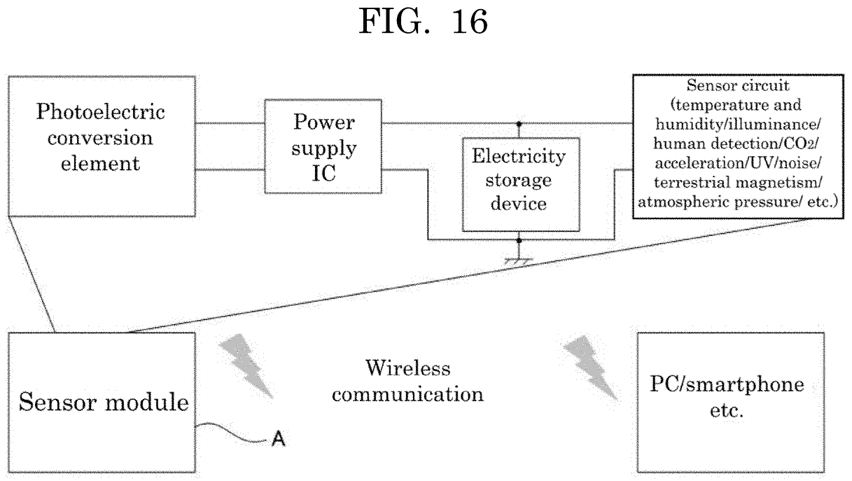

FIG. 16 presents one example where a sensor is used as the electronic device.

As presented in FIG. 16, a photoelectric conversion element, a power supply IC, and an electricity storage device are combined, and the supplied electric power is allowed to pass to a power supply of a sensor circuit. As a result, a sensor module can be constituted without requiring connection to an external power supply and without requiring replacement of a cell. A sensing target is, for example, temperature and humidity, illuminance, human detection, CO₂, acceleration, ultraviolet rays (UV), noise, terrestrial magnetism, and atmospheric pressure, and such an electronic device can be applied to various sensors, which is effective. As presented in A in FIG. 16, the sensor module is configured to sense a target to be measured on a regular basis and to transmit the read data to a personal computer (PC) or a smartphone through wireless communication.

It is expected that use of sensors is significantly increased as the internet of things (IoT) society approaches. Replacing batteries of numerous sensors one by one is time consuming and is not realistic. Moreover, the fact that a sensor is installed at a position such as a ceiling and a wall where a cell is not easily replaced also makes workability bad. Moreover, supplying electric power by the photoelectric conversion element is also a significantly large advantage. In addition, the photoelectric conversion element of the present disclosure has advantages that a high output can be obtained even with light of a low illuminance and a high degree of freedom in installation can be achieved because dependence of light incident angle for the output is small.

Another embodiment of an electronic device including the photoelectric conversion element and/or the photoelectric conversion module of the present disclosure and a device configured to be driven by electric power obtained through power generation of the photoelectric conversion element and/or the photoelectric conversion module will be described.

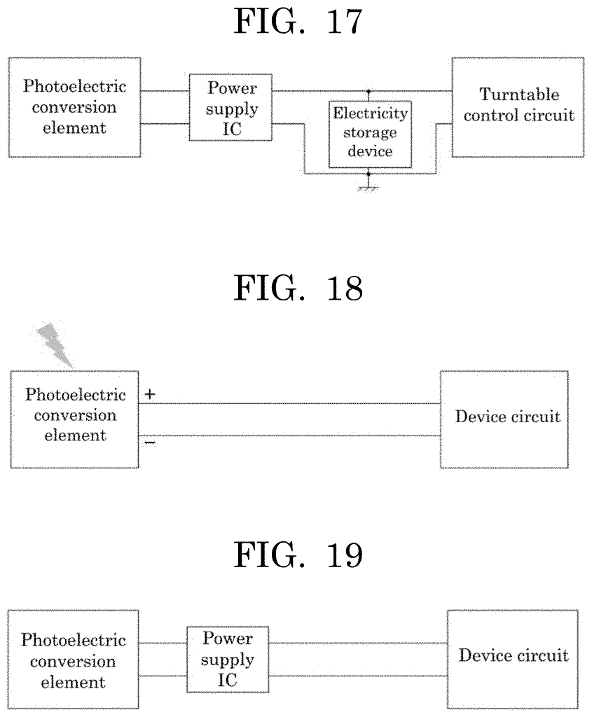

FIG. 17 presents one example in which a turntable is used as the electronic device.

As presented in FIG. 17, the photoelectric conversion element, a power supply IC, and an electricity storage device are combined, and the supplied electric power is allowed to pass to a power supply of a turntable circuit. As a result, the turntable can be constituted without requiring connection to an external power supply and without requiring replacement of a cell.

The turntable is used, for example, in a display case in which products are displayed. Wiring of a power supply degrades appearance of the display, and moreover displayed products need to be removed at the time of replacing a cell, which is time-consuming. Use of the photoelectric conversion element of the present disclosure is effective because the aforementioned problems can be solved.

### <Use>

As described above, the electronic device including the photoelectric conversion element and/or the photoelectric conversion module of the present disclosure and the device configured to be driven by electric power obtained through power generation of the photoelectric conversion element and/or the photoelectric conversion module, and the power supply module have been described above. However, the embodiments described are only part of applicable embodiments, and use of the photoelectric conversion element or the photoelectric conversion module of the present disclosure is not limited to the above-described uses.

The photoelectric conversion element and/or the photoelectric conversion module can be applied for, for example, a power supply device by combining it with a circuit board configured to control generated electric current.

Examples of devices using the power supply device include electronic desk calculators, watches, mobile phones, electronic organizers, and electronic paper.

Moreover, a power supply device including the photoelectric conversion element can be used as an auxiliary power supply for prolonging a continuous operating time of a charge-type or dry cell-type electronic equipment.

The photoelectric conversion element and the photoelectric conversion module of the present disclosure can function as a self-sustaining power supply, and electric power generated through photoelectric conversion can be used to drive a device. Since the photoelectric conversion element and the photoelectric conversion module of the present disclosure can generate electricity by irradiation of light, it is not necessary to couple the electronic device to a power supply or to replace a cell. Therefore, the electronic device can be driven in a place where there is no power supply facility, the electronic device can be worn or carried, and the electronic device can be driven without replacement of a cell even in a place where a cell is not easily replaced. Moreover, when a dry cell is used, the electronic device becomes heavy by a weight of the dry cell, or the electronic device becomes large by a size of the dry cell. Therefore, there may be a problem in installing the electronic device on a wall or ceiling, or transporting the electronic device. Since the photoelectric conversion element and the photoelectric conversion module of the present disclosure are light and thin, they can be freely installed, and can be worn and carried, which is advantageous.

As described above, the photoelectric conversion element and the photoelectric conversion module of the present disclosure can be used as a self-sustaining power supply, and can be combined with various electronic devices. For example, the photoelectric conversion element and the photoelectric conversion module of the present disclosure can be used in combination with a display device (e.g., an electronic desk calculator, a watch, a mobile phone, an electronic organizer, and electronic paper), an accessory device of a personal computer (e.g., a mouse and a keyboard), various sensor devices (e.g., a temperature and humidity sensor and a human detection sensor), transmitters (e.g., a beacon and a global positioning system (GPS)), and numerous electronic devices (e.g., an auxiliary lamp and a remote controller).

The photoelectric conversion element and the photoelectric conversion module of the present disclosure are widely applied because they can generate electricity particularly with light of a low illuminance and can generate electricity indoors and in further darker shade. Moreover, the photoelectric conversion element and the photoelectric conversion module are highly safe because liquid leakage found in the case of a dry cell does not occur, and accidental ingestion found in the case of a button cell does not occur. Furthermore, the photoelectric conversion element and the photoelectric conversion module can be used as an auxiliary power supply for the purpose of prolonging a continuous operation time of a charge-type or dry cell-type electronic equipment. As described above, when the photoelectric conversion element and the photoelectric conversion module of the present disclosure are combined with a device configured to be driven by electric power generated through photoelectric conversion of the photoelectric conversion element and/or the photoelectric conversion module, it is possible to obtain an electronic device that is light and easy to use, has a high degree of freedom in installation, does not require replacement of a cell, is excellent in safety, and is effective in decreasing environmental loads.

FIG. 18 presents a basic configuration diagram of an electronic device obtained by combining the photoelectric conversion element and/or the photoelectric conversion module of the present disclosure with a device configured to be driven by electric power generated through photoelectric conversion of the photoelectric conversion element and/or the photoelectric conversion module. The electronic device can generate electricity when the photoelectric conversion element is irradiated with light, and can extract electric power. A circuit of the device can be driven by the generated electric power.

Since the output of the photoelectric conversion element varies depending on circumferential illuminance, the electronic device presented in FIG. 18 may not be stably driven in some cases. In this case, as presented in FIG. 19, a power supply IC for a photoelectric conversion element can be incorporated between the photoelectric conversion element and the circuit of the device in order to supply stable voltage to a side of the circuit, and such arrangement is effective.

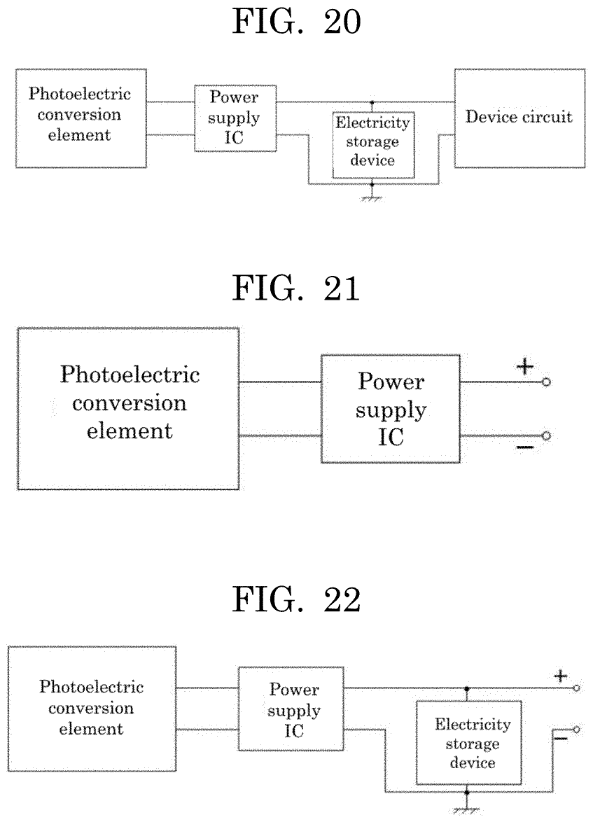

The photoelectric conversion element can generate electricity so long as light of a sufficient illuminance is applied thereto. However, when an illuminance for generating electricity is not enough, desired electric power cannot be obtained, which is a disadvantage of the photoelectric conversion element. In this case, as presented in FIG. 20, when an electricity storage device such as a capacitor is mounted between a power supply IC and a device circuit, excess electric power from the photoelectric conversion element can be stored in the electricity storage device. In addition, the electric power stored in the electricity storage device can be supplied to a device circuit to thereby enable stable operation when the illuminance is too low or even when light is not applied to the photoelectric conversion element.

As described above, the electronic device obtained by combining the photoelectric conversion element and/or the photoelectric conversion module of the present disclosure with the device circuit can be driven even in an environment without a power supply, does not require replacement of a cell, and can be stably driven in combination with a power supply IC or an electricity storage device. Therefore, it is possible to make the most of advantages of the photoelectric conversion element.

Meanwhile, the photoelectric conversion element and/or the photoelectric conversion module of the present disclosure can also be used as a power supply module, and such use is effective. As presented in FIG. 21, for example, when the photoelectric conversion element and/or the photoelectric conversion module of the present disclosure are coupled to a power supply IC for a photoelectric conversion element, a DC power supply module capable of supplying electric power generated through photoelectric conversion of the photoelectric conversion element to the power supply IC at a predetermined voltage level can be constituted.

Moreover, as presented in FIG. 22, when an electricity storage device is added to a power supply IC, electric power generated by the photoelectric conversion element can be stored in the electricity storage device. Therefore, a power supply module to which electric power can be supplied can be constituted when the illuminance is too low or even when light is not applied to the photoelectric conversion element.

The power supply modules of the present disclosure presented in FIG. 21 and FIG. 22 can be used as a power supply module without replacement of a cell as in case of conventional primary cells.

### EXAMPLES

Hereinafter, the present disclosure will be described by way of Examples and Comparative Examples. However, the present disclosure should not be construed as being limited to Examples exemplified herein.

### Production of Photoelectric Conversion Element

### Example 1

On a glass substrate as a first substrate, a film of indium-doped tin oxide (ITO) and a film of niobium-doped tin oxide (NTO) as a first electrode were sequentially formed through sputtering. Then, a compact layer formed of titanium oxide as a hole blocking layer was formed through reactive sputtering with oxygen gas.

Next, titanium oxide (ST-21, obtained from ISHIHARA SANGYO KAISHA, LTD.) (3 parts by mass), acetylacetone (0.2 parts by mass), and polyoxyethylene octylphenyl ether (obtained from Wako Pure Chemical Industries, Ltd.) (0.3 parts by mass) as a surfactant were subjected to a bead mill treatment for 12 hours together with water (5.5 parts by mass) and ethanol (1.0 part by mass). To the titanium oxide dispersion liquid obtained, polyethylene glycol (polyethylene glycol 20,000, obtained from Wako Pure Chemical Industries, Ltd.) (1.2 parts by mass) was added, to thereby prepare paste.

The paste prepared was coated on the hole blocking layer (average thickness: about 1.2 μm) and was dried at 100° C. Then, the resultant was fired at 550° C. for 30 minutes in the air, to thereby form a porous electron-transporting layer.

The glass substrate on which the electron-transporting layer had been formed was immersed in a mixed solution including a photosensitization compound expressed by the B-5 and acetonitrile/t-butanol (volume ratio: 1:1) and was left to stand for 1 hour in the dark. Then, the excess photosensitization compound was removed, and the photosensitization compound was adsorbed on the surface of the electron-transporting layer.

To chlorobenzene (1,550 parts by mass), lithium bis(trifluoromethanesulfonyl)imide (LiTFSI) as a lithium salt (obtained from KANTO CHEMICAL CO., INC.) (30 parts by mass), a compound including a pyridine ring structure expressed by the C-10 (55 parts by mass), a hole-transporting material expressed by the D-7 (obtained from Merck KGaA) (273 parts by mass), a cobalt complex expressed by the F-11 as an oxidizing agent (obtained from Sigma-Aldrich Japan) (26 parts by mass), and acetonitrile (obtained from KANTO CHEMICAL CO., INC.) (80 parts by mass) were added, followed by dissolving, to prepare a coating liquid for a hole-transporting layer.

Next, on the electron-transporting layer to which the photosensitization compound had been adsorbed, a hole-transporting layer was formed (average thickness: about 500 nm) through the die coating method using the coating liquid for the hole-transporting layer. Then, the hole-transporting layer coated on the peripheral portions of the glass substrate was removed. On the hole-transporting layer, silver was deposited under vacuum to thereby form a second electrode (average thickness: 100 nm).

On the peripheral portions of the glass substrate from which the hole-transporting layer had been removed, an ultraviolet-curing resin (World Rock No. 5910, obtained from Kyoritsu Chemical & Co., Ltd.) as a sealing member was coated using a dispenser (2300N, obtained from SAN-EI TECH LTD.) so as to surround a power generation region. Then, it was transferred to a glove box into which high purity air (dew point: −50° C.) had been introduced, and a cover glass as a second substrate was placed on the ultraviolet-curing resin. Then, the resin was cured by irradiation of ultraviolet rays to seal the power generation region. The resultant was finally subjected to a heat treatment at 80° C. for 1 hour, to produce a photoelectric conversion element of Example 1 as presented in FIG. 5.

### Example 2

A photoelectric conversion element of Example 2 was produced in the same manner as in Example 1 except that the lithium salt was changed to lithium (fluorosulfonyl)(trifluoromethanesulfonyl)imide (LiFTFSI) (obtained from PROVISCO CS) (25 parts by mass); the amount of the compound including a pyridine ring structure was changed to 56 parts by mass; the amount of the hole-transporting material was changed to 277 parts by mass; and the amount of the oxidizing agent was changed to 27 parts by mass in the preparation of the coating liquid for the hole-transporting layer.

### Example 3

A photoelectric conversion element of Example 3 was produced in the same manner as in Example 2 except that the amount of the lithium salt was changed to 28 parts by mass; the amount of the compound including a pyridine ring structure was changed to 55 parts by mass; and the amount of the hole-transporting material was changed to 273 parts by mass in the preparation of the coating liquid for the hole-transporting layer.

### Example 4

A photoelectric conversion element of Example 4 was produced in the same manner as in Example 2 except that the amount of the lithium salt was changed to 31 parts by mass; the amount of the compound including a pyridine ring structure was changed to 55 parts by mass; and the amount of the hole-transporting material was changed to 271 parts by mass in the preparation of the coating liquid for the hole-transporting layer.

### Example 5

A photoelectric conversion element of Example 5 was produced in the same manner as in Example 2 except that the amount of the lithium salt was changed to 27 parts by mass; the compound including a pyridine ring structure was changed to a compound including a pyridine ring structure expressed by the C-12 (59 parts by mass); the amount of the hole-transporting material was changed to 264 parts by mass; and the amount of the oxidizing agent was changed to 32 parts by mass in the preparation of the coating liquid for the hole-transporting layer.

### Example 6

A photoelectric conversion element of Example 6 was produced in the same manner as in Example 5 except that the amount of the lithium salt was changed to 28 parts by mass; the amount of the compound including a pyridine ring structure was changed to 58 parts by mass; the amount of the hole-transporting material was changed to 258 parts by mass; and the amount of the oxidizing agent was changed to 38 parts by mass in the preparation of the coating liquid for the hole-transporting layer.

### Example 7

A photoelectric conversion element of Example 7 was produced in the same manner as in Example 2 except that the amount of the lithium salt was changed to 28 parts by mass; the amount of the compound including a pyridine ring structure was changed to 55 parts by mass; the amount of the hole-transporting material was changed to 274 parts by mass; and the oxidizing agent was changed to a cobalt complex expressed by the F-22 (obtained from Sigma-Aldrich Japan) (25 parts by mass) in the preparation of the coating liquid for the hole-transporting layer.

### Example 8

A photoelectric conversion element of Example 8 was produced in the same manner as in Example 7 except that the amount of the lithium salt was changed to 30 parts by mass; the amount of the compound including a pyridine ring structure was changed to 54 parts by mass; the amount of the hole-transporting material was changed to 270 parts by mass; and the amount of the oxidizing agent was changed to 29 parts by mass in the preparation of the coating liquid for the hole-transporting layer.

### Example 9

A photoelectric conversion element of Example 9 was produced in the same manner as in Example 1 except that the coating method of the coating liquid for the hole-transporting layer was changed to spin coating in the formation of the hole-transporting layer.

### Example 10

A photoelectric conversion element of Example 10 was produced in the same manner as in Example 1 except that the heat treatment after sealing was performed at 80° C. for 2 hours.

### Example 11

A photoelectric conversion element of Example 11 was produced in the same manner as in Example 1 except that the heat treatment after sealing was not performed.

### Comparative Example 1

A photoelectric conversion element of Comparative Example 1 was produced in the same manner as in Example 1 except that the coating liquid for the hole-transporting layer did not include a lithium salt.

### <Measurement of TOF-SIMS>

The sealed portion of the produced photoelectric conversion element was opened, and the second electrode was exfoliated by a piece of adhesive tape, to obtain a sample for TOF-SIMS measurement. As a device, TOF. SIMS 5 (obtained from ION-TOF) was used. The depth direction analysis of lithium from the hole-transporting layer to the first substrate via the electron-transporting layer was performed by GCIB. Measurement was performed by changing the sputter time between the measurements at two portions on the same sample. First, in the measurement from the hole-transporting layer to the electron-transporting layer, the measurement was stopped approximately 30 seconds after sputtering when the electron-transporting layer appeared (i.e., (1) Sputter time 30 s). Next, in the measurement from the electron-transporting layer to the first substrate, the measurement was stopped at (2) Sputter frames 1, at which Si derived from the first substrate was detected. The measurement of (1) and the measurement of (2) were performed on the same day. When intensity of lithium was saturated, the Pulsing width was adjusted to 19 ns. Measurement conditions were as follows.
Primary ion: Bi3++
Primary ion acceleration voltage: 30 KV
Secondary ion polarity: positive
Measurement area: 250 μm×250 μm
Charging neutralization correction: Presence
Sputtering: Ar-GCIB
Sputtering acceleration voltage: 20 KV
Raster size: 128×128 pixel
Sputtering mode: non-interlaced mode
   Analysis: 1 frames
   Sputter time 30 s or Sputter frames 1
   Pause time: 0.5 seconds
Sputtering area 500 μm×500 μm

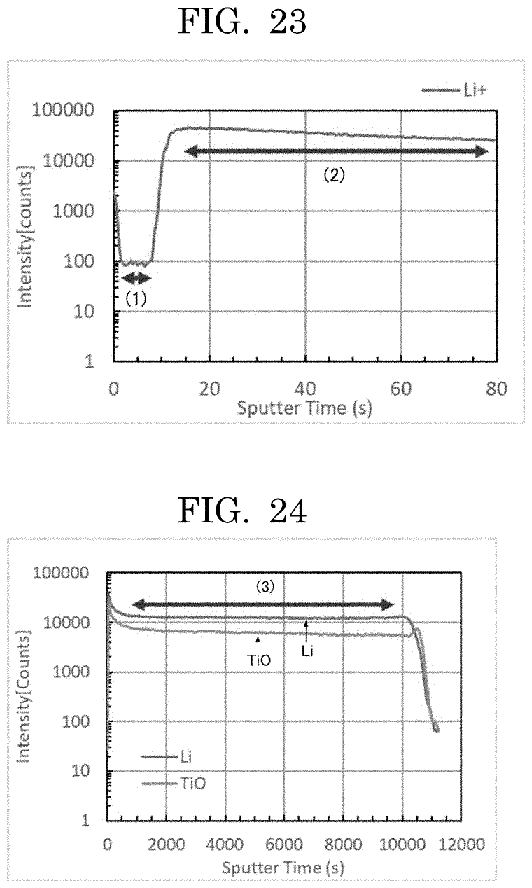

FIG. 23 presents one example of a depth profile of TOF-SIMS. FIG. 23 is one example of a depth profile from the hole-transporting layer to the electron-transporting layer. In FIG. 23, the profile (1) obtained by sputtering within 10 seconds corresponds to the hole-transporting layer, and the profile (2) obtained by sputtering for 10 seconds or longer corresponds to the electron-transporting layer. FIG. 23 presents a profile of a lithium ion only. When the profile of lithium and the profile of titanium oxide included in the electron-transporting layer are overlapped, regions of the hole-transporting layer and the electron-transporting layer are clearer.

The depth profile of TOF-SIMS is not always linear, may be a curve, or may have a slope in some cases. In order to determine an ionic intensity of lithium, the ionic intensity can be converted into a numerical value by obtaining an average value in its region. For example, the ionic intensity of lithium in the electron-transporting layer in FIG. 23 can be converted into a numerical value by obtaining an average value in the flat region excluding a region having the steep region.

For example, the region (1) in FIG. 23 is a region of the hole-transporting layer. Therefore, when an average value in this region is determined, the ionic intensity of lithium can be estimated to be about 90. Meanwhile, the region (2) in FIG. 23 is a region of the electron-transporting layer. Therefore, when an average value in this region is determined, the ionic intensity of lithium can be estimated to be about 34,000.

A ratio (I_{E}/I_{H}) of an average value (I_{E}) of ionic intensities of lithium contained in the electron-transporting layer to an average value (I_{H}) of ionic intensities of lithium contained in the hole-transporting layer obtained by the aforementioned method can be calculated. These results are presented in Table 1.

FIG. 24 presents one example of a depth profile from the electron-transporting layer to the first substrate. FIG. 24 presents the profile of lithium and the profile of titanium oxide included in the electron-transporting layer. In order to determine an ionic intensity of lithium or titanium oxide, the ionic intensity can be converted into a numerical value by obtaining an average value in its region in the same manner as described above.

For example, an ionic intensity of lithium in the electron-transporting layer in FIG. 24 can be judged as the region (3). Therefore, when an average value in this region is determined, the ionic intensity of lithium can be estimated to be about 12,500. Meanwhile, an ionic intensity of titanium oxide in FIG. 24 is also the region (3). Therefore, when an average value in this region is determined, the ionic intensity of titanium oxide in the electron-transporting layer can be estimated to be about 6,100.

A ratio (I_{E}/I_{E2}) of an average value (I_{E}) of ionic intensities of lithium contained in the electron-transporting layer to an average value (I_{E2}) of ionic intensities of titanium oxide contained in the electron-transporting layer obtained by the aforementioned method can be calculated. These results are presented in Table 1.

### <Output Characteristics and Durability Test of Photoelectric Conversion Element>

Using a solar cell test system (As-510-PV03, obtained from NF CORPORATION), under irradiation of white LED of which illuminance had been adjusted to 200 lux, each of the produced photoelectric conversion elements was evaluated for IV characteristics. An initial maximum output power P max 1 (μW/cm²) thereof was determined.

Next, the photoelectric conversion element was irradiated with white LED of which illuminance had been adjusted to 10,000 lux for 1,000 hours. Then, the photoelectric conversion element was evaluated again for IV characteristics under irradiation of white LED of which illuminance had been adjusted to 200 lux, and a maximum output power P max 2 (μW/cm²) after the test was determined.

Finally, the maximum output power P max 2 (μW/cm²) after the test was divided by the initial maximum output power P max 1 (μW/cm²) to thereby determine a P max maintenance rate (P max 2/P max 1×100) after the durability test. These results are presented in Table 1.

### <Production of Photoelectric Conversion Module>

On a glass substrate as a first substrate, a film of indium-doped tin oxide (ITO) and a film of niobium-doped tin oxide (NTO) as a first electrode were sequentially formed through sputtering. Then, a compact layer formed of titanium oxide as a hole blocking layer was formed through reactive sputtering with oxygen gas.

The first electrode formed on the substrate and the hole blocking layer were partially subjected to an etching treatment through laser processing to divide the adjacent photoelectric conversion element.

Next, an electron-transporting layer was formed in the same manner as in Example 1.

Subsequently, the electron-transporting layer was subjected to an etching treatment through laser processing to divide a part between the adjacent photoelectric conversion elements.

Then, a photosensitization compound was adsorbed on the surface of the electron-transporting layer in the same manner as in Example 1. A coating liquid for forming a hole-transporting layer was prepared in the same manner as in Example 1, and the coating liquid was used to form a hole-transporting layer on the electron-transporting layer through die coating (average thickness: about 500 nm).

The peripheral portions of the glass substrate on which a sealing member would be provided were subjected to an etching treatment through laser processing, and then through holes configured to couple photoelectric conversion elements in series were formed through further laser processing.

Furthermore, silver was deposited thereon under vacuum to thereby form a second electrode (average thickness: about 100 nm). At this time, silver was also deposited on the inner walls of the through holes. Then, it was confirmed that the adjacent photoelectric conversion elements were coupled in series.

On the peripheral portions of the glass substrate, an ultraviolet-curing resin (World Rock No. 5910, obtained from Kyoritsu Chemical & Co., Ltd.) as a sealing member was coated using a dispenser (2300N, obtained from SAN-EI TECH LTD.) so as to surround a power generation region. Then, it was transferred to a glove box into which high purity air (dew point: −60° C.) had been introduced, and a cover glass as a second substrate was placed on the ultraviolet-curing resin. Then, the resin was cured by irradiation of ultraviolet rays, and was further subjected to a heat treatment at 80° C. for 1 hour, to produce a photoelectric conversion module of Example 12 as presented in FIG. 8.

### Example 13

A photoelectric conversion module of Example 13 was produced in the same manner as in Example 12 except that a coating liquid for a hole-transporting layer was prepared in the same manner as in Example 2.

### Example 14

A photoelectric conversion module of Example 14 was produced in the same manner as in Example 12 except that a coating liquid for a hole-transporting layer was prepared in the same manner as in Example 3.

### Example 15

A photoelectric conversion module of Example 15 was produced in the same manner as in Example 12 except that a coating liquid for a hole-transporting layer was prepared in the same manner as in Example 4.

### Example 16

A photoelectric conversion module of Example 16 was produced in the same manner as in Example 12 except that a coating liquid for a hole-transporting layer was prepared in the same manner as in Example 5.

### Example 17

A photoelectric conversion module of Example 17 was produced in the same manner as in Example 12 except that a coating liquid for a hole-transporting layer was prepared in the same manner as in Example 6.

### Example 18

A photoelectric conversion module of Example 18 was produced in the same manner as in Example 12 except that a coating liquid for a hole-transporting layer was prepared in the same manner as in Example 7.

### Example 19

A photoelectric conversion module of Example 19 was produced in the same manner as in Example 12 except that a coating liquid for a hole-transporting layer was prepared in the same manner as in Example 8.

### Example 20

A photoelectric conversion module of Example 20 was produced in the same manner as in Example 12 except that a heat treatment after sealing was not performed.

### Comparative Example 2

A photoelectric conversion module of Comparative Example 2 was produced in the same manner as in Example 12 except that the coating liquid for the hole-transporting layer contained no lithium salt.

### <Measurement of TOF-SIMS>

Each of the photoelectric conversion modules produced in Examples 12 to 20 was subjected to the TOF-SIMS measurement in the same manner as described above. These results are presented in Table 1.

### <Output Characteristics and Durability Test of Photoelectric Conversion Module>

Each of the photoelectric conversion modules produced in Examples 12 to 20 was evaluated for IV characteristics in the same manner as described above to determine an initial maximum output power P max (μW/cm²) and a P max maintenance rate (P max 2/P max 1×100). These results are presented in Table 1.

TABLE 1

| | | Hole | | | | | | | | Initial | Pmax |
|---|---|---|---|---|---|---|---|---|---|---|---|
| | | transporting | Oxidizing | Lithium | Pyridine | Coating | Heat | | | Pmax | maintenance |
| | Dye | material | agent | salt | compound | method | treatment | I_{E}/I_{H} | I_{E}/I_{E2} | (μW/cm2) | rate (%) |
| Ex. 1 | B-5 | D-7 | F-11 | Li-TFSI | C-10 | Die | 80° C. | 109 | 2.0 | 10.8 | 88 |
| Ex. 2 | | | | Li-FTFSI | | coating | 60 min | 137 | 2.2 | 11.3 | 92 |
| Ex. 3 | | | | | | | | 272 | 3.4 | 11.1 | 93 |
| Ex. 4 | | | | | | | | 415 | 4.3 | 10.5 | 92 |
| Ex. 5 | | | | | C-12 | | | 203 | 2.7 | 10.9 | 92 |
| Ex. 6 | | | | | | | | 229 | 2.9 | 10.6 | 91 |
| Ex. 7 | | | F-22 | | C-10 | | | 217 | 2.7 | 10.7 | 92 |
| Ex. 8 | | | | | | | | 269 | 3.1 | 10.3 | 89 |
| Ex. 9 | | | F-11 | Li-TFSI | | Spin | | 26 | 8.4 | 11.0 | 93 |
| | | | | | | coating | | | | | |
| Ex. 10 | | | | | | Die | 80° C. | 117 | 2.1 | 10.9 | 90 |
| | | | | | | coating | 120 min | | | | |
| Ex. 11 | | | | | | | None | 83 | 1.2 | 8.5 | 85 |
| Comp. | | | | None | | | 80° C. | — | 0.0 | 3.8 | 28 |
| Ex. 1 | | | | | | | 60 min | | | | |
| Ex. 12 | | | | Li-TFSI | | | | 113 | 2.0 | 57.3 | 85 |
| Ex. 13 | | | | Li-FTFSI | | | | 144 | 2.3 | 63.1 | 88 |
| Ex. 14 | | | | | | | | 274 | 3.4 | 62.8 | 91 |
| Ex. 15 | | | | | | | | 406 | 4.5 | 61.6 | 92 |
| Ex. 16 | | | | | C-12 | | | 210 | 2.7 | 60.3 | 92 |
| Ex. 17 | | | | | | | | 233 | 3.0 | 59.1 | 91 |
| Ex. 18 | | | F-22 | | C-10 | | | 216 | 2.6 | 61.5 | 91 |
| Ex. 19 | | | | | | | | 275 | 3.1 | 58.7 | 89 |
| Ex. 20 | | | F-11 | Li-TFSI | | | None | 90 | 1.3 | 46.9 | 83 |
| Comp. | | | | None | | | 80° C. | — | 0.0 | 19.8 | 25 |
| Ex. 2 | | | | | | | 60 min | | | | |

As seen from the aforementioned results, it was found that when the ionic intensity of lithium in the electron-transporting layer was higher than the ionic intensity of lithium in the hole-transporting layer (I_{E}/I_{H}>1), the initial output was improved, and the output maintenance rate of power generation over time was also improved. In particular, when the I_{E}/I_{H}≥100 was satisfied, these effects were significantly improved. It was found that use of Li-FTFSI having an asymmetrical anionic species was effective in further improving the output and improving the maintenance rate of the initial output. The reason for this was because use of a lithium salt asymmetrical to the anionic species made it possible to improve solubility and to increase an amount of the lithium salt added. As a result, it was believed that an amount of lithium ions in the electron-transporting layer could be increased.

Moreover, it was revealed that the heat treatment promoted migrating of lithium from the hole-transporting layer to the electron-transporting layer, and the effects of the present disclosure could be further enhanced.

When the coating liquid for the hole-transporting layer was coated through spin coating, the I_{E}/I_{H} was greatly decreased, but good results of the initial output and the maintenance rate could be obtained. The reason for this was because it was believed that the I_{E}/I_{H} was decreased, while the I_{E}/I_{E2} could be significantly increased. The reason for this can be explained by the following suggestion. Specifically, a larger amount of lithium ions migrating from the hole-transporting layer to the electron-transporting layer is more effective when the amount of lithium is the same. However, irrespective of the migrating amount, when an absolute amount of lithium ions in the electron-transporting layer can be increased, the effects of the present disclosure can be obtained.

Aspects of the present disclosure are as follows, for example.

<1> A photoelectric conversion element including:

a first electrode;

a photoelectric conversion layer; and

a second electrode,

wherein the photoelectric conversion layer includes an electron-transporting layer and a hole-transporting layer,

the electron-transporting layer includes a lithium ion,

the hole-transporting layer includes an organic hole-transporting material and a lithium salt, and

lithium included in the electron-transporting layer is more than lithium included in the hole-transporting layer.

<2> The photoelectric conversion element according to <1>,

wherein the lithium included in the electron-transporting layer being more than the lithium included in the hole-transporting layer is determined by an average value of ionic intensities of the lithium included in the electron-transporting layer being larger than an average value of ionic intensities of the lithium included in the hole-transporting layer, in a depth profile obtained by measuring the lithium included in the electron-transporting layer and the lithium included in the hole-transporting layer by a measurement method (1) or (2) below:

(1) after the second electrode is removed from the photoelectric conversion element, a gas cluster ion beam is applied toward the hole-transporting layer and the electron-transporting layer from a side of the hole-transporting layer, to cut the hole-transporting layer and the electron-transporting layer to prepare an exposed surface; and the lithium of the exposed surface is measured through time-of-flight secondary ion mass spectrometry (TOF-SIMS) in a thickness direction of the hole-transporting layer and the electron-transporting layer, to measure a distribution of the lithium in the thickness direction of the hole-transporting layer and the electron-transporting layer; and

(2) after the second electrode is removed from the photoelectric conversion element, the hole-transporting layer and the electron-transporting layer are cut by a cutting blade in a diagonal direction relative to a thickness direction from a side of an exposed surface of the hole-transporting layer, to form an exposed surface in the diagonal direction; and the lithium of the exposed surface is measured through time-of-flight secondary ion mass spectrometry (TOF-SIMS) to measure a distribution of the lithium in the thickness direction of the hole-transporting layer and the electron-transporting layer.

<3> The photoelectric conversion element according to <2>,

wherein, in the depth profile of the time-of-flight secondary ion mass spectrometry (TOF-SIMS), a ratio (I_{E}/I_{H}) of an average value (I_{E}) of ionic intensities of the lithium included in the electron-transporting layer to an average value (I_{H}) of ionic intensities of the lithium included in the hole-transporting layer is 100 or more.

<4> The photoelectric conversion element according to <2> or <3>,

wherein, in the depth profile of the time-of-flight secondary ion mass spectrometry (TOF-SIMS), a ratio (I_{E}/I_{E2}) of an average value (I_{E}) of ionic intensities of the lithium included in the electron-transporting layer to an average value (I_{E2}) of ionic intensities of an electron-transporting material included in the electron-transporting layer is 1.5 or more.

<5> The photoelectric conversion element according to any one of <1> to <4>,

wherein the lithium salt includes at least one selected from the group consisting of lithium bis(trifluoromethanesulfonyl)imide and lithium (fluorosulfonyl)(trifluoromethanesulfonyl)imide.

<6> The photoelectric conversion element according to any one of <1> to <5>,

wherein the organic hole-transporting material includes a spiro compound.

<7> The photoelectric conversion element according to any one of <1> to <6>,

wherein the electron-transporting layer includes a titanium oxide particle including a photosensitization compound adsorbed on a surface of the titanium oxide particle.

<8> The photoelectric conversion element according to any one of <1> to <7>,

wherein the hole-transporting layer further includes a compound including a pyridine ring structure.

<9> The photoelectric conversion element according to any one of <1> to <8>,

wherein the hole-transporting layer further includes an oxidizing agent.

<10> The photoelectric conversion element according to any one of <1> to <9>, further including

a hole blocking layer between the first electrode and the electron-transporting layer.

<11> The photoelectric conversion element according to any one of <1> to <10>, further including

a sealing member configured to shield the hole-transporting layer from an external environment of the photoelectric conversion element.

<12> A photoelectric conversion module including

photoelectric conversion elements that are electrically coupled in series or in parallel, each of the photoelectric conversion elements being the photoelectric conversion element according to any one of <1> to <11>.

<13> The photoelectric conversion module according to <12>,

wherein, in the photoelectric conversion module including at least two of the photoelectric conversion elements adjacent to each other, the first electrode in one of the photoelectric conversion elements is electrically coupled to the second electrode in other of the photoelectric conversion elements through a conduction section penetrating at least the hole-transporting layer and the electron-transporting layer.

<14> The photoelectric conversion module according to <12> or <13>, further including

a sealing member configured to shield, from an external environment of the photoelectric conversion module, the hole-transporting layers of the photoelectric conversion elements constituting the photoelectric conversion module.

<15> An electronic device including:

the photoelectric conversion element and/or the photoelectric conversion module according to any one of <1> to <14>; and

a device configured to be driven by electric power generated through photoelectric conversion of the photoelectric conversion element and/or the photoelectric conversion module.

<16> An electronic device including:

the photoelectric conversion element and/or the photoelectric conversion module according to any one of <1> to <14>;

an electricity storage device that can store electric power generated through photoelectric conversion of the photoelectric conversion element and/or the photoelectric conversion module; and

a device configured to be driven by the electric power stored in the electricity storage device.

The photoelectric conversion elements according to <1> to <11>, the photoelectric conversion modules according to <12> to <14>, and the electronic devices according to <15> and <16> can solve the conventionally existing problems in the art and can achieve the object of the present disclosure.

1. A photoelectric conversion element comprising:
a first electrode;
a photoelectric conversion layer; and
a second electrode,
wherein the photoelectric conversion layer includes an electron-transporting layer and a hole-transporting layer,
the electron-transporting layer includes a lithium ion,
the hole-transporting layer includes an organic hole-transporting material and a lithium salt, and
lithium included in the electron-transporting layer is more than lithium included in the hole-transporting layer.

2. The photoelectric conversion element according to claim 1,
wherein the lithium included in the electron-transporting layer being more than the lithium included in the hole-transporting layer is determined by an average value of ionic intensities of the lithium included in the electron-transporting layer being larger than an average value of ionic intensities of the lithium included in the hole-transporting layer, in a depth profile obtained by measuring the lithium included in the electron-transporting layer and the lithium included in the hole-transporting layer by a measurement method (1) or (2) below:
(1) after the second electrode is removed from the photoelectric conversion element, a gas cluster ion beam is applied toward the hole-transporting layer and the electron-transporting layer from a side of the hole-transporting layer, to cut the hole-transporting layer and the electron-transporting layer to prepare an exposed surface; and the lithium of the exposed surface is measured through time-of-flight secondary ion mass spectrometry (TOF-SIMS) in a thickness direction of the hole-transporting layer and the electron-transporting layer, to measure a distribution of the lithium in the thickness direction of the hole-transporting layer and the electron-transporting layer; and
(2) after the second electrode is removed from the photoelectric conversion element, the hole-transporting layer and the electron-transporting layer are cut by a cutting blade in a diagonal direction relative to a thickness direction from a side of an exposed surface of the hole-transporting layer, to form an exposed surface in the diagonal direction; and the lithium of the exposed surface is measured through time-of-flight secondary ion mass spectrometry (TOF-SIMS) to measure a distribution of the lithium in the thickness direction of the hole-transporting layer and the electron-transporting layer.

3. The photoelectric conversion element according to claim 2,
wherein, in the depth profile of the time-of-flight secondary ion mass spectrometry (TOF-SIMS), a ratio (IE/IH) of an average value (IE) of ionic intensities of the lithium included in the electron-transporting layer to an average value (IH) of ionic intensities of the lithium included in the hole-transporting layer is 100 or more.

4. The photoelectric conversion element according to claim 2,
wherein, in the depth profile of the time-of-flight secondary ion mass spectrometry (TOF-SIMS), a ratio (IE/IE2) of an average value (IE) of ionic intensities of the lithium included in the electron-transporting layer to an average value (IE2) of ionic intensities of an electron-transporting material included in the electron-transporting layer is 1.5 or more.

5. The photoelectric conversion element according to claim 1,
wherein the lithium salt includes at least one selected from the group consisting of lithium bis(trifluoromethanesulfonyl)imide and lithium (fluorosulfonyl)(trifluoromethanesulfonyl)imide.

6. The photoelectric conversion element according to claim 1,
wherein the organic hole-transporting material includes a spiro compound.

7. The photoelectric conversion element according to claim 1,
wherein the electron-transporting layer includes a titanium oxide particle including a photosensitization compound adsorbed on a surface of the titanium oxide particle.

8. The photoelectric conversion element according to claim 1,
wherein the hole-transporting layer further includes a compound including a pyridine ring structure.

9. The photoelectric conversion element according to claim 1,
wherein the hole-transporting layer further includes an oxidizing agent.

10. The photoelectric conversion element according to claim 1, further comprising
a hole blocking layer between the first electrode and the electron-transporting layer.

11. The photoelectric conversion element according to claim 1, further comprising
a sealing member configured to shield the hole-transporting layer from an external environment of the photoelectric conversion element.

12. A photoelectric conversion module comprising
photoelectric conversion elements that are electrically coupled in series or in parallel, each of the photoelectric conversion elements being the photoelectric conversion element according to claim 1.

13. The photoelectric conversion module according to claim 12,
wherein, in the photoelectric conversion module including at least two of the photoelectric conversion elements adjacent to each other, the first electrode in one of the photoelectric conversion elements is electrically coupled to the second electrode in other of the photoelectric conversion elements through a conduction section penetrating at least the hole-transporting layer and the electron-transporting layer.

14. The photoelectric conversion module according to claim 12, further comprising
a sealing ember configured to shield, from an external environment of the photoelectric conversion module, the hole-transporting layers of the photoelectric conversion elements constituting the photoelectric conversion module.

15. An electronic device comprising:
the photoelectric conversion element according to claim 1; and
a device configured to be driven by electric power generated through photoelectric conversion of the photoelectric conversion element.

16. An electronic device comprising:
the photoelectric conversion element according to claim 1;
an electricity storage device that can store electric power generated through photoelectric conversion of the photoelectric conversion element; and
a device configured to be driven by the electric power stored in the electricity storage device.

17. An electronic device, comprising:
the photoelectric conversion module according to claim 12; and
a device configured to be driven by electric power generated through photoelectric conversion of the photoelectric conversion module.

18. An electronic device, comprising:
the photoelectric conversion module according to claim 12;
an electricity storage device that can store electric power generated through photoelectric conversion of the photoelectric conversion module; and
a device configured to be driven by the electric power stored in the electricity storage device.
